(19) United States
(12) Patent Application Publication
(10) Pub. No.: US 2025/0314940 A1
(43) Pub. Date: Oct. 9, 2025

(54) ELECTROCHROMIC DEVICES USING TRANSPARENT MXENES

(71) Applicant: Drexel University, Philadelphia, PA (US)

(72) Inventors: Yury Gogotsi, Warminster, PA (US); Pol Sallés Perramon, Manresa (ES); David Pinto, Creteil (FR); Kanit Hantansirisakul, Philadelphia, PA (US); Kathleen Maleski, Mount Airy, MD (US)

(21) Appl. No.: 19/196,920

(22) Filed: May 2, 2025

Related U.S. Application Data
(63) Continuation of application No. 18/595,683, filed on Mar. 5, 2024, now abandoned.
Application No. 18/595,683 is a continuation of application No. 17/287,161, filed on Apr. 21, 2021, now abandoned.
(60) Provisional application No. 62/748,587, filed on Oct. 22, 2018.

(51) Int. Cl. G02F 1/155; G02F 1/1506; G02F 1/1516

(52) U.S. Cl. CPC G02F 1/155; G02F 1/1508; G02F 1/15165

(57) ABSTRACT

The present disclosure describes electrochromic devices comprising transparent conductive layer acting as an electrode, an active electrochromic film, an ion conductor, and an ion storage film at least one of which comprises at least one MXene material.

### CROSS REFERENCE TO RELATED APPLICATIONS

This application is a Continuation of U.S. patent application Ser. No. 18/595,683 (filed Mar. 5, 2024); which is a Continuation of U.S. patent application Ser. No. 17/287,161 (filed Apr. 21, 2021); which is the National Stage Application of International Patent Application No. PCT/US2019/057391 (filed Oct. 22, 2021); which claims priority to and the benefit of U.S. Patent Application No. 62/748,587 (filed Oct. 22, 2018). All foregoing applications are incorporated herein by reference in their entireties for any and all purposes.

### GOVERNMENT RIGHTS

This invention was made with government support under Contract No. W911NF-18-2-0026 awarded by the Army Research Office. The government has certain rights in the invention.

### TECHNICAL FIELD

The present disclosure relates to the field of electrochromic devices and to the field of MXene materials.

### BACKGROUND

Electrochromic energy storage is rapidly evolving due to its applicability in many technologies including wearable smart textiles, bifunctional supercapacitors, and miniaturized indicators. Combining the advantages of energy storage via electrochemical reactions with concomitant color change provides visual indication for charge/discharge states in an electrochromic energy storage device. There is a long-felt need in the art, however, for improved such devices and methods of making such devices.

### SUMMARY

The present disclosure provides, inter alia, an electrochromic micro-supercapacitor (MSC) semitransparent devices (e.g. modification of the color, within the light spectrum, consecutively to the appliance of a potential with storing energy). The device is built, following a planar or digitated MSC architecture, by, e.g., facing two transparent/semi-transparent substrates covered with a thin film of Ti₃C₂ MXene (˜100 nm, sheet resistance≤200 Ω/sq), as electrode, by dip-coating (spray- or spin-coating). Electrodes are separated by a thin (1-1000 micrometers) layer of an aqueous gel, ionogel or liquid electrolyte, composed of an acid (including but not limited to H₂SO₄, H₃PO₄) and/or a salt (including but not limited to MgSO₄, Li₂SO₄). The contact is ensured on both sides of the electrode using copper tape/metal wire and/or conducting paste.

Ti₃C₂ shows a remarkable extinction (absorbance and scattering) peak at specific wavelength of 780 nm. The wavelength of this peak is a unique characteristic of each MXene. While applying consecutive increasing or decreasing potential (within the stable electrochemical window) to the electrodes, a shift of the wavelength of the peak maximum, as well as a variation of the electrode transparency is observed. The wavelength of the peak, initially at 780 nm can vary by −100 nm, to a minimum of 680 nm, depending on the applied potential. The transparency of the full device varies by 10 to 25%, depending on the applied potential and considered wavelength. This variation results in the tailoring of the MXene film color, from semi-transparent green (initial color, at E≥OCV) to semi-transparent blue (at E=−1 V/Ag). A fast switching time of 0.6 s was observed while switching from 0.0 V/Ag (green) to −1 V/Ag (blue) compared to the literature (metal oxide, few seconds to minutes; or conductive polymer, >10 ms). In comparison to the existing and previously cited systems, the present invention does not require the application of a conductive and transparent current collector prior to the active material. The invention is composed of MXene, acting as both active materials only and current collector. Based on the literature, ultra-fast switching rate might be reached by the optimization of the film structure.

Two parameters that influence the performance of electrochemical energy storage devices are the electrode configuration and the electrical conductivity of the charge storing electrode materials. A planar configuration of electrodes in energy storage devices is preferred for easy and compatible integration into small-scale electronic devices and sensors. Additionally, this configuration often results in better rate capabilities due to facile diffusion of ions in the planar configuration over sandwich counterparts that employ physical separators. In addition to the electrode geometry, the kinetics of electrochromic devices is primarily dependent on the intrinsic electronic/ionic conductivity of the electrode materials. Therefore, planar fabrication of electrochromic electrodes is of significant interest towards the design of high-rate energy storage devices.

Though conventional transparent conducting electrodes (TCEs) work well with non-aqueous electrolyte media, such as indium doped tin oxide (ITO), metal nanowire networks and metallic meshes; multi-step patterning protocols and acidic electrolyte incompatibilities remain major hurdles for developing aqueous on-chip electrochromic energy storage devices.

In meeting the described long-felt needs, the present disclosure first provides an electrochromic device, comprising: an electrochromic portion and at least one of (i) a transparent conducting portion and (ii) an ion storage portion, one or more MXene materials being present in at least one of (a) the electrochromic portion and (b) the at least one of (i) the transparent conducting electrode portion and (ii) the ion storage portion; and an electrolyte, the electrolyte placing the electrochromic portion into electronic communication with the at least one of (i) the transparent conducting portion and (ii) the ion storage portion.

Also provided is an electrochromic device, comprising: a first MXene portion and a second MXene portion, the first MXene portion and the second MXene portion being in physical isolation from one another, a conductive material disposed on at least one of the first MXene portion and the second MXene portion, the conductive material optionally having a lower conductivity than the MXene portion on which the conductive material is disposed, the conductive material optionally being disposed within the MXene portion on which the conductive material is disposed, and the conductive material optionally comprising a conductive polymer.

Further provided are methods, comprising: operating a device according to the present disclosure.

Also disclosed are methods, comprising: operating a device according to the present disclosure so as to effect at least one of ion accumulation into or ion release from the ion storage portion.

Further provided are devices, device comprising an electrochromic device according to the present disclosure.

Also provided are methods, comprising: disposing an amount of a MXene material on a substrate so as to form a MXene panel, the substrate optionally being transparent; and placing the MXene panel into electronic communication with an electrode.

### BRIEF DESCRIPTION OF THE DRAWINGS

In the drawings, which are not necessarily drawn to scale, like numerals may describe similar components in different views. Like numerals having different letter suffixes can represent different instances of similar components. The drawings illustrate generally, by way of example, but not by way of limitation, various aspects discussed in the present document. In the drawings:

FIGS. 1A-1C provide a schematic representing construction of electrochromic devices (side view) which include transparent conductive electrodes, an electrochromic layer, an ion-storage layer, and an ion-conducting layer (electrolyte) operating in either transmittance mode (FIG. 1A) and reflectance mode (FIG. 1B). In transmittance mode (FIG. 1A), incident light is absorbed and transmitted through the device, therefore, transparent electrodes are needed on both sides. In reflectance mode (FIG. 1B), incident light is reflected out of the device. The type and mode of the device determines the application. Devices employing MXenes can take advantage of MXenes' multiple functions (FIG. 1C) as the MXene thin film can act as one or both of a transparent conducting electrode/electrochromic layer and a transparent conducting electrode/ion-storage layer.

FIG. 2 provides a schematic of a MXene electrochromic device (side view). In some embodiments, MXene layers are supported by glass substrates, but could be any transparent substrate available (PET, plastics, quartz, etc.). The electrolyte (ion-conducting layer) is used to conduct ions between MXene layers and can be liquid, gel, or solid in state. Common electrolytes are used, including but not limited to, magnesium sulfate (MgSO₄), sulfuric acid (H₂SO₄), and phosphoric acid (H₃PO₄). Such electrolytes described as useful in previous patent applications directed to the use of MXenes are also useful in this capacity. In FIG. 2, MXene is shown as capable of acting as the transparent conducting electrode, ion-storage, and electrochromic layers.

FIGS. 3A-3C provide a schematic illustration of Ti₃C₂ semitransparent film prepared by spray coating. FIG. 3A is the structure of Ti₃AlC₂ and Ti₃C₂, where Ti, Al, C, O, and H atoms are shown, and FIG. 3A also provides a schematic of electrode fabrication. FIG. 3B provides a schematic illustration of a3-electrode cell for the in-situ tests. FIG. 3C provides digital images of the example device at different voltages in 1M LiTFSI electrolyte and their related red-green-blue (RGB) values.

FIGS. 4A-4D provide in-situ UV-vis tests collected at different voltages in 1M LiTFSI/PC (FIG. 4A), 1M EMIMTFSI/PC (FIG. 4B), and 1 M LiClO₄/PC (FIG. 4C) electrolytes. (FIG. 4D) In-situ XRD results of the (002) peak of Ti₃C₂ tested in different electrolytes.

FIGS. 5A-5D provide (FIG. 5A) cyclic voltammograms of the Ti₃C₂ film and (FIG. 5B) the charge capacity vs UVvis peak shift plots recorded in different electrolytes. In-situ Raman spectra (FIG. 5C) and the statistics (FIG. 5D) of peak change at 620 and 282 cm⁻¹ of Ti₃C₂ recorded in 1M LiTFSI/PC are also shown.

FIGS. 6A-6D provide computation calculations of optical transmission (FIG. 6A) and reflectivity (FIG. 6B) of Ti₃C₂(OH)₂ MXene with varying Li concentration. (FIG. 6C) The electronic band structures of Ti₃C₂(OH)₂ (lower) and Ti₃C₂(OH)₂Li₂ with Li character colored in cyan (highlighted by arrows). Three inter-band excitations mechanisms are assigned in the band structure: 1.1 (dark green), 2.4(orange). And (FIG. 6D) Bader charges of three Ti layers (bottom to the top as the Ti layer index) of Ti₃C₂(OH)₂Liₓ (x=0, −0.5, 1, 1.25, 2).

FIG. 7 provides a schematic depicting the formation process for hybrid/composite PEDOT/Ti₃C₂ films. Spray coated Ti₃C₂ films on glass substrates. Electrochemical polymerization of poly(3,4-ethylenedioxythiophene), PEDOT on MXene thin films. Corresponding digital photographs of Ti₃C₂ (left) and PEDOT/Ti₃C₂ (right) thin films are shown.

FIGS. 8A-8F provide (FIG. 8A) X-ray diffraction (XRD) patterns of PEDOT/Ti₃C₂ and pristine Ti₃C₂ thin films, inset shows (002) peak shift after electrodeposition of PEDOT (FIG. 8B) Raman spectra of PEDOT/ITO, PEDOT/Ti₃C₂, and pristine Ti₃C₂. Stars are indicative of Ti₃C₂ Raman peaks. (FIG. 8C) High-resolution cross-section TEM image of the PEDOT/Ti₃C₂ film, (FIG. 8D) schematic illustrating nucleation and growth of PEDOT on the surface and in top few Ti₃C₂ layers. (FIG. 8E) Cross-sectional scanning electron microscopy (SEM) image of PEDOT deposited on Ti₃C₂, (FIG. 8F) magnified view of PEDOT/Ti₃C₂ interface.

FIGS. 9A-9F provide a schematic of (FIG. 9A) PEDOT/Ti₃C₂ symmetric interdigitated microsupercapacitor (MSC), (FIG. 9B) cyclic voltammograms at different scan rates, (FIG. 9C) variation of areal capacitance with scan rate, (FIG. 9D) galvanostatic charge-discharge curves at different current densities, (FIG. 9E) cycling stability of PEDOT/Ti₃C₂ MSC for 10,000 cycles at a scan rate of 100 mV/s, the inset shows the Nyquist plot of the device and (FIG. 9F) Ragone plot of (100 nm thickness) PEDOT/Ti₃C₂ MSC compared with the reported MSCs.

FIGS. 10A-10C provide in-situ spectra recorded on PEDOT/Ti₃C₂ finger electrodes (100 nm thickness). (FIG. 10A) In-situ UV-vis spectra at different voltages during the CV test. (FIG. 10B) In-situ resonant Raman spectra of the PEDOT/Ti₃C₂ electrode during the CV scan. (FIG. 10C) Digital images at different voltages showing the color changes of the finger electrodes in reversible manner and the corresponding RGB values are shown.

FIGS. 11A-11B provide cyclic voltammograms of Ti₃C₂ in cathodic and anodic potential windows of operation at a scan rate of 10 mV/s (FIG. 11A) and a comparison (FIG. 11B) of CV profiles before and after anodic oxidation at a scan rate of 10 mV/s.

FIGS. 12A-12B provides UV-Vis spectra of (FIG. 12A) the pristine Ti₃C₂ films with different thickness and (FIG. 12B) PEDOT/Ti₃C₂ films with different loadings of PEDOT (thickness of the Ti₃C₂ layer is ˜40 nm). Corresponding charge values for depositing PEDOT on MXene films are indicated.

FIG. 13 provides a comparison of four-point probe electrical conductivities of pristine Ti₃C₂ (thickness, ˜40 nm) and PEDOT/Ti₃C₂ thin films (thickness, ˜100 nm).

FIGS. 14A-14B provide cyclic voltammograms of (FIG. 14A) pristine Ti₃C₂(40 nm) and (FIG. 14B) PEDOT (30 nm)/Ti₃C₂ (40 nm) MSCs recorded with the scan rates ranging from 10 to 1000 mV/s. The poor rate performance of MXene MSC is due to limited ion diffusion pathways into the stacked large sheets of MXene. While PEDOT/MXene MSCs show a rate performance due to intercalated PEDOT chains into the top few layers of MXenes, which facilitate ion diffusion.

FIG. 15 provides In-situ UV-vis spectra of the pristine Ti₃C₂ symmetric MSC.

FIGS. 16A-16B provide (FIG. 16A) stimulus-response of transmittance at 488 nm of PEDOT/Ti₃C₂ device under the pulse voltage of ±0.6 V and (FIG. 16B) corresponding cycling performance of the device, maintaining the similar transmittance states over 300 cycles.

FIGS. 17A-17C provide in-situ electrochromic study of Ti₃C₂ transparent electrodes with a H₃PO₄/PVA gel electrolyte in a three-electrode configuration. (FIG. 17A) Cyclic voltammogram of the working electrode in a Ti₃C₂Tₓ//Ti₃C₂ (Ag reference electrode) three-electrode configuration at 20 mV/s, where red cross marks indicate anodic potentials (EWE>OCV) and blue cross marks indicate cathodic potentials (EWE<OCV). Probing the percent transmittance (% T) spectral response from 280 to 1000 nm to (FIG. 17B) cathodic potentials and (FIG. 17C) anodic potentials, with black arrows showing the direction of change from OCV to the extreme potential and insets showing the % T reversibility to OCV.

FIGS. 18A-18B provide switching rate of Ti₃C₂ electrochromic device in 1 M H₃PO₄ aqueous electrolyte in a three-electrode configuration. The rate was probed by monitoring the change in transmittance at 450 nm (T₄₅₀ₙₘ) when the potential was swept from 0.0 to −1.0 V/Ag, applied by (FIG. 18A) cyclic voltammetry at 50 mV/s and (FIG. 18B) chronoamperometry. The potential applied to the device is represented by the blue trace and the measured T₄₅₀ₙₘ by the black trace. Inset in (FIG. 18B) shows shift of transmittance for switch rate calculation.

FIGS. 19A-19D provide an investigation of the electrochromic mechanism of the Ti₃C₂ electrode in H₃PO₄/PVA gel in three-electrode configuration by in-situ X-ray diffraction (XRD) (FIG. 19A, 19B) to study the structural changes and in-situ Raman spectroscopy (FIG. 19C, 19D) to study the chemical changes. (FIG. 19A) and (FIG. 19C) are XRD patterns and Raman spectra, respectively, of the electrode before (orange trace) and after (black trace) addition of electrolyte. The XRD patterns and Raman spectra recorded at different potentials (0.2 to −0.8 V/Ag) are shown in (FIG. 19B) and (FIG. 19D), respectively.

FIGS. 20A-20F provide in-situ electrochromic study of Ti₃C₂ in H₂SO₄ and MgSO₄ aqueous electrolytes in a three-electrode configuration. (FIG. 20A) Cyclic voltammogram of the device in H₂SO₄, where blue cross marks indicate cathodic potentials (E_{WE}<OCV) and red cross marks indicate anodic potentials (E_{WE}>OCV). Probing the UV-vis-NIR transmittance spectral response from 280 to 1000 nm to (FIG. 20B) cathodic potentials (reversibility to OCV is shown in the inset) and (FIG. 20C) anodic potentials; with black arrows showing the direction of change from OCV to the extreme potential applied. (FIG. 20D) Cyclic voltammogram of the device in MgSO₄, (FIG. 20E) UV-vis-NIR spectra recorded at cathodic potentials (reversibility to OCV is shown in inset) and (FIG. 20F) anodic potentials.

FIGS. 21A-21B provide (FIG. 21A) Comparison of the change in extinction peak position of UV-vis-NIR spectra (corresponding wavelength plotted in energy, eV) for Ti₃C₂ MXene with different electrolytes under potential. (FIG. 21B) Schematic of the energy change as a function of the applied potential for acidic electrolytes.

FIGS. 22A-22D provide an examination of dip-coated Ti₃C₂ thin films and the effect of flake size. (FIG. 22A) Flake size distribution obtained by dynamic light scattering (DLS). SEM images of an individual flake on glass obtained by (FIG. 22B) MILD method (LiF/HCl) and (FIG. 22C) after sonication. (FIG. 22D) Optoelectronic characteristics; T₅₅₀ₙₘ plotted as function of Rₛ for different thin films, inset shows plot for FoMₑ calculations.

FIGS. 23A-23C provide an optimization of dip-coated Ti₃C₂ thin films: effect of number of dips versus concentration. Digital images of thin films of different thicknesses obtained by (FIG. 23A) dipping into a MXene solution of different concentrations from 1 to 6 mg/mL and (FIG. 23B) dipping different times from 1 to 5 dips into a 3 mg/mL MXene solution. (FIG. 23C) Optoelectronic characteristics; upper panel shows T₅₅₀ₙₘ plotted as function of Rₛ for different thin films, and lower panel shows plot for FoMₑ calculations.

FIGS. 24A-24C provide Ti₃C₂ thin film characterization; (FIG. 24A) roughness and thickness obtained by profilometer, (FIG. 24B) XRD pattern and (FIG. 24C) the deconvoluted Raman spectrum.

FIG. 25 provides XRD pattern of the Ti₃AlC₂ MAX phase and Ti₃C₂ MXene free-standing film

FIGS. 26A-26B provide a comparison of UV-vis-NIR spectra obtained by (FIG. 26A) combination of both electrodes in a full symmetric device when −1.0 V/Ag was applied, and (FIG. 26B) average combination of the spectra obtained when extreme potentials were applied in the single electrode study. All spectra were obtained with H₃PO₄ PVA gel electrolyte.

FIGS. 27A-27B provide complementary data for characterization of the switching rate of Ti₃C₂ electrochromic device in 1 M H₃PO₄ electrolyte in a three-electrode configuration. Current measured upon applying potential from 0.0 to −1.0 V/Ag for (FIG. 27A) Cyclic voltammetry (scan rate dE/dt=50 m V/s) and (FIG. 27B) chronoamperometry.

FIG. 28 provides a schematic of in-situ electrochemical configurations for each technique: UV-visible spectroscopy, XRD, and Raman spectroscopy.

FIG. 29 provides a Ti₃CN electrochromic device in 1 M H₃PO₄ PVA gel electrolyte in a three-electrode configuration. UV-vis-NIR spectra for OCV and extreme cathodic voltage (−0.7 V/Ag); inset corresponding to a cyclic voltammogram of the device.

FIGS. 30A-30B provide (FIG. 30A) UV-vis-NIR spectra showing absorption characteristics of Ti₃C₂, Ti₃CN, Ti₂C and Ti_{1.6}Nb_{0.4}C over the entire visible range, relevant extinction peak positions are marked. (FIG. 30B) XRD patterns showing the crystalline nature of MXene thin films, (002) peak corresponds to typical interlayer spacing of 12-14.5 Å.

FIGS. 31A-31B provide (FIG. 31A) relationship between transmittance at 550 nm (T₅₅₀ₙₘ) versus sheet resistance, and (FIG. 31B) estimated electrical figure of merit (FoMₑ) values for MXene thin films.

FIGS. 32A-32D provide in-situ opto-electrochemical behavior of Ti₃C₂ thin films. (FIG. 32A) Typical CV profile of Ti₃C₂ at 20 mV/s. Change of optical properties with gradual (FIG. 32B) cathodic and (FIG. 32C) anodic polarizations. Insets show the UV-vis spectra tracing back to original (same spectrum as OCV condition) after relaxation from each potential polarization steps. (FIG. 32D) Reversible color switching from green to blue for Ti₃C₂ electrochromic films.

FIGS. 33A-33B provide (FIG. 33A) CV of Ti₃C₂ under cathodic and anodic potentials. At high anodic potential (0.8 V vs. Ag), irreversible oxidation was observed. (FIG. 33B) UV-vis spectra showing no change of optical extinction peak for oxidized MXene even during cathodic polarization (at −1 V vs. Ag).

FIGS. 34A-34D provide in-situ opto-electrochemical behavior of Ti₃CN thin films. (FIG. 34A) Typical CV profile of Ti₃CN at 20 mV/s. Change of optical properties with gradual (FIG. 34B) cathodic and (FIG. 34C) anodic polarizations. Insets showing the UV-vis spectra tracing back to original (same spectrum as OCV condition) after relaxation from each potential polarization steps. (FIG. 34D) Reversible color switching from gray to violet blue for Ti₃CN electrochromic films.

FIGS. 35A-35D provide in-situ opto-electrochemical behavior of Ti₂C and Ti_{1.6}Nb_{0.4}C thin films. (FIG. 35A, 35C) Typical CV profiles of Ti₂C and Ti_{1.6}Nb_{0.4}C at 20 mV/s, respectively and corresponding UV-vis spectra under (FIG. 35B, 35D) cathodic polarization. Insets showing the UV-vis spectra tracing back to original (same spectrum as OCV condition) after relaxation from each potential polarization steps.

FIGS. 36A-36B provide a summary of electrochromic effect of Ti-based MXenes. (FIG. 36A) Typical cyclic voltammograms (CVs) of MXene thin films (Ti₃C₂, Ti₃CN, Ti₂C, Ti_{1.6}Nb_{0.4}C) at 20 mV/s and (FIG. 36B) their optical absorption properties towards cathodic polarization (−1 V vs. Ag) with respect to open circuit voltage (OCV).

FIGS. 37A-37D provide transmittance change of MXene electrochromic devices with time under potential pulses between 0 to −1V (vs. Ag), (FIG. 37A) Ti₃C₂, (FIG. 37B) Ti₃CN, (FIG. 37C) Ti₂C, and (FIG. 37D) Ti_{1.6}Nb_{0.4}C. Insets show corresponding switching time estimations for the devices.

FIGS. 38A-38D provide electro-optical responses of Ti-based MXene electrochromic devices. (FIG. 38A) Change of transmittance of the of MXene electrochromic devices with cycle number. (FIG. 38B) switching times versus associated optical dynamic range, (FIG. 38C) performance metrics (coloration efficiency vs durability) of MXenes is compared with other electrochromic materials and (FIG. 38D) summary of tunable optical behavior of MXene thin films under different cathodic potentials with respect to initial centering (shows in dotted line) of extinction peak for each MXene.

FIGS. 39A-39C provide an exemplary device and exemplary results.

### DETAILED DESCRIPTION OF ILLUSTRATIVE EMBODIMENTS

The present disclosure may be understood more readily by reference to the following detailed description taken in connection with the accompanying figures and examples, which form a part of this disclosure. It is to be understood that this disclosure is not limited to the specific devices, methods, applications, conditions or parameters described and/or shown herein, and that the terminology used herein is for the purpose of describing particular embodiments by way of example only and is not intended to be limiting of the claimed technology.

Also, as used in the specification including the appended claims, the singular forms “a,” “an,” and “the” include the plural, and reference to a particular numerical value includes at least that particular value, unless the context clearly dictates otherwise. The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable, and it should be understood that steps can be performed in any order.

It is to be appreciated that certain features of the invention which are, for clarity, described herein in the context of separate embodiments, can also be provided in combination in a single embodiment. Conversely, various features of the invention that are, for brevity, described in the context of a single embodiment, can also be provided separately or in any subcombination. All documents cited herein are incorporated herein in their entireties for any and all purposes.

Further, reference to values stated in ranges include each and every value within that range. In addition, the term “comprising” should be understood as having its standard, open-ended meaning, but also as encompassing “consisting” as well. For example, a device that comprises Part A and Part B can include parts in addition to Part A and Part B, but can also be formed only from Part A and Part B.

Preferred and/or optional features of the invention will now be set out. Any aspect of the invention can be combined with any other aspect of the invention unless the context demands otherwise. Any of the preferred and/or optional features of any aspect can be combined, either singly or in combination, with any aspect of the invention unless the context demands otherwise.

Due to the large variety of available MXene phases (from mono-metal, Mₙ₊₁Cₙ, referring to but not only, Ti₃C₂, Ti₃CN, Ti₂C, V₂C, Nb₂C, Mo₂C; to multi-metal M′₂M″C₂ and M′₂M″₂C₃, referring to but not only, Mo₂TiC₂, Mo₂Ti₂C₃, Mo_{1.33}Y_{0.66}C, Mo_{1.33}Sc_{0.66}C, Cr₂TiC₂), showing different absorption depending on the composition, multiple change in color can be achieved in the visible spectrum of the light. In the present appended article draft, we demonstrate a variation from green to blue.

MXenes are hydrophilic and easily processable on a large variety of (semi-) transparent substrate (glass, quartz polymer, such as PET or others, Kapton) by all most available techniques, such as spin-coating (gold standard in the solar cell field) or easily scalable spray-coating and dip-coating (as demonstrated in the present study). With both spray-and dip-coating, large surfaces can be covered.

MXenes shows outstanding electrical conductivity (from 100 to 10,000 S/cm as a thick film). The thin semitransparent or transparent film presents sheet resistance of 500 Ω/sq or less. In consequence, the MXenes can be applied directly on the substrate without requiring an expensive conductive transparent current collector (such as thin gold layer or ITO) or the development of complex material-mix strategies as for metal oxides or conductive polymers.

Due to the intrinsic low resistance of thin films of MXene, it can be envisaged to combine the electrochromic response of the thin film, in the present invention, with other optoelectronic properties of MXene for various application, such as resistive responsive screen, smart glass and/or screen.

Due to their intercompatibility (chemistry, processability), different MXene compositions might be combined to associate their optoelectronic properties. Different MXene provides different wavelength shift and so on, different change in color and electrochromism. In consequence, MXenes can be associated in a sole film to ensure different color changes, based on the inherent color of each MXene, the individual color shift while applying a specific potential and the combination of these physical colors.

Within the present invention statement, array architectures of MXene thin films are proposed to select different deposited MXenes on a substrate and shift the electrochromic properties of only one or several deposited MXenes at different potential.

### MXene Compositions

The present disclosure may be understood more readily by reference to the following description taken in connection with the accompanying Figures and Examples, all of which form a part of this disclosure. It is to be understood that this disclosure is not limited to the specific products, methods, conditions or parameters described or shown herein, and that the terminology used herein is for the purpose of describing particular embodiments by way of example only and is not intended to be limiting of any claimed invention. Similarly, unless specifically otherwise stated, any description as to a possible mechanism or mode of action or reason for improvement is meant to be illustrative only, and the disclosure herein is not to be constrained by the correctness or incorrectness of any such suggested mechanism or mode of action or reason for improvement. Throughout this text, it is recognized that the descriptions refer to compositions and methods of making and using said compositions. That is, where the disclosure describes or claims a feature or embodiment associated with a composition or a method of making or using a composition, it is appreciated that such a description or claim is intended to extend these features or embodiment to embodiments in each of these contexts (i.e., compositions, methods of making, and methods of using).

The MXene layers may be applied using any of the methods described elsewhere herein, but exemplary methods include spray, spin, roller, or dip coating, or ink-printing, or lithographic patterning.

MXenes have been previously been described in several publications, and a reference to MXenes in this disclosure contemplates at least all of the compositions described therein:
Compositions comprising free-standing two-dimensional nanocrystal, PCT/US2013/072733;
Two-dimensional, ordered, double transition metals carbides having a nominal unit cell composition M′₂M″ₙXₙ₊₁, PCT/US2016/028354;
Physical Forms of MXene Materials Exhibiting Novel Electrical and Optical Characteristics, U.S. Pat. No. 20,170,294546A1

Additionally, the MXene compositions may comprise any of the compositions described elsewhere herein. Exemplary MXene compositions include those comprising:
(a) at least one layer having first and second surfaces, each layer described by a formula Mₙ₊₁XₙTₓ and comprising:
substantially two-dimensional array of crystal cells, each crystal cell having an empirical formula of Mₙ₊₁Xₙ, such that
each X is positioned within an octahedral array of M, wherein
M is at least one Group IIIB, IVB, VB, or VIB metal or Mₙ, wherein
each X is C, N, or a combination thereof;
n=1, 2, or 3; and wherein
Tₓ represents surface termination groups when present; or
(b) at least one layer having first and second surfaces, each layer comprising:
a substantially two-dimensional array of crystal cells,
each crystal cell having an empirical formula of M′₂M″ₙXₙ₊₁Tₓ, such that each X is positioned within an octahedral array of M′ and M″, and where M″ₙ is present as individual two-dimensional array of atoms intercalated between a pair of two-dimensional arrays of M′ atoms,
wherein M′ and M″ are different Group IIIB, IVB, VB, or VIB metals,
wherein each X is C, N, or a combination thereof;
n=1 or 2; and wherein
Tₓ represents surface termination groups. In certain of these exemplary embodiments, the at least one of said surfaces of each layer has surface termination groups (Tₓ) comprising alkoxide, carboxylate, halide, hydroxide, hydride, oxide, sub-oxide, nitride, sub-nitride, sulfide, thiol, or a combination thereof. In certain preferred embodiments, the MXene composition has an empirical formula of Ti₃C₂. (It should be understood that MXene materials can include terminations, though this is not a requirement, as MXene materials can include terminations or be free of terminations. Accordingly, although the notation Tₓ is used in certain formulas herein to show the possible presence of terminations, it should be understood that the absence of the notation Tₓ from a formula does not also mean that the formula in question lacks terminations.)

While the instant disclosure describes the use of Ti₃C₂, because of the convenient ability to prepare larger scale quantities of these materials, it is believed and expected that all other MXenes will perform similarly, and so all such MXene compositions are considered within the scope of this disclosure. In certain embodiments, the MXene composition is any of the compositions described in at least one of U.S. patents application Ser. Nos. 14/094,966 (filed Dec. 3, 2013), 62/055,155 (filed Sep. 25, 2014), 62/214,380 (filed Sep. 4, 2015), 62/149,890 (filed Apr. 20, 2015), 62/127,907 (filed Mar. 4, 2015) or International Applications PCT/US2012/043273 (filed Jun. 20, 2012), PCT/US2013/072733 (filed Dec. 3, 2013), PCT/US2015/051588 (filed Sep. 23, 2015), PCT/US2016/020216 (filed Mar. 1, 2016), or PCT/US2016/028,354 (filed Apr. 20, 2016), preferably where the MXene composition comprises titanium and carbon (e.g., Ti₃C₂, Ti₂C, Mo₂TiC₂, etc.). Each of these compositions is considered independent embodiment. Similarly, MXene carbides, nitrides, and carbonitrides are also considered independent embodiments. Various MXene compositions are described elsewhere herein, and these and other compositions, including coatings, stacks, laminates, molded forms, and other structures, described in the above-mentioned references are all considered within the scope of the present disclosure.

Where the MXene material is present as a coating on a conductive or non-conductive substrate, that MXene coating may cover some or all of the underlying substrate material. Such substrates may be virtually any conducting or non-conducting material, though preferably the MXene coating is superposed on a non-conductive surface. Such non-conductive surfaces or bodies may comprise virtually any non-electrically conducting organic polymer, inorganic material (e.g., glass or silicon). Since MXene can be produced as a free-standing film, or applied to any shaped surface, in principle the MXene can be applied to almost any substrate material, depending on the intended application, with little dependence on morphology and roughness. In independent embodiments, the substrate may be a non-porous, porous, microporous, or aerogel form of an organic polymer, for example, a fluorinated or perfluorinated polymer (e.g., PVDF, PTFE) or an alginate polymer, a silicate glass, silicon, GaAs, or other low-K dielectric, an inorganic carbide (e.g., SiC) or nitride (Al₃N₄) or other thermally conductive inorganic material wherein the choice of substrate depends on the intended application. Depending on the nature of the application, low-k dielectrics or high thermal conductivity substrates may be used.

In some embodiments, the substrate is rigid (e.g., on a silicon wafer). In other embodiments, substrate is flexible (e.g., on a flexible polymer sheet). Substrate surfaces may be organic, inorganic, or metallic, and comprise metals (Ag, Au, Cu, Pd, Pt) or metalloids; conductive or non-conductive metal oxides (e.g., SiO₂, ITO), nitrides, or carbides; semi-conductors (e.g., Si, GaAs, InP); glasses, including silica or boron-based glasses; or organic polymers.

The coating may be patterned or un-patterned on the substrate. In independent embodiments, the coatings may be applied or result from the application by spin coating, dip coating, roller coating, compression molding, doctor blading, ink printing, painting or other such methods. Multiple coatings of the same or different MXene compositions may be employed.

Flat surface or surface-patterned substrates can be used. The MXene coatings may also be applied to surfaces having patterned metallic conductors or wires. Additionally, by combining these techniques, it is possible to develop patterned MXene layers by applying a MXene coating to a photoresist layer, either a positive or negative photoresist, photopolymerize the photoresist layer, and develop the photopolymerized photoresist layer. During the developing stage, the portion of the MXene coating adhered to the removable portion of the developed photoresist is removed. Alternatively, or additionally, the MXene coating may be applied first, followed by application, processing, and development of a photoresist layer. By selectively converting the exposed portion of the MXene layer to an oxide using nitric acid, a MXene pattern may be developed. In short, these MXene materials may be used in conjunction with any appropriate series of processing steps associated with thick or thin film processing to produce any of the structures or devices described herein (including, e.g., plasmonic nanostructures).

The methods described in PCT/US2015/051588 (filed Sep. 23, 2015), incorporated by reference herein at least for such teachings, are suitable for such applications.

In independent embodiments, the MXene coating can be present and is operable, in virtually any thickness, from the nanometer scale to hundreds of micrometers. Within this range, in some embodiments, the MXene may be present at a thickness ranging from 1-2 nm to 1000 micrometers, or in a range defined by one or more of the ranges of from 1-2 nm to 25 nm, from 25 nm to 50 nm, from 50 nm to 100 nm, from 100 nm to 150 nm, from 150 nm to 200 nm, from 200 nm to 250 nm, from 250 nm to 500 nm, from 500 nm to 1000 nm, from 1000 nm to 1500 nm, from 1500 nm to 2500 nm, from 2500 nm to 5000 nm, from 5 micrometers to 100 micrometers, from 100 micrometers to 500 micrometers, or from 500 micrometers to 1000 micrometers.

Typically, in such coatings, the MXene is present as an overlapping array of two or more overlapping layers of MXene platelets oriented to be essentially coplanar with the substrate surface. In specific embodiments, the MXene platelets have at least one mean lateral dimension in a range of from about 0.1 micrometers to about 50 micrometers, or in a range defined by one or more of the ranges of from 0.1 to 2 micrometers, from 2 micrometers to 4 micrometers, from 4 micrometers to 6 micrometers, from 6 micrometers to 8 micrometers, from 8 micrometers to 10 micrometers, from 10 micrometers to 20 micrometers, from 20 micrometers to 30 micrometers, from 30 micrometers to 40 micrometers, or from 40 micrometers to 50 micrometers.

Again, the substrate may also be present such that its body is a molded or formed body comprising the MXene composition. While such compositions may comprise any of the MXene compositions described herein, exemplary methods of making such structures are described in PCT/US2015/051588 (filed Sep. 23, 2015), which is incorporated by reference herein at least for such teachings.

To this point, the disclosure(s) have been described in terms of the methods and derived coatings or compositions themselves, the disclosure also contemplates that devices incorporating or comprising these thin films are considered within the scope of the present disclosure(s). Additionally, any of the devices or applications described or discussed elsewhere herein are considered within the scope of the present disclosure(s)

### Additional Terms

In the present disclosure the singular forms “a,” “an,” and “the” include the plural reference, and reference to a particular numerical value includes at least that particular value, unless the context clearly indicates otherwise. Thus, for example, a reference to “a material” is a reference to at least one of such materials and equivalents thereof known to those skilled in the art, and so forth.

When a value is expressed as an approximation by use of the descriptor “about,” it will be understood that the particular value forms another embodiment. In general, use of the term “about” indicates approximations that can vary depending on the desired properties sought by the disclosed subject matter and is to be interpreted in the specific context in which it is used, based on its function. The person skilled in the art will be able to interpret this as a matter of routine. In some cases, the number of significant figures used for a particular value may be one non-limiting method of determining the extent of the word “about.” In other cases, the gradations used in a series of values may be used to determine the intended range available to the term “about” for each value. Where present, all ranges are inclusive and combinable. That is, references to values stated in ranges include every value within that range.

It is to be appreciated that certain features of the disclosure which are, for clarity, described herein in the context of separate embodiments, may also be provided in combination in a single embodiment. That is, unless obviously incompatible or specifically excluded, each individual embodiment is deemed to be combinable with any other embodiment(s) and such a combination is considered to be another embodiment. Conversely, various features of the disclosure that are, for brevity, described in the context of a single embodiment, may also be provided separately or in any sub-combination. Finally, while an embodiment may be described as part of a series of steps or part of a more general structure, each said step may also be considered an independent embodiment in itself, combinable with others.

When a list is presented, unless stated otherwise, it is to be understood that each individual element of that list, and every combination of that list, is a separate embodiment. For example, a list of embodiments presented as “A, B, or C” is to be interpreted as including the embodiments, “A,” “B,” “C,” “A or B,” “A or C,” “B or C,” or “A, B, or C.”

The transitional terms “comprising,” “consisting essentially of,” and “consisting” are intended to connote their generally in accepted meanings in the patent vernacular; that is, (i) “comprising,” which is synonymous with “including,” “containing,” or “characterized by,” is inclusive or open-ended and does not exclude additional, unrecited elements or method steps; (ii) “consisting of” excludes any element, step, or ingredient not specified in the claim; and (iii) “consisting essentially of” limits the scope of a claim to the specified materials or steps “and those that do not materially affect the basic and novel characteristic(s)” of the claimed disclosure. Embodiments described in terms of the phrase “comprising” (or its equivalents), also provide, as embodiments, those which are independently described in terms of “consisting of” and “consisting essentially of.” Where the term “consisting essentially of” is used, the basic and novel characteristic(s) of the method is intended to be the ability of the MXene materials to exhibit selective infrared thermal emission and absorption properties.

Throughout this specification, words are to be afforded their normal meaning, as would be understood by those skilled in the relevant art. However, so as to avoid misunderstanding, the meanings of certain terms will be specifically defined or clarified

While MXene compositions include any and all of the compositions described in the patent applications and issued patents described above, in some embodiments, MXenes are materials comprising or consisting essentially of a Mₙ₊₁Xₙ(Tₓ) composition having at least one layer, each layer having a first and second surface, each layer comprising
a substantially two-dimensional array of crystal cells.
each crystal cell having an empirical formula of Mₙ₊₁Xₙ, such that each X is positioned within an octahedral array of M,
wherein M is at least one Group 3, 4, 5, 6, or 7, or Mn,
wherein each X is carbon and nitrogen or combination of both and
n=1, 2, or 3;
wherein at least one of said surfaces of the layers has surface terminations, Tₛ, independently comprising alkoxide, alkyl, carboxylate, halide, hydroxide, hydride, oxide, sub-oxide, nitride, sub-nitride, sulfide, sulfonate, thiol, or a combination thereof;

As described elsewhere within this disclosure, the Mₙ₊₁Xₙ(Tₓ) materials produced in these methods and compositions have at least one layer, and sometimes a plurality of layers, each layer having a first and second surface, each layer comprising a substantially two-dimensional array of crystal cells; each crystal cell having an empirical formula of Mₙ₊₁Xₙ, such that each X is positioned within an octahedral array of M, wherein M is at least one Group 3, 4, 5, 6, or 7 metal (corresponding to Group IIIB, IVB, VB, VIB or VIIB metal or Mn), wherein each X is C and/or N and n=1, 2, or 3; wherein at least one of said surfaces of the layers has surface terminations, Tₓ, comprising alkoxide, alkyl, carboxylate, halide, hydroxide, hydride, oxide, sub-oxide, nitride, sub-nitride, sulfide, sulfonate, thiol, or a combination thereof.

Supplementing the descriptions above, Mₙ₊₁Xₙ(Tₓ), compositions may be viewed as comprising free standing and stacked assemblies of two-dimensional crystalline solids. Collectively, such compositions are referred to herein as “Mₙ₊₁Xₙ(Tₓ),” “MXene,” “MXene compositions,” or “MXene materials.” Additionally, these terms “Mₙ₊₁Xₙ(Tₓ),” “MXene,” “MXene compositions,” or “MXene materials” also refer to those compositions derived by the chemical exfoliation of MAX phase materials, whether these compositions are present as free-standing two-dimensional or stacked assemblies (as described further below). Reference to the carbide equivalent to these terms reflects the fact that X is carbon, C, in the lattice. Such compositions comprise at least one layer having first and second surfaces, each layer comprising: a substantially two-dimensional array of crystal cells; each crystal cell having an empirical formula of Mₙ₊₁Xₙ, where M, X, and n are defined above. These compositions may be comprised of individual or a plurality of such layers. In some embodiments, the Mₙ₊₁Xₙ(Tₓ) MXenes comprising stacked assemblies may be capable of, or have atoms, ions, or molecules, that are intercalated between at least some of the layers. In other embodiments, these atoms or ions are lithium. In still other embodiments, these structures are part of an energy-storing device, such as a battery or supercapacitor. In still other embodiments these structures are added to polymers to make polymer composites.

The term “crystalline compositions comprising at least one layer having first and second surfaces, each layer comprising a substantially two-dimensional array of crystal cells” refers to the unique character of these MXene materials. For purposes of visualization, the two-dimensional array of crystal cells may be viewed as an array of cells extending in an x-y plane, with the z-axis defining the thickness of the composition, without any restrictions as to the absolute orientation of that plane or axes. It is preferred that the at least one layer having first and second surfaces contain but a single two-dimensional array of crystal cells (that is, the z-dimension is defined by the dimension of approximately one crystal cell), such that the planar surfaces of said cell array defines the surface of the layer; it should be appreciated that real compositions may contain portions having more than single crystal cell thicknesses.

That is, as used herein, “a substantially two-dimensional array of crystal cells” refers to an array which preferably includes a lateral (in x-y dimension) array of crystals having a thickness of a single cell, such that the top and bottom surfaces of the array are available for chemical modification.

Metals of Group 3, 4, 5, 6, or 7 (corresponding to Group IIIB, IVB, VB, VIB, or VIIB), either alone or in combination, said members including Ti, Zr, Hf, V, Nb, Ta, Cr, Mo, and W. For the purposes of this disclosure, the terms “M” or “M atoms,” “M elements,” or “M metals” may also include Mn. Also, for purposes of this disclosure, compositions where M comprises Ti, Zr, Hf, V, Nb, Ta, Cr, Mo, W, or mixtures thereof constitute independent embodiments. Similarly, the oxides of M may comprise any one or more of these materials as separate embodiments. For example, M may comprise any one or combination of Hf, Cr, Mn, Mo, Nb, Sc. Ta, Ti, V, W, or Zr. In other preferred embodiments, the transition metal is one or more of Ti, Zr, V, Cr, Mo, Nb, Ta, or a combination thereof. In even more preferred embodiments, the transition metal is Ti, Ta, Mo, Nb, V, Cr, or a combination thereof.

In certain specific embodiments, Mₙ₊₁Xₙ comprises Mₙ₊₁Cₙ (i.e., where X=C, carbon) which may be Ti₂C, V₂C, V₂N, Cr₂C, Zr₂C, Nb₂C, Hf₂C, Ta₂C, Mo₂C, Ti₃C₂, V₃C₂, Ta₃C₂, Mo₃C₂, (Cr_{2/3} Ti_{1/2})₃C₂, Ti₄C₃, V₄C₃, Ta₄C₃, Nb₄C₃, or a combination thereof.

In more specific embodiments, the Mₙ₊₁Xₙ(Tₓ) crystal cells have an empirical formula Ti₃C₂ or Ti₂C. In certain of these embodiments, at least one of said surfaces of each layer of these two dimensional crystal cells is coated with surface terminations, Tₓ, comprising alkoxide, fluoride, hydroxide, oxide, sub-oxide, sulfonate, or a combination thereof.

The range of compositions available can be seen as extending even further when one considers that each M-atom position within the overall Mₙ₊₁Xₙ matrix can be represented by more than one element. That is, one or more type of M-atom can occupy each M-position within the respective matrices. In certain exemplary non-limiting examples, these can be (M^{A}ₓM^{B}_{y})₂C, (M^{A}ₓM^{B}_{y})₃C₂, or (M^{A}ₓM^{B}_{y})₄C₃, where M^{A} and M^{B} are independently members of the same group, and x+y=1. For example, in but one non-limiting example, such a composition can be (V_{1/2}Cr_{1/2})₃C₂.

### Electrochromic Devices

The construction, materials, and architectures used in electrochromic devices is known, though never in the context of using MXene materials as an electrochromic material. Typically, an electrochromic device comprises a transparent conductive electrode, an active electrochromic film, and ion conductor options), and an ion storage film. Such devices, and methods of making and using such devices, are disclosed and described, for example, in U.S. Pat. Nos. 10,088,729; 10,078,252; 10,061,176; 10,061,174; 10,054,833; 10,012,887; 10,012,885; 10,007,163; 10,001,689; 9,995,949; 9,977,306; 9,958,751; 9,946,137; 9,939,705; 9,939,704; 9,939,703; 9,939,702; 9,933,682; 9,933,681; 9,933,680; 9,904,138; 9,897,887; 9,897,885; 9,891,497; 9,882,201; 9,880,440; 9,874,762; 9,864,250; 9,857,656; 9,829,762; 9,823,536; 9,823,535; 9,823,484; 9,798,214; 9,798,213; 9,791,760; 9,785,031; 9,778,531; 9,759,975; 9,740,074; 9,738,140; 9,723,723; 9,721,527; 9,720,299; 9,720,298; 9,715,119; 9,711,571; 9,709,868; 9,703,165; and 9,701,671. The present disclosure encompasses any and all of the architectures and materials used in such devices, except that the electroactive films comprises at least one or more MXene.

### Illustrative Electrochromic Devices

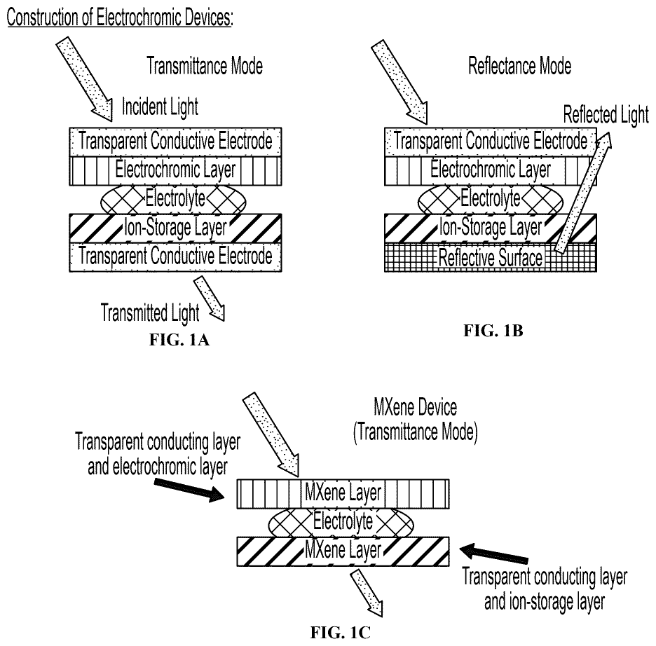

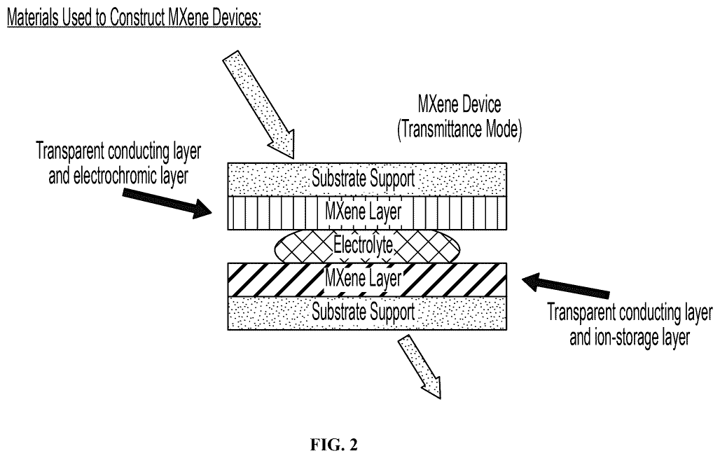

Some additional embodiments of the present disclosure are described below and in FIGS. 1 and 2:

FIG. 1 shows a schematic representing construction of electrochromic devices (side view) which include transparent conductive electrodes, an electrochromic layer, an ion-storage layer, and an ion-conducting layer (electrolyte) operating in either transmittance mode (FIG. 1A) and reflectance mode (FIG. 1B). In transmittance mode (FIG. 1A), incident light is absorbed and transmitted through the device, therefore, transparent electrodes are needed on both sides. In reflectance mode (FIG. 1B), incident light is reflected out of the device. The type and mode of the device determines the application. Devices employing MXenes can take advantage of MXenes' multiple functions (FIG. 1C) as the MXene thin film can act as one or both of a transparent conducting electrode/electrochromic layer and a transparent conducting electrode/ion-storage layer.

In the context of standard electrochromic devices:

Transparent Conductive Electrode can be an electron conductor and visibly transparent. Standards are transmitting 80% of incident light (in this case visible light) as well as achieve conductivities higher than 103 S/cm. Materials used include, but not limited to, indium tin oxide (ITO), transparent conductive oxides, conductive polymers, metal grids, carbon nanotubes (CNT's), graphene, etc. MXenes have previously been characterized to exhibit such characteristics and so would function well in this capacity

Ion-storage Layer: store ions and can be optically passive. Materials include, but are not limited to, graphene, CNT's, metal oxides, conductive polymers, and carbon materials.

Electrochromic Layer: conduct both ions and electrons and belong to a class of mixed conductors. Common materials used are tungsten oxide (WO₃), conducting polymers (polypyrrole, PEDOT, and polyaniline), viologen, and titanium oxide (TiO₂).

Ion-conducting Layer (electrolyte): ionic conductor, solid and liquid electrolytes are used. Liquid electrolyte devices are usually encapsulated in a laminated device. Electrolytes are used to separate the two electrode layers.

FIG. 2 provides a schematic of a MXene electrochromic device (side view). In some embodiments, MXene layers are supported by glass substrates, but could be any transparent substrate available (PET, plastics, quartz, etc.). The electrolyte (ion-conducting layer) is used to conduct ions between MXene layers and can be liquid, gel, or solid in state. Common electrolytes are used, including but not limited to, magnesium sulfate (MgSO₄), sulfuric acid (H₂SO₄), and phosphoric acid (H₃PO₄). Such electrolytes described as useful in previous patent applications directed to the use of MXenes are also expected to work well in this capacity. In FIG. 2, MXene is shown to be capable of acting as the transparent conducting electrode, ion-storage, and electrochromic layers.

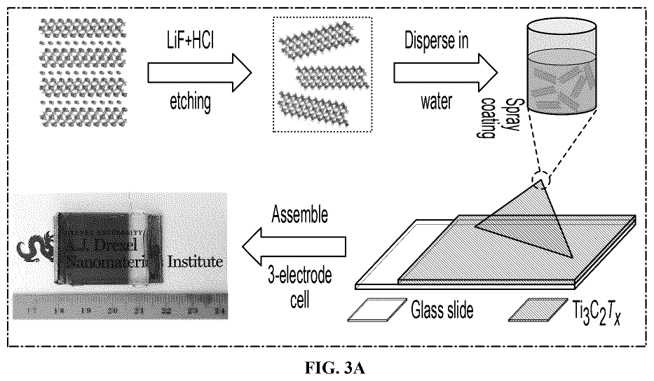

FIG. 3A-C provide a schematic illustration of Ti₃C₂ semitransparent film prepared by spray coating; FIG. 3A is the structure of Ti₃AlC₂ and Ti₃C₂, where Ti, Al, C, O, and H atoms are shown, and FIG. 3A also provides a schematic of electrode fabrication. FIG. 3B provides a schematic illustration of a 3-electrode cell for the in-situ tests. FIG. 3C provides digital images of the example device at different voltages in IM LiTFSI electrolyte and their related red-green-blue (RGB) values.

The suspension of monolayer Ti₃C₂ MXene was prepared by a previously reported approach. The lateral dimension of the flakes as generally in the range of hundreds of nanometers, and images evidenced the single-layer structure of the Ti₃C₂ flake, which showed highly agreement with the SEM image.

The semitransparent Ti₃C₂ thin film was prepared by spray coating the delaminated Ti₃C₂ suspension (˜2 mg/mL) onto a glass substrate. To catch the requirements of tests, its thickness/transmittance can be controlled by the time of spray coating. SEM images show that the Ti₃C₂ sprayed on glass is uniform with a thickness of ˜50 nm, which showed a transmittance about 60% at 550 nm. Raman spectroscopy was conducted to understand the surface environment. According to the previous density functional theory (DFT) simulations, the Raman peaks at 200 and 723 cm⁻¹ are correspondingly attributed to the Ti—C and C—C vibrations (A_{1g} symmetry) of the oxygen terminated Ti₃C₂O₂. The peak at 620 cm⁻¹ comes mostly from E_{g} vibrations of the C atoms in the OH-terminated Ti₃C₂. The peaks at 389 and 580 cm⁻¹ are attributed to the O atoms E_{g} and A_{1g} vibrations, respectively. The 282 cm⁻¹ are occurring due to the contribution of H atoms in the OH groups of Ti₃C₂.

A 3-electrode cell was assembled by using the Ti₃C₂ coated glass (Ti₃C₂-glass) as a working electrode, ITO coated glass (ITO-glass) as a counter electrode, silver wire as a reference electrode filled with different organic electrolyte for the in-situ tests, as shown in FIGS. 3A, 3B. Further, FIG. 3C shows the digital images of the as assembled cell tested in 1 M LiTFSI/PC electrolyte, which showed a reversible green-to −blue color change as the applied voltage changing from 0 to −2 V, indicating the potential electrochromic performance of Ti₃C₂ MXene. In the digital video (conducted as the voltage applying by cyclic voltammetry (CV) scanning at a scan rate of 10 mV/s between −2 and 0.2 V), color switched to blue from green gradually and recovered to green as the CV scanning back to 0 V.

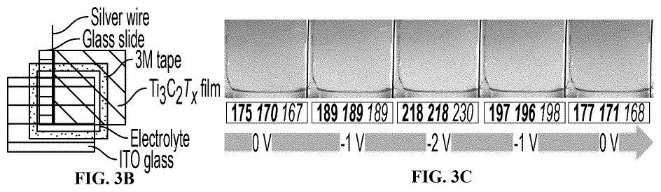

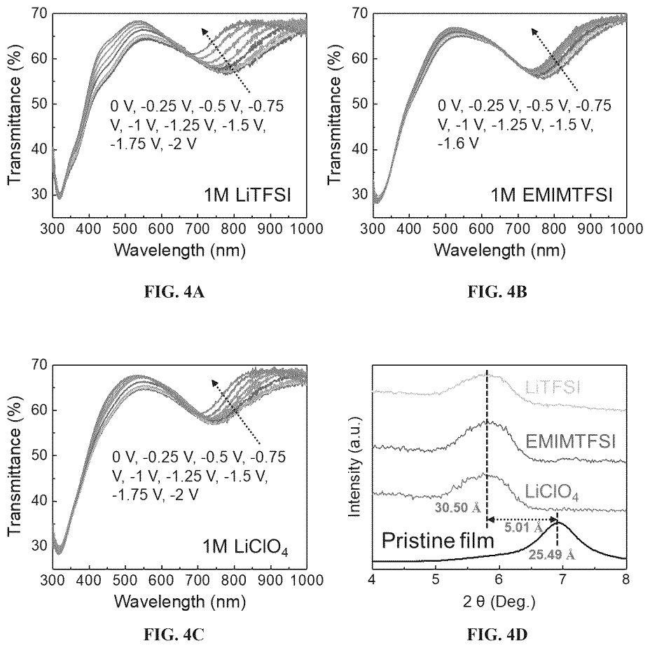

To quantify the optical color changes of the Ti₃C₂ films in LiTFSI/PC, its optical properties were evaluated by combining the electrochemical potentiostat with ultraviolet-visible (UV-vis) spectrophotometry, shown in FIG. 4A. The UV-vis data were collected at different potential during the CV test between its stable potential window (−2 to 0.2 V) at 2 mV/s. Its initial transmittance curve exhibits a trough at 780 nm (T) with a transmittance of 57%, a crest at 550 nm (C1) with a transmittance of 64% and a shoulder at 428 nm (S) with a transmittance of 53%. As the voltage increased from 0 to −2 V, a blue shift occurred on its trough and crest, with the transmittance enhanced obviously. A new crest appeared at 929 nm (C2) with a transmittance of 68% when the voltage reaches −1.5 V. At the voltage of −2 V, the T shifted to 680 nm with transmittance of 61%, demonstrating a blue shift of 100 nm and 4% of the increased transmittance. Such a wide shift should be responsible for the visible green-to-blue color change. The C1 shifted to 536 nm with the transmittance increased to 68%, while the C2 shifted to 854 nm keeping the transmittance constant. Additionally, the transmittance of S showed an increase of 8% without shift. While the CV test was scanning back, its transmittance curve went back to the initial state, indicating the blue-to-green color change process. The transmittance exhibited an inverted change compared with negative voltage.

The transmittance at 450 nm and 810 nm were selected to evaluate the cycle stability of the Ti₃C₂ semitransparent film by applying a pulse voltage of −2 and 0.2 V and repeating for 300 times, during which the transmittance data were collected. These data demonstrated the stable change of transmittance during the electrochemical cycle, indicating the high electrochemical stability of Ti₃C₂ in organic electrolyte. To further confirm its electrochemical stability, the X-ray diffraction (XRD) patterns before and after long-term cycle were conducted, and no obvious phase transformation or oxidation can be found after cycles, evidencing its excellent cycle stability. Ex-situ X-ray photoelectron spectroscopy (XPS) was used to evaluate the stability of Ti₃C₂ during the electrochemical process in this 3-electrode cell. Initially, the most prominent Ti 2p component is the (OH, O)—Ti(II)—C component, where the majority of Ti in the MXene has a valency of Ti²⁺. When LiTFSI was introduced to the system, there is a slight relative increase in the amount of TiO₂ but reduction of some of the Ti in the MXene results in an increased amount of (OH, O)—Ti—C. After EMIMTSFI is introduced to the MXene, the relative amount of TiO₂ increases, but the most prominent MXene component remains (OH, O)—Ti—C.

Ti₃C₂ has exhibited an obvious electrochromic behavior in acidic aqueous electrolyte induced by intercalation of proton. Recently, strong lithium intercalation was observed in Ti₃C₂ in an organic system with large voltage window. Thus, it was assumed that such a significant color change in LiTFSI is because of the intercalation of Li⁺ ions. Without being bound to any particular theory, the Li-ion intercalation into Ti₃C₂ may introduce the expansion of its interlayer space. Without being bound to any particular theory, the intercalation process can be accompanied by redox reactions, during which the intercalated Li-ions may interacted with selected terminations on its surface.

Thus, EMIMTFSI was selected, because of its bigger cation size compared to Li ions, to evaluate the effect of the changed interlayer space. However, the in-situ UV-vis data tested in 1M EMIMTFSI/PC electrolyte showed a reversible but much smaller change (see FIG. 4B), with a stable potential window from −1.6 to 0.6 V. There is no C2 generated even the applied voltage was increased to −1.6 V. The blue shift for T1 and C1 was 33 and 18 nm, displaying a transmittance change of 1% and 2%, respectively. Also, almost no transmittance change was observed on the S. 1M LiClO₄/PC electrolyte, which is a common electrolyte used in electrochromic devices, was used to reveal the effects of anion in a stable potential window of −2 to 0.2 V, whose UV-vis data were shown in FIG. 4C. As for T, a 39-nanometer blue shift was noticed, with 2% change for its transmittance, while the C1 showed a blue shift of 24 nm accompanied by a transmittance change of 3%. Interestingly, the C2 appeared at 982 nm when the potential reached −0.5 V, whose transmittance was 67%. It shifted to 867 nm as the voltage increased to −2 V, with the transmittance adding 2%. A transmittance change of 4% was observed. Similarly, the UV-vis data tested at positive voltage in EMIMTFSI and LiClO₄ showed a small change.

The in-situ XRD was conducted for these three electrolytes to demonstrate the relationship between the optical change and interlayer space, as shown in FIG. 4D. The (002) peak of the MXene electrode was at the 6.93° indicating an interlayer space of 25.49 Å. After the pre-cycling, the (002) peak shifted to 5.79° for all of these three electrolytes (interlayer space of 30.50 Å), keeping constant while the applied voltage increased during the following test. The optical property of the Ti₃C₂film changed without the interlayer space change, indicating that there is no relationship between the electrochromic effect and expanded interlayer space. The electrolyte intercalated into the Ti₃C₂ layers to enlarge its interlayer space, after which redox reactions dominated the electrochemical process that induced the electrochromic effect.

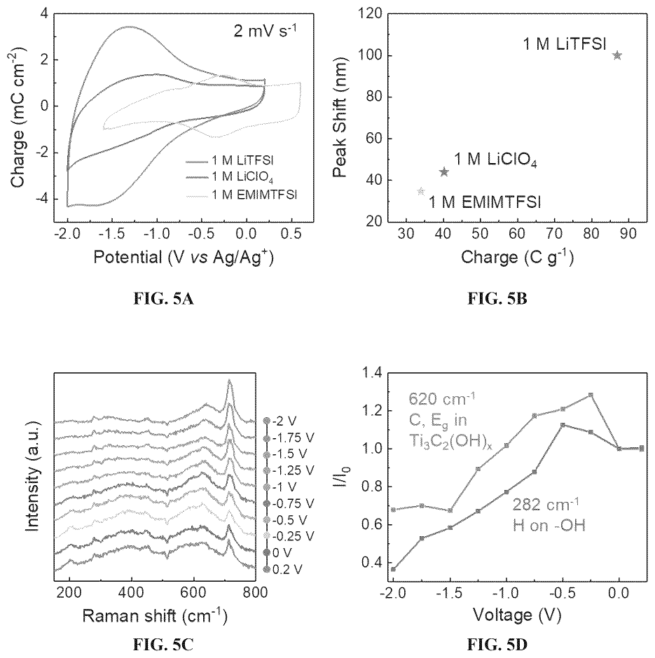

The discharge capacities at 2 mV/s, calculated by integrating the anodic scans of the cyclic voltammetry curves (CVs) in FIG. 5A, are 86.9 C g⁻¹, 44 C g⁻¹ and 35 C g⁻¹ in LiTFSI, LiClO₄ and EMIMTFSI, respectively. The charge capacities and the peak shift of UV vis spectrum are summarized in FIG. 5B, in which the optical change showed a positive correlation with the charge capacity. This further confirmed that the color change is because of the redox reactions during the electrochemical process. To facilitate a more fundamental understanding of the charging process of Ti₃C₂ in 1 M LiTFSI/PC, in-situ electrochemical Raman spectroscopy measurements were conducted to track the physical or chemical processes during cycling (see FIG. 5C). Voltage-dependent changes in Raman bands assigned to Ti₃C₂ were recognized. FIG. 5D shows its corresponding statistic data of the peak intensities at 620 and 282 cm⁻¹, corresponding to the E_{g} vibration of the C atoms in Ti₃C₂(OH)₂ and H atoms in the —OH groups, respectively. The intensity of the vibration for H on —OH groups started to decrease when Ti₃C₂(OH)₂ was charged to −0.5 V, which may be correlated to the onset of a state where the intercalated Li ions start bonding onto —OH groups. It then reached a minimum intensity of 36% at −2 V, corresponding to the fully charged state. Accordingly, the intensity corresponding to E_{g} vibration of the C atoms in Ti₃C₂(OH)₂ also showed a decrease of 32%, which agrees with the decrease of the H variation. These results indicated that the electrochromic effect of Ti₃C₂ in LiTFSI is because of the redox reactions between Li ions with the surface —OH groups, which induced the tunable change of the surface plasmonic effect of Ti₃C₂.

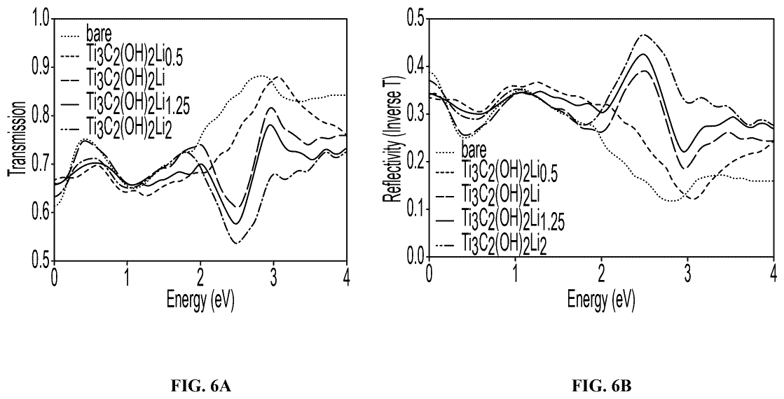

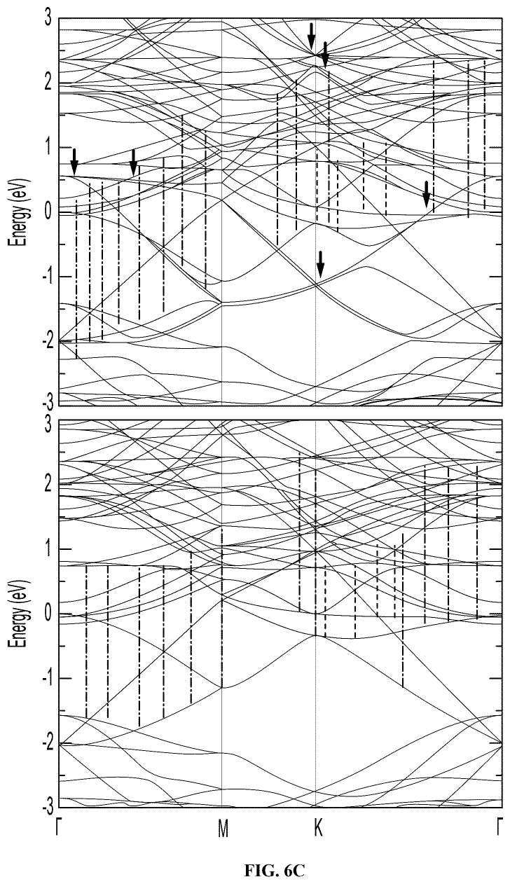

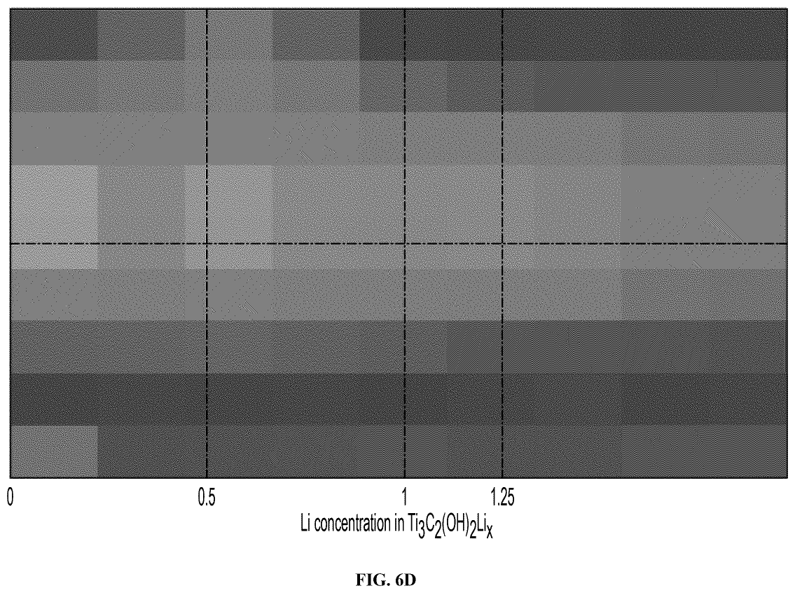

For Ti₃C₂ MXene, others have reported that the composition of its termination is mainly consist of hydroxyl group, and we therefore studied the optical transmission that is shown in FIG. 6A, 6B, structure as well as electronic structure of Ti₃C₂(OH)₂Liₓ. The optical transmission (T) could refer to the inverse of reflectivity (R), which is also proportional to the optical absorption (Ab). Now, the observed variance of optical transmission with a clear trend is subsequently ascribed to the inverse relation to the optical excitation, which can be derived in density functional theory. In the perspective of excitation effects, an excitation peak at ˜2.5 eV appears when the Li concentration is becoming high, which could be summarized from the features of electronic excitation on the basis of FIG. 6B. We collect the above calculated fingerprints from the optical reflectivity and move forward to the electronic structure analysis, which is shown in FIG. 6C.

Following the optical properties, we therefore focus on the observed three fingerprints at 1.1, 2.5 eV and take likely inter-band excitation paths with the corresponding excitation energies as the indicators of the Li intercalation induced effects shown in FIG. 6C. For the excitations with an energy of 1.1 eV, the primary excitations can be only found along the K-Γ path, where the band with Li intercalation does not develop any emerging excitation possibilities, contrast to the band in the lower panel showing the non-Li intercalation case. However, for the excitations with about 2.5 eV, the corresponding occurrences (in green) can be situated in a wider k-space, such as the path along Γ-M in addition to the K-Γ path in the case of non-Li intercalation. Notably, the Fermi energy has been shifted upward as the Li ion are intercalated into the MXene layers, and more importantly, a few bands appear with the increasing concentration of Li ions, such as the bands at Γ with the energy of 0.6 eV as well as the bands along M-Γ with the degeneracy at K point in an energy of −1.2 eV. The Li dominant band in the regime between −2 and 0 eV with the degeneracy at K point further contribute the excitations as of 2.5 eV. Moreover, not only the Li states in the valence band, the Li dominant bands at Γ can also serve as the host for the excited electrons. Hereafter, the Li intercalation induced states and the hybridization states play a significant role of creating more and more excitation possibilities with the exciting energies at 2.5 eV, respectively.

As the undergoing of Li intercalation, the interaction between Li atoms and the MXene surface should be the core of inducing the optical excitations. Here, the atom projected DOS was analyzed to show the Li concentration dependent changes: DOS as well as the valence charge of Ti layers. Before the intercalation, there is a 1 eV width pseudo-gap beneath the Fermi energy, which is caused by the strong hybridization between Ti—C as well as the hydroxyl termination. In this energy window, it is shown that Li atoms primarily contribute states to this pseudo-gap regime as well as little states in the lower valence band (see the cyan curves in b-e). For x>1, there is a Li peak situated at about −2 eV, which is very likely to be excited to the states at ˜0.5 eV dominant by C—OH states. Such observed excitation mechanism is just the one shown in the excitation paths shown in the band structure. Notably, both are corresponding to exactions with an energy of 2.5 eV. Clearly, the intercalated Li atoms directly participate the excitations and further activate more excitation paths, which is in accordance with the observation related to FIG. 6C. Hereby, such phenomenon of electrochromic is driven by the Li intercalation and the induced states in the valence band and the hybridization states near the Fermi energy.

On the other hand, the evolution of valence charge of Ti layers is another interesting angle to carry out an investigate due to its close relation between the variance of charge and the capacitance, referring to the capability of charge storage in this perspective. FIG. 6D shows a statics plot of the varying Bader charges of three Ti layers with the increase of Li concentration. Since in the structural models, the Li atoms are mostly placed in the upper layer (x<1), when x is from 0.5 to 1, the Bader charge is experiencing a more evident change for the upper Ti layer. As indicated by the color bar, the changes of the charges of Ti atoms are however marginal, particularly for the middle layer, which is due to that they are somewhat less affected by the Li intercalations. Compared with the middle layer, the surface Ti layers are showing smaller numbers, indicating a lager deviation from the elementary Ti atoms. This finding is because of the role of surface termination, which alters the electronic structure of surface Ti atoms. The explanations to the slight changes on the valence charge can be referred to the DOS plots, where the Ti states are not participating on the hybridization with Li atoms, so that the Li intercalation will not bring much effects on the charge of Ti atoms.

### Exemplary Procedures

### Material Characterization

Scanning Electron Microscope (SEM) images were conducted at 10 kV (Zeiss Supra 50VP, Germany). UV-vis measurements (Evolution 201 UV-vis spectrophotometer, Thermo-Fischer scientific) were performed on different voltages for the various electrolytes to study the optical properties. X-ray diffraction (XRD) patterns were measured by a powder diffractometer (Rigaku Smart Lab, USA) with Cu Ka radiation at a step size of 0.04° with 0.5 s dwelling time. Raman spectra were recorded using a Renishaw Raman microscope with LEICA CTR6000 setup with 514 nm laser, 1800 lines mm⁻¹ grating at 10% of maximum intensity and 50× objective. The in-situ Raman spectra and XRD patterns were collected during the CV scanning at 2 mV/s, after stabilizing for 10 cycles. The electrochemical tests were conducted at room temperature using a BioLogic SP 150 potentiostat.

Synthesis of Ti₃C₂Tₓ MXene

All chemical reagents were used as received without further purification. The MAX phase of Ti₃AlC₂ powder was obtained from Murata Manufacturing Co., Ltd, Japan (particle size<40 micrometer). Ti₃C₂ MXene was synthesized by the previous reported method. In short, the etching solution was prepared by adding 1 g of LiF (Alfa Aesar, 98+%) to 10 mL of 9 M HCl (Fisher, technical grade, 35-38%), followed by stirring for 5 minutes. 1 g of Ti₃AlC₂ powder was slowly added to the above etchant at 35° C. and the solution was stirred continuously for 24 h. The resulting acidic suspension of Ti₃C₂ was washed with deionized (DI) water until it reached pH˜6 through centrifugation at 3500 rpm (5 minutes per cycle) and decanting the supernatant after each cycle. Then, the sediment was dispersed into DI water and sonicated in bath sonication for 1 h, followed by centrifugation for 1 h at 3500 rpm. At last, the supernatant was collected for the further use.

Its concentration was calculated by vacuum-assistant filtrating 1 mL of the as prepared Ti₃C₂suspension, followed by weighing to know the mass of Ti₃C₂ after drying.

Preparation of Semitransparent Ti₃C₂ Film on Glass

A typical spray coating process was used to prepare the semitransparent Ti₃C₂ films for the color changeable electrode. Firstly, the glass substrates (Fisher Scientific) were cleaned by bath sonication for 30 minutes in ethanol, followed by drying in an oven at 60° C. Then, the cleaned glass substrates were treated by plasma (Tergeo Plus, Pie Scientific) at 50 W with a mixture of O₂/Ar at 3 and 5 sccm for 5 minutes to make their surface hydrophilic. After that, the glass substrates were adhered onto a 45°-sloped stage by double-side tape. And a Ti₃C₂ suspension with a concentration of 2 mg/mL was used to spray. The thickness was controlled by spraying for different time. At last, the as prepared semitransparent Ti₃C₂ films were dried by vacuum oven at 90° C. overnight to remove the water.

Fabrication of a 3-electrode Cell

To fabricate the 3-electrode cell for the in-situ tests, the as prepared Ti₃C₂-coated glass electrode was used as work electrode, the ITO-coated glass (MSE Supplies LLC) was used as counter electrode, the silver wire was used as reference electrode and different organic electrolytes was used. At first, the work and counter electrodes were cut into 2*3 cm². Then, some of the Ti₃C₂ was scraped off from the glass to make a blank part about 2*0.5 cm² on the one side. Four stripes of 3M 4910 VHB double-side tape was adhered onto the Ti₃C₂side of the work electrode to make a groove, with a silver wire cling to the blank part. Afterwards, the ITO-coated glass was pressed onto the groove, with the ITO side face to the work electrode, to make a cavity for the electrolyte. Finally, the cell without electrolyte was transferred into an Argon protected glovebox to inject electrolyte by a 1 mL injector.

### Additional Disclosure

Solution processable two-dimensional transition metal carbides, commonly known as MXenes, have drawn much interest due to their diverse optoelectronic, electrochemical and other useful properties. These properties have been exploited to develop thin and optically transparent microsupercapacitors. However, color changing MXene-based microsupercapacitors have not been explored. In this study, we developed titanium carbide—poly(3,4-ethylenedioxythiophene) (PEDOT) heterostructures by electrochemical deposition using a non-aqueous monomeric electrolytic bath. Planar electrodes of such hybrid films were carved directly using an automated scalpel technique. Hybrid microsupercapacitors showed five-fold areal capacitance and higher rate capabilities (2.4 mF cm⁻² at 10 mV/s, retaining 1.4 mF cm⁻² at 1000 mV/s) over the pristine MXene microsupercapacitors (455 μF cm⁻² at 10 mV/s, 120 μF cm⁻² at 1000 mV/s). Furthermore, the electrochromic behavior of PEDOT/Ti₃C₂microsupercapacitors was investigated using in-situ UV-vis and resonant Raman spectroscopies. A high-rate color switch between a deep blue and colorless state is achieved on both electrodes in the voltage range of −0.6 to 0.6 V, with switching times of 6.4 and 5.5 s for bleaching and coloration, respectively. This disclosure provides new avenues for developing electrochromic energy storage devices based on MXene heterostructures.

Solution processable conductive two-dimensional (2D) nanomaterials, termed MXenes, are useful as TCEs as they are hydrophilic, enabling ease of formation of transparent thin films on a variety of substrate platforms. Key features of MXenes that are relevant to TCEs include optical transparency in thin films and excellent electrical conductivity. Further, the redox active metal-oxide like surface and conductive carbide core of MXenes are responsible for their excellent ultra-high rate charge storage capability, especially in acidic electrolytes. High-quality MXene flakes (1-2 micrometer) obtained through minimally intensive layer delamination (MILD) method showed electrical figure of merit up to 14. Diverse physicochemical properties of MXenes enable a multitude of properties including transparency in the visible wavelength range, electronic conductivity and energy storage capabilities—key for transparent energy storage applications. Recently, transparent MXene-based microsupercapacitors have been demonstrated with excellent capacitive storage. Previous work characterized the optoelectronic properties of MXene thin films using ultraviolet-visible (UV-vis) spectroscopy and correlated this data with the electrical conductivity of the films.

Poly(3,4-ethylenedixoythiophene) (PEDOT), an electrochromic conducting polymer, shows remarkable chemical and electrochemical stability and exhibits transparency in the doped state, which is suitable for single color changing electrochromic devices. However, Ti₃C₂ MXene is electrochemically stable only at cathodic potentials (<0.2 V (vs. Ag/AgCl)), which is a limitation for electrochemical deposition of conducting polymers at anodic potentials (>0.8 V vs. Ag/AgCl). The combination of those materials has demonstrated a remarkably fast electrochemical charge/discharge rate.

In the following examples, acetonitrile was employed as the solvent to exclude the anodic oxidation of MXene during depositing PEDOT on MXene thin films. An automated scalpel lithography was used for direct fabrication of co-planar electrochromic microsupercapacitors (MSC) in a mask-less and resist-free manner. Simultaneous electrochemical storage and electrochromic functions of PEDOT/Ti₃C₂ MSC were demonstrated at a high scan rate of 5000 mV/s. Furthermore, in-situ UV-vis and resonant Raman spectroscopies were employed to probe the mechanism of electrochromic behavior of PEDOT/Ti₃C₂ heterostructures.

### Material and Methods

Synthesis of Ti₃C₂MXene

All chemical reagents were used as received without further purification. Layered ternary carbide Ti₃AlC₂ (MAX phase) powder was obtained from Carbon-Ukraine, Ukraine (particle size<40 micrometer). Ti₃C₂ MXene was synthesized by etching Ti₃AlC₂ in a solution produced by adding lithium fluoride (LiF) salt to hydrochloric acid (HCl) solution. The etching solution was prepared by adding 1 g of LiF (Alfa Aesar, 98+%) to 20 mL of 9 M HCl (Fisher, technical grade, 35-38%), followed by stirring for 5 minutes. 1 g of Ti₃AlC₂ powder was slowly added over the course of a few minutes to the above etchant at room temperature and the solution was stirred continuously for 24 h. The resulting acidic suspension of Ti₃C₂ was washed with deionized (DI) water until it reached pH˜6 through centrifugation at 3500 rpm (5 minutes. per cycle) and decanting the supernatant after each cycle. Around pH˜6, a stable dark supernatant of Ti₃C₂ was observed and collected after 30 minutes of centrifugation at 3500 rpm. The concentration of Ti₃C₂ solution was measured by filtering a specific volume of colloidal dispersion through a polypropylene filter (3501 Coated PP, Celgard LLC, Charlotte, NC), followed by overnight drying under vacuum and dividing the dried film's weight over the volume of the colloidal dispersion.

### Spray Coating of MXene Films

Glass substrates (Fisher Scientific) were cleaned with a soap solution to remove any grease followed by ultrasonication in deionized water and ethanol sequentially for 15 minutes each and then dried by blowing compressed air. The cleaned glass substrates were then plasma cleaned (Tergeo Plus, Pie Scientific) at 50 W with a mixture of O₂/Ar at 3 and 5 sccm for 5 minutes to make the surface hydrophilic. These glass substrates were then spray coated with MXene using a MXene dispersion with a concentration of 2 mg/mL. The spraying time varied to produce films with thicknesses ranging from 20-70 nm. Thin films were finally kept in a desiccator overnight before characterization.

Electrochemical Deposition of Poly(3,4-ethylenedioxythiophene)

To prepare the solution for electrodeposition, 100 μL of 3,4-Ethylenedioxythiophene (EDOT, 97%, Sigma-Aldrich) was added into 50 mL of 0.1 M LiClO₄/acetonitrile solution. Then, the as-prepared Ti₃C₂-coated glass slide was immersed into the above solution and a graphite rod was used as a counter electrode and silver wire as a reference electrode. A constant potential of 1.1 V was applied by a Bio-logic VMP3 workstation. The as-prepared PEDOT/Ti₃C₂ semi-transparent electrode was carefully washed by acetonitrile to remove the extra EDOT and LiClO₄, followed by drying in a vacuum oven under 60° C. for 6 h.

### Fabrication of Electrochromic Microsupercapacitors

AxiDraw (IJ Instruments Ltd.), and its associated extension in Inkscape 0.91, was used as an automatic X-Y control stage for fabricating MXene microsupercapacitors. Commercially available scalpels were loaded onto the slot of an AxiDraw to engrave square wave patterns resulting in interdigitated semi-transparent MXene patterns.

Preparation of PVA/H₂SO₄ Gel Electrolyte

1 g of polyvinyl alcohol (PVA) (Alfa Aesar, 98%) was dissolved in 10 mL DI H₂O at 90° C. for 1 h after which the transparent gel was obtained. 1 g (0.6 mL) of concentrated sulfuric acid (Alfa Aesar) was added to 10 wt. % PVA gel and stirred for 30 minutes to obtain 1 M PVA/H₂SO₄.

### Material Characterization

UV-vis measurements (Evolution 201 UV-vis spectrophotometer, Thermo-Fischer scientific) were performed on different MXene and PEDOT/MXene films to study the optical properties. Cross-sectional images of Ti₃C₂ and PEDOT/Ti₃C₂ coatings were taken using a scanning electron microscope (SEM) (Zeiss Supra 50VP, Germany). X-ray diffraction (XRD) patterns were measured by a powder diffractometer (Rigaku Smart Lab, USA) with Cu K_{α} radiation at a step size of 0.04° with 0.5 s dwelling time. Raman spectra were recorded using a Renishaw Raman microscope with LEICA CTR6000 setup with 514 nm laser, 1800 lines mm⁻¹ grating at 10% of maximum intensity and 50× objective. Spectra were collected with a dwell time of 120 s and 2-4 accumulations. The electrical conductivities of Ti₃C₂ and PEDOT/Ti₃C₂ thin films were measured using a four-point probe (ResTest v1, Jandel Engineering Ltd., Bedfordshire, UK) with a probe distance of 1 mm.

### Electrochemical Measurements

The electrochemical tests (cyclic voltammetry (CV), galvanostatic charge-discharge (CD), electrochemical cycling stability) were conducted at room temperature using a VMP3 electrochemical workstation (Bio-Logic, France).

### In-situ UV-Visible Measurements

Clean glass slides were used for 100% transmittance background correction. The transmittance was recorded from 300 to 1000 nm with 1 nm resolution using deuterium and tungsten lamps. In-situ UV-vis spectra were conducted by combining the UV-vis spectrometer with a BioLogic SP 150 potentiostat. The UV-vis spectra under different voltages were recorded while running cyclic voltammetry (CV) at 10 mV/s.

### In-situ Raman Measurements

A two-electrode open system was used for the in-situ Raman spectroscopy measurements. The as-prepared PEDOT/Ti₃C₂ MSC was connected to a BioLogic SP 150 potentiostat and placed on the test stage. The laser was focused on one of the electrodes. The Raman spectra at different voltages were recorded during CV scan at a scan rate of 10 mV/s.

### 2-Electrode Configuration (Device Measurements)

Areal capacitance was calculated using equation (1):

$${C}_{A} = \frac{1}{VAv} \int idV \qquad ( 1 )$$

where i is the current (mA), V is the voltage window of the device (V), v is the scan rate (mV/s), A is the geometrical footprint area of the device including total area of finger electrodes and interspace regions. S idV is the integrated area over the discharge portion of the corresponding CV scan.

Volumetric and areal energy and power densities were calculated using equations (2) and (3):

$$Energy density , {E}_{V} = \frac{1}{Γ} \int iVdt \qquad ( 2 )$$

$$Power density , {P}_{V} = \frac{{E}_{V}}{Δ t} \qquad ( 3 )$$

Where Γ is the area or volume of the device and Δt is the discharge time(s).

### Exemplary Results

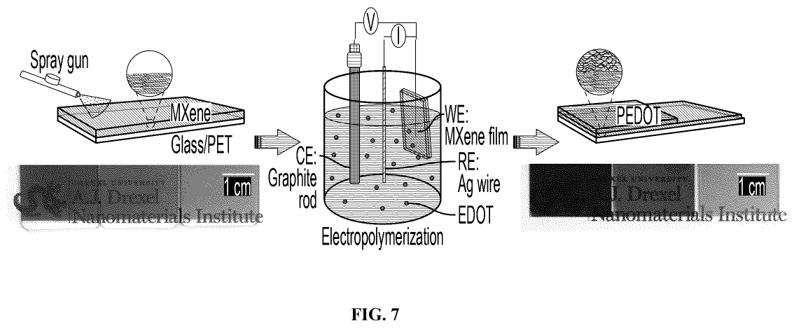

The schematic shown in FIG. 7 illustrates the process of depositing Ti₃C₂/PEDOT thin films onto glass substrates. For spray coating, Ti₃C₂ was synthesized through the minimally intensive layer delamination (MILD) method as reported previously, and a colloidal solution of Ti₃C₂ in water was collected. It was demonstrated that pre-intercalated hydrated Li-ions assist in delaminating MXene flakes through manual shaking. The colloidal stability of such MXene dispersions is attributed to its negative zeta potentials, originating from surface functional groups (Tₓ: —OH, —O, —F, —Cl). During the spray coating process, instantaneous drying causes evaporation of water, producing restacked MXene flakes as a continuous thin film. It is possible to control the thickness of MXene films by adjusting the concentration of the MXene dispersion and the spraying duration. Typical sheet resistance values of MXene films vary from 20 to 100 Ω/sq for the thicknesses ranging from 70 to 20 nm. The as-prepared MXene thin films have transmittance values varying from 80% to 54% when the thickness varies from 20 to 40 nm.

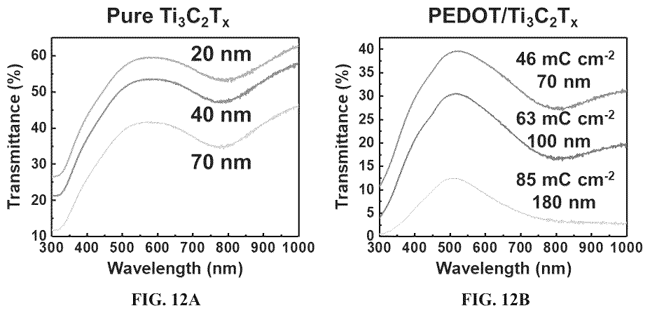

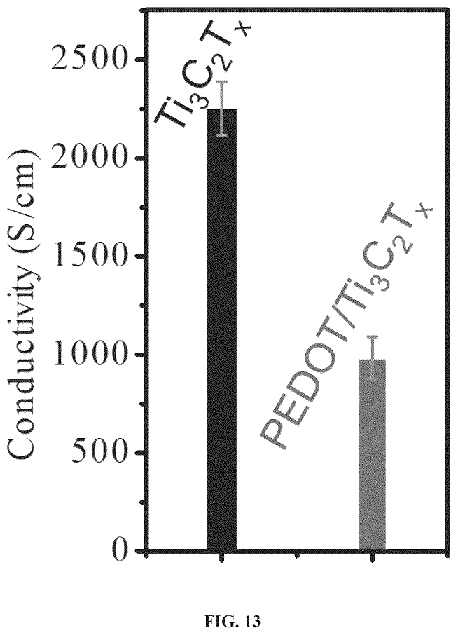

Considering its transmittance and conductivity together, spray-coated MXene thin films with a thickness of about 40 nm and transmittance of 54% at 550 nm were used as TCEs for depositing PEDOT. MXene serves as a TCE due to its ability to be electrically conductive while being optically transparent. A non-aqueous electrolytic bath (EDOT+0.1 M LiClO₄+acetonitrile) was used. The corresponding digital photographs of Ti₃C₂ and PEDOT/Ti₃C₂ thin films were shown in FIG. 7 and the UV-vis spectra were shown in FIG. 12.

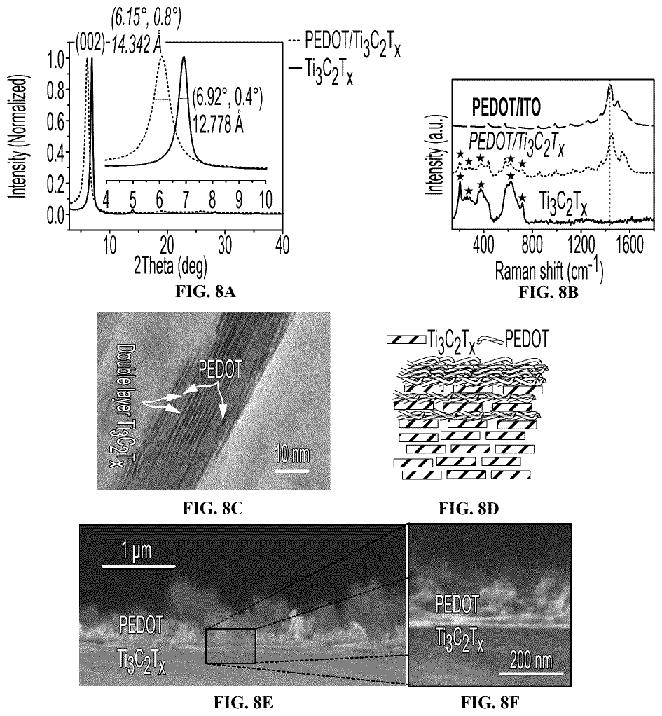

The structural aspects of PEDOT/Ti₃C₂ and Ti₃C₂ were investigated using X-ray diffraction (XRD). The (002) peak of Ti₃C₂ was prominent after the electrochemical deposition of PEDOT, signifying that the alignment of MXene layers was preserved (FIG. 8A). However, a shift towards lower 2θ was observed for PEDOT/Ti₃C₂ compared to Ti₃C₂. The apparent increase in the d-spacing up to 16 Å with nearly double the full width at half maximum (FWHM) of the (002) peak was observed for PEDOT/Ti₃C₂ with respect to pristine Ti₃C₂. Based on our previous work, polar solvents such as acetonitrile and propylene carbonate may intercalate spontaneously between the MXene layers. This could lead to penetration of solvated EDOT monomers into the top layers of MXene flakes. Such kind of expansion of MXene layers is beneficial for better accommodation and faster transport of ions between otherwise re-stacked MXene layers. Based on Raman spectra, the chemical nature of PEDOT grown on both MXene and ITO surfaces through electrochemical deposition remains the same, as shown in FIG. 8B. The most intense peak at 1439 cm⁻¹ is due to the symmetric stretching of Cα=Cβ which provides information about the level of oxidation of PEDOT. The bands at 1514 cm⁻¹ is due to asymmetric Cα=Cβ stretching; 1359 cm⁻¹ corresponds to C_{β}-C_{β} inter-ring stretching, 1257 cm⁻¹ represents C_{α}-C_{α} inter-ring stretching, 1116 cm⁻¹ is due to C—O—C deformation, 982 cm⁻¹ represents C—C anti-symmetrical stretching mode, 700 cm⁻¹ corresponds to symmetric C—S—C deformation, 571 cm⁻¹ due to oxy-ethylene ring deformation. In the case of PEDOT/Ti₃C₂. C_{α}=C_{β} stretching peak shifts to higher wavenumber, possibly due to electrostatic attachment of the negatively charged MXene surface with the PEDOT moieties. The PEDOT intercalated fibers between MXene layers was further confirmed by high-resolution transmission electron microscopy (HRTEM) (FIG. 8C), from which some of the confined PEDOT chains between MXene layers can be visualized. The schematic shown in FIG. 8D illustrates the PEDOT/MXene heterostructure where the intimate coupling between top MXene layers and PEDOT chains is beneficial for synergistic improvement in electrochemical performance. The morphology of PEDOT is seen as small fibroid-type particles glued to the MXene surface (shown in FIG. 8E). The thickness of the PEDOT layer was approximately 70-100 nm, depending on the deposition duration. As shown in FIG. 8F, dense deposition of PEDOT on top of the MXene surface and the overall conductivity of PEDOT/Ti₃C₂ are also influenced by the intrinsic electrical conductivity of PEDOT deposited during this process.

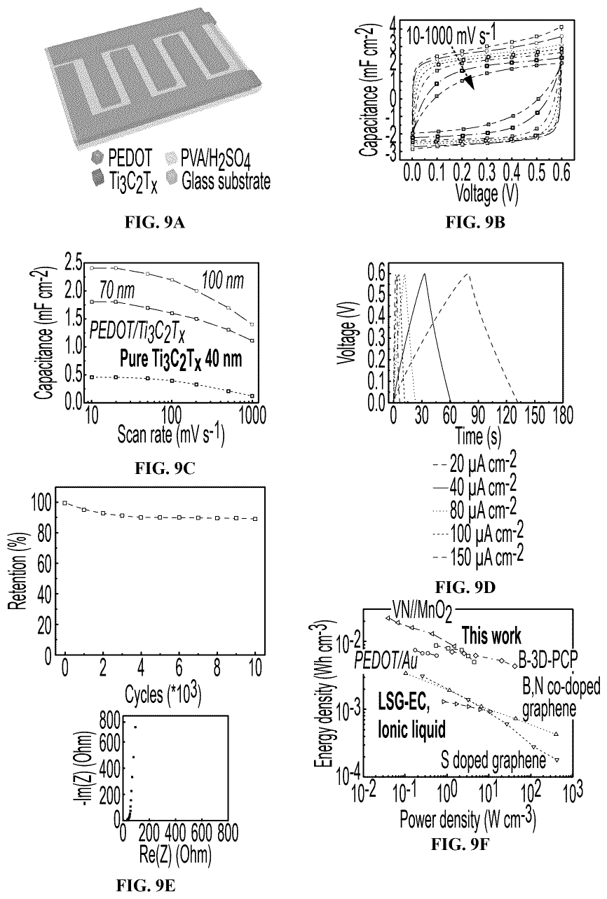

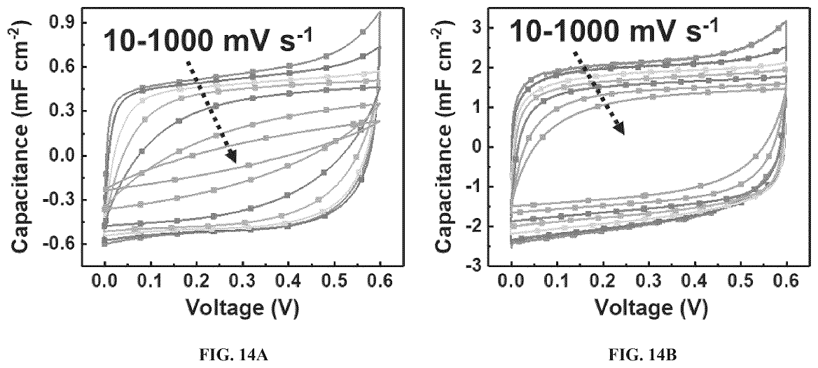

The schematic in FIG. 9A shows the PEDOT/Ti₃C₂ microsupercapacitor (MSC) device configuration. The pattern was fabricated by the automated scalpel engraving technique as described previously. Due to the superior electronic conductivity of MXene compared to PEDOT, the PEDOT is presumed to primarily contribute to the charge storage while MXene serves as a current collecting layer. Pure 40-nm MXene films studied in this work had conductivity of ˜2500 S/cm, while the PEDOT-MXene film of 100 nm thickness had the conductivity of ˜1000 S/cm. During the charging process, the positive PEDOT electrode was doped by SO₄⁻² or bisulfate ions, while the protons intercalated into the negatively polarized PEDOT electrodes. Anion doping causes the oxidation of PEDOT while cation doping causes the reduction of PEDOT. Doped PEDOT is more conductive than undoped PEDOT and accordingly a color contrast is observed between the fingers. To evaluate electrochemical performance, cyclic voltammetry (CV) and galvanostatic charge-discharge (GCD) measurements were conducted. FIG. 9B shows the typical CV curves of (100 nm) PEDOT/Ti₃C₂ MSC in the voltage window of 0-0.6 V at various scan rates from 10 to 1000 mV/s. The rectangular shape was maintained even at a scan rate of 1000 mV/s due to fast redox reactions related to doping/dedoping processes at the surface of the conducting polymer electrodes. On the contrary, the CV curves of pristine Ti₃C₂ and 70 nm PEDOT/Ti₃C₂ MSC, shown in FIG. 14, exhibit a much lower capacitance compared to 100 nm PEDOT/Ti₃C₂ MSC. As expected, capacitive performance of the device was improved by increasing the deposition of PEDOT. Compared to the previously reported electrochromic MSCs employing metal current collectors, our PEDOT/Ti₃C₂ MSC exhibited quite rectangular CV curves, signifying good ohmic coupling between PEDOT and Ti₃C₂Tₓ. As shown in FIG. 9C, the areal capacitance of the PEDOT/Ti₃C₂Tₓ and pristine Ti₃C₂ MSCs were compared. Notably, for the 100 nm device, a high capacitance of 2.4 mF cm⁻² was achieved at 10 mV/s, retaining 58% (1.4 mF cm⁻²) at a scan rate of 1000 mV/s, while for pristine Ti₃C₂ device is 455 μF cm⁻² at 10 mV/s, with a 26% retention (120 μF cm⁻²) at 1000 mV/s. Moreover, for the 70 nm device, capacitance of 1.8 mF cm⁻² at 10 mV/s was observed, retaining 61% (1.1 mF cm⁻²) at 1000 mV/s. Such a high-rate performance could be attributed to the high ionic conductivity of the heterostructure of metallic Ti₃C₂ and conducting PEDOT and the enlarged interlayer space of Ti₃C₂ by the intercalation of PEDOT.

The GCD curves of the (100 nm) PEDOT/Ti₃C₂ MSC at different current densities are shown in FIG. 9D. Furthermore, we evaluated its electrochemical cycling stability by repeating CVs for 10,000 times at 100 mV/s. As shown in the upper panel of FIG. 9E, 90% of the capacitance was retained after 10,000 cycles at a Coulombic efficiency of 100%. The lower panel of FIG. 9E shows a Nyquist plot for the PEDOT/Ti₃C₂ MSC, from which the vertical line in the low-frequency region is an indication of typical capacitive behavior. A low interfacial resistance was evident, as there is no semi-circle in the high frequency region. The Ragone plot, shown in FIG. 9F, demonstrates the energy and power density of the 100 nm PEDOT/Ti₃C₂ MSC. Notably the 100 nm PEDOT/Ti₃C₂ MSC delivered a specific volumetric energy density of up to 8.7 mWh cm⁻³ at a power density of 0.55 W cm⁻³, also providing high power density of 4.5 W cm⁻³ at 5.0 mWh cm⁻³, which is superior to activated carbon and graphene-based MSCs. Furthermore, these results are superior to many pseudocapacitive microsupercapacitors, including the VN//mesoporous MnO₂ MSC, and the PEDOT/Au MSC. Our 100 nm PEDOT/Ti₃C₂ MSC showed an order of magnitude enhancement compared to the previously reported PEDOT/Au MSC at similar thickness, which can be attributed to the high conductivity of the PEDOT/Ti₃C₂ composite, the expanded interspace of Ti₃C₂ layers during the deposition of PEDOT and additional charge storage contribution from bottom MXene TCE layer as well.

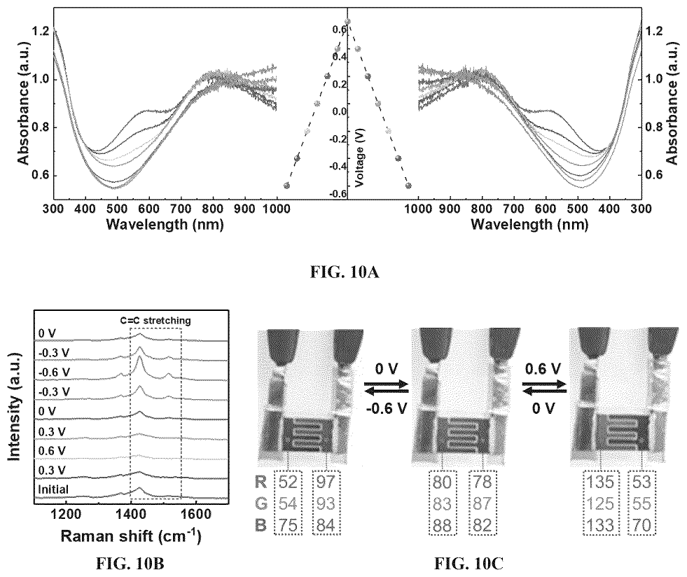

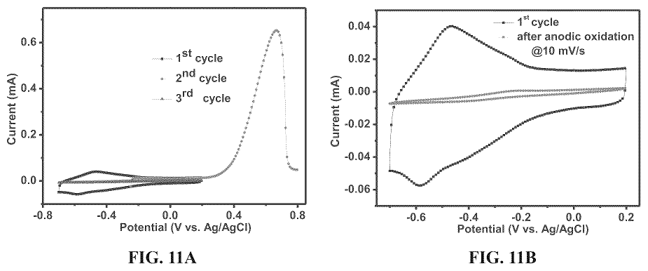

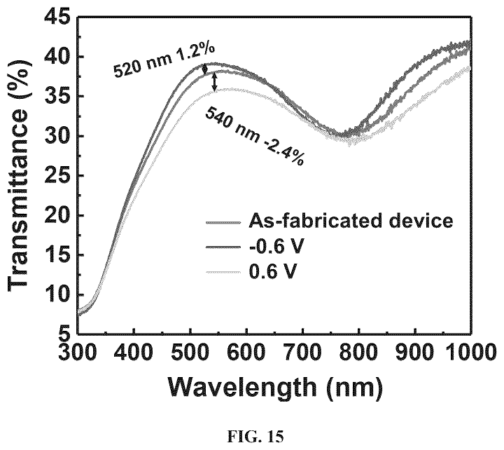

To demonstrate the electrochromic effect of the as-prepared electrochromic on-chip 100 nm PEDOT/Ti₃C₂ symmetric MSC, an in-situ UV-vis spectro-electrochemical technique was employed to monitor the transmittance changes between 300-1000 nm in response to the CV scan between −0.6 and 0.6 V (at a scan rate of 10 mV/s). As shown in FIG. 10A, during the charging process from 0 to 0.6 V, the color of the PEDOT/Ti₃C₂ positive electrode gradually became lighter and the absorption at 488 nm decreased, corresponding to the doping of SO₄²⁻ ions. When the voltage reached 0.6 V, the lighter color and the higher transmittance over the pristine electrode was observed. During the charging process from 0 to −0.6 V, corresponding to the proton doping behavior, the color of the PEDOT/Ti₃C₂ got deeper and the absorption between 400 to 700 nm increased. Notably, a new peak was observed at 589 nm as the voltage increased, which should be influenced by Ti₃C₂, which retained its absorption peak during the electrochemical process. The UV-vis spectra during the discharge process from 0.6 to 0 V and from −0.6 to 0 V verified the reversibility of the color change. UV-vis spectra of the pristine Ti₃C₂ device were recorded at different voltages to confirm the contribution of PEDOT to the electrochromic behavior, as shown in FIG. 15. Though relatively high electrochromic activity was observed on pure Ti₃C₂ in a 3-electrode cell, only a slight difference could be observed with the change in voltage for the pristine symmetric MXene MSC. From this, we conclude that the main role of Ti₃C₂ is to provide high electronic conductivity while PEDOT primarily contributes to the charge storage and electrochromic behavior. Digital images of the PEDOT/Ti₃C₂Tₓ device at different voltages, shown in FIG. 10C, agree with the UV-vis spectra. The RGB values of each electrode at different status were calculated and shown below these images.

Raman spectroscopy allowed for a detailed and time-resolved investigation of the kinetics of complex physical or chemical processes in a nondestructive manner. We employed a 514 nm laser excitation to exploit the resonant Raman phenomenon of PEDOT during electrochemical oxidation and reduction. FIG. 10B shows the voltage-dependent changes for the Raman bands of PEDOT when the device was scanned between −0.6 and 0.6 V at a scan rate of 10 mV/s, meaning that the evolution in Raman bands is reversible. The main peak at 1425 cm⁻¹ is broadened and shifted to 1445 cm⁻¹ due to electrochemical doping process. During the scan from 0 to 0.6 V, the specific Raman peaks of C═C bonds at 1425 and 1514 cm⁻¹ indicated a dramatic decrease in intensity. When scanned back from 0.6 to 0 V, the intensities of these peaks are reverted to their original intensities. While these peaks were significantly enhanced when the device was scanned from 0 to −0.6 V, they decreased back during the scanning from −0.6 to 0 V. To quantify the change of Raman peaks, we calculated the ratio of the intensity of these two peaks relatively to C═C bond with the peak at 1454 cm⁻¹, since this peak only showed a slight change with applied voltage. These results are consistent with the doping-dedoping process of protons and SO₄²⁻. When charged to a positive potential, the PEDOT was doped by SO₄²⁻ ions to reach its oxidation state. This change may induce the decrease of its polarizability, which is responsible for the decrease of Raman peaks intensity. On the other hand, the doping of protons could increase the polarizability, which resulted in an increase of the Raman peak intensities. In other words, charging to −0.6V caused the PEDOT band gaps to resonate with 514 nm and hence increased intensities of Raman peaks. At voltages of 0 and 0.6V, PEDOT is non-resonant with the laser wavelength and hence diminished intensities. These results are in agreement with resonant Raman studies on PEDOT electrodes.

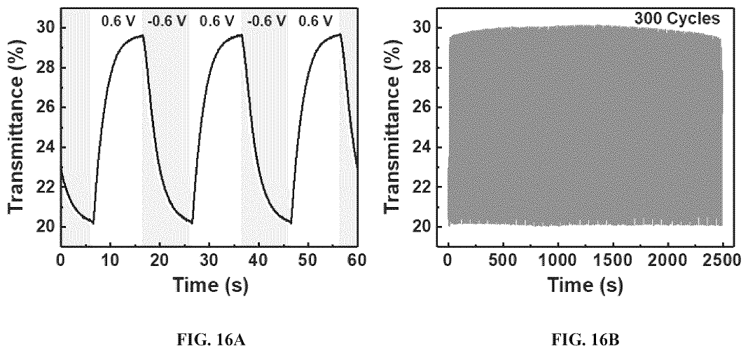

FIG. 15 reveals the in-situ transmittance at 488 nm under a pulse voltage of ±0.6 V because the biggest difference of transmittance was observed at 488 nm. The switching times were calculated to be 6.4 s and 5.5 s for bleaching and coloration, respectively, which is faster than most of the reported electrochromic devices (see Table 2). Without being bound to any particular theory, the fast switching speed can be attributed to the high conductivity and the uniform electric field distribution of the bottom-layer Ti₃C₂. In addition, the conducting PEDOT has a much higher conductivity than electrochromic transition metal oxides such as WO₃, NiO, and V₂O₅. The cycle stability of the bleaching-coloration was shown in FIG. 16B, which was tested by repeating the pulse voltage of ±0.6 V for 300 cycles. The transmittance of bleached and colored states was stable during the test, indicating a steady color change process.

### Results Summary

Electrochromic energy storage using a MXene-PEDOT heterostructure has been demonstrated. Direct fabrication of the MXene-PEDOT microsupercapacitors has been achieved through automated scalpel lithography. A high areal capacitance of 2.4 mF cm⁻² was achieved for the (100 nm) PEDOT/Ti₃C₂ MSC at a scan rate of 10 mV/s, retaining 1.4 mF cm⁻² at 1000 mV/s. Moreover, in-situ UV-vis and resonant Raman spectroscopies were employed to analyze the electrochromic behavior of PEDOT/Ti₃C₂ MSC. Color-switching time of 6.4 s for bleaching and 5.5 s for coloration was obtained. This study opens new avenues for developing MXene-conducting polymer heterostructures for color-changing energy storage devices.

TABLE 1
Ratio of the intensities of the C═C stretching
peaks with the peak at 1254 cm⁻¹.

| | Peak 1 | Peak 2 | Peak 3 | | |
|---|---|---|---|---|---|
| | C—C | Asymmetric | Symmetric | | |
| Voltage | stretching | stretching | stretching | Peak 2/ | Peak 3/ |
| (V) | at 1454 cm⁻¹ | of C═C | of C═C | Peak 1 | Peak 1 |
| Initial | 807 | 3757 | 980 | 4.66 | 1.21 |
| 0.3 | 776 | 2501 | 558 | 3.22 | 0.72 |
| 0.6 | 463 | 1335 | 303 | 2.88 | 0.65 |
| 0.3 | 677 | 1994 | 494 | 2.95 | 0.73 |
| 0 | 480 | 2895 | 730 | 6.03 | 1.52 |
| −0.3 | 482 | 5028 | 1349 | 10.43 | 2.80 |
| −0.6 | 497 | 8714 | 2385 | 17.53 | 4.80 |
| −0.3 | 440 | 4960 | 1352 | 11.27 | 3.07 |
| 0 | 424 | 2656 | 675 | 6.26 | 1.59 |

TABLE 2
Comparison of the electrochromic performance of 100 nm
PEDOT/Ti₃C₂ MSC with the reported electrochromic devices.

| Materials and | Current | | | Coloration | Bleaching |
|---|---|---|---|---|---|
| device structure | collector | Electrolyte | Voltage/V | time/s | time/s |
| PEDOT//FTO | Au | 0.5M | −0.5~1 | 2.2 | 1.1 |
| (asymmetric sandwich) | | [EMI][BTI]/PC | | | |
| WO₃//ITO | ITO | LiFTSI/acetone | 0~1.5 | 68 | 25 |
| (asymmetric sandwich) | | | | | |
| WO₃//NiO | ITO | LiTaO₃ | −1~1 | 44.0 | 33.6 |
| (asymmetric sandwich) | | | | | |
| Polyamide //ITO | ITO | 1M | −1.5~1.5 | 7.5 | 73.5 |
| (asymmetric sandwich) | | LiBF₄/PC/PMMA | | | |
| [FcNTf]/[EV]/IL | FTO | [FcNTf]/[EV] | 0~2 | 5.6 | 6.7 |
| (color-changing electrolyte) | | | | | |
| EG/V₂O₅-MSC | Au | 1M PVA/LiCl | 0~1 | 20 | 20 |
| (on-chip symmetric) | | | | | |
| PEDOT/Ti₃C₂ | None | PVA/H₂SO₄ | −0.6~0.6 | 6.4 | 5.5 |
| (on-chip symmetric) | | | | | |

FTO: fluorine-doped tin oxide, Au: gold, WO₃: tungsten oxide, NiO: Nickel oxide, ITO: indium doped tin oxide, PC: propylene carbonate, PMMA: poly(methyl methacrylate), [EV]: ethyl viologen, [FcNTf]: ferrocenylsulfonyl(trifluoromethylsulfonyl) imide, EG: exfoliated graphene, V₂O₅-MSC: vanadium oxide microsupercapacitors, PVA: polyvinyl alcohol.

### Illustrative Disclosure

In this study, transparent Ti₃C₂ MXene thin films were prepared by dip-coating and investigated as a transparent conductor and an electrochromic material. The electrochromic behavior of Ti₃C₂ was studied by in-situ ultraviolet-visible-near infrared (UV-vis-NIR) spectroscopy under a three-electrode electrochemical testing setup. In an acidic electrolyte, the vis-NIR absorption peak (˜770 nm) of Ti₃C₂ reversibly blue-shifted by ˜100 nm, exhibited a transmittance change of ˜12%, and occurred with a switching rate of less than 1 s. The observed behavior was further probed by in-situ XRD and Raman spectroscopy studies and was found to be related to the protonation/deprotonation pseudocapacitive mechanism involved in cycling with an acidic electrolyte. Finally, neutral and acidic electrolytes were studied to confirm the proposed mechanism and compare electrochromic device performance.

Due to the hydrophilic surface of MXenes, they can be easily processed in aqueous solutions at room temperature, allowing deposition on flexible and stretchable substrates. Scalable techniques which produce uniform transparent MXene films on a substrate are necessary. MXene TCEs were previously prepared by techniques such as spray-coating, which allows for large area coverage, and spin-coating, which permits more uniform coverage with limited area. Here, an optimization of the dip-coating process for MXene was studied, based on previous works which employed simplified or layer-by-layer dip-coating strategies

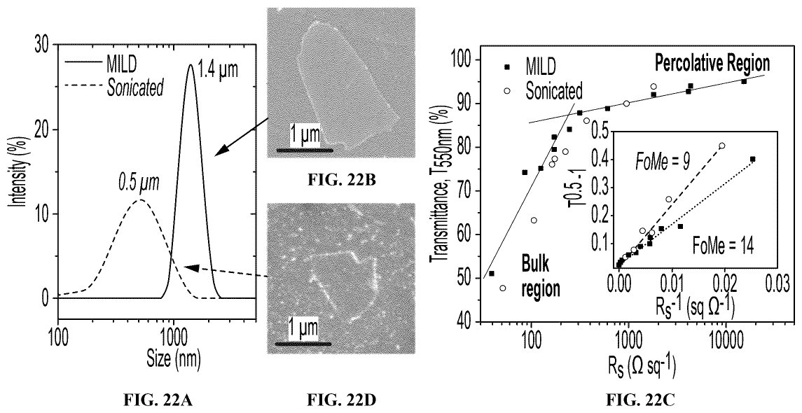

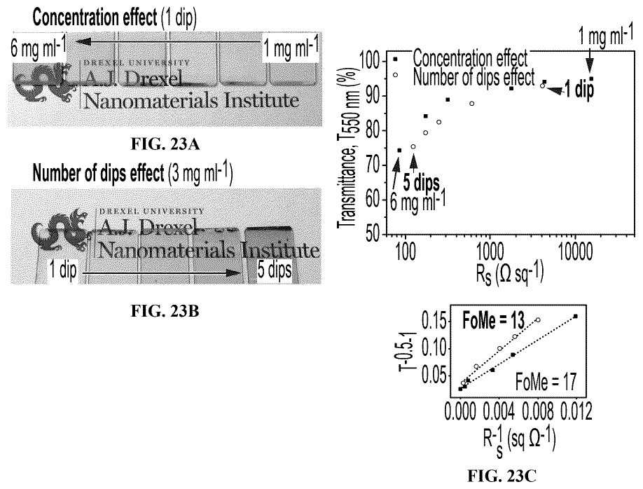

Multiple parameters govern the homogeneity and quality of the film produced through dip-coating, such as the MXene composition, surface chemistry and concentration, immersion time, withdrawing (dipping) speed, and relative environment humidity. To obtain the targeted thin film properties (30-50% transmittance, homogeneity, and high electrical conductivity), the flake size, concentration of MXene solution, and the number of dips were considered based on the electrical figure of merit (FoMₑ) (FIGS. 22A, B, C, D) and FIGS. 23A, B, C). The FoMₑ is defined as _{σDC}/_{σop}, (_{σDC} is the electrical conductivity, _{σop} is the optical conductivity, S m⁻¹) given by Equation (1):

$${T}_{550 nm} = {( 1 + \frac{188.5}{{R}_{s}} \frac{{σ}_{op}}{{σ}_{DC}} )}^{- 2} \qquad ( 1 )$$

where the FoMₑ can be calculated from the transmittance at 550 nm (T₅₅₀ₙₘ) and the sheet resistance (Rₛ in Ω sq⁻¹). The FoMₑ obtained from the optimized dip-coated Ti₃C₂ films in this study was 17, similar to those produced by spin-coating (FoMₑ of 15 after vacuum annealing). Due to this, dip-coating can be used as an easily scalable processing technique for MXene thin films, resulting in similar optoelectronic properties as thin films produced by spin-coating.

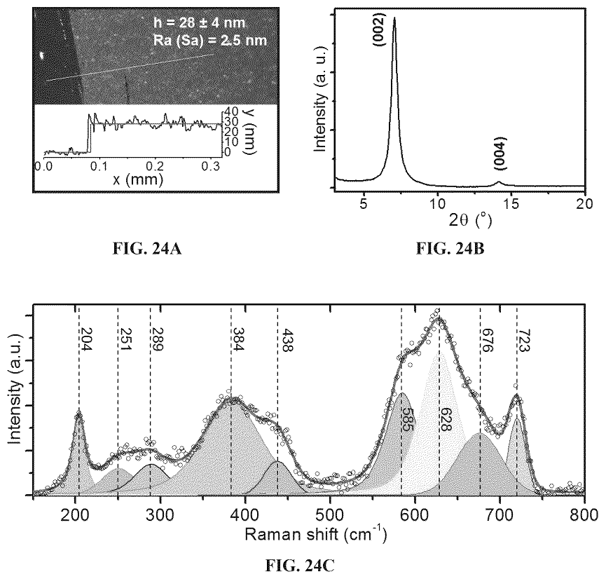

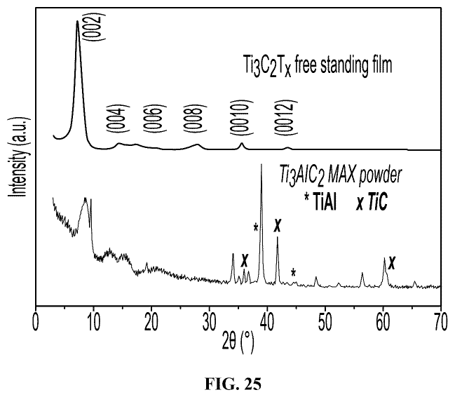

To determine the thickness, optical profilometry measurements were performed, which showed low surface roughness (for a film of T₅₅₀ₙₘ=65%: thickness 30 nm and roughness Ra (Sa)=2.5 nm, FIG. 24A) In addition, film thicknesses follow the empirical linearity between thickness and absorbance shown by others. The XRD pattern and a Raman spectrum characteristic of Ti₃C₂ films, showing that the material is preserved after dip-coating. XRD pattern shows a broad 002 peak at 2θ=7.0°, corresponding to a c-lattice parameter of 25.2 Å. The presence of the (004) peak at 14.0° further confirms the high degree of stacking along the c direction (FIG. 24B and FIG. 25). The Raman spectrum of our Ti₃C₂ thin films has been deconvoluted and shows the active vibration modes of Ti₃C₂ (FIG. 24C and Table 3). Furthermore, SEM images (FIGS. 22B-22C) confirm the flake-like morphology and indicate that no oxidation occurred during synthesis or dip-coating.

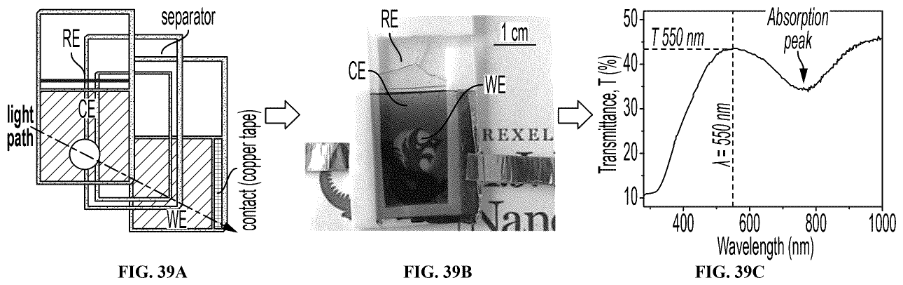

Two thin films of similar transparency (30-50% T₅₅₀ₙₘ) and sheet resistance (20-70 Ω sq⁻¹) were assembled in a three-electrode configuration to characterize the optoelectrochemical behavior (setup shown in FIG. 39B,). One thin film acted as the working electrode (WE), while the other was the counter electrode (CE), and a silver wire was used as a pseudo-reference electrode (RE). To probe the change in optical properties of only the WE, a 0.5 cm diameter hole was made in the Ti₃C₂ CE to avoid contribution of the CE in the UV-vis-NIR spectrum (FIG. 39A). The UV-vis-NIR spectrum of a Ti₃C₂ MXene thin film has several characteristic features, such as a broad absorption peak around 760-780 nm and an absorption peak in the UV region (FIG. 39C). According to previous studies, it was suggested that the absorption peak at ˜770 nm corresponds to a plasmonic effect, more specifically to a transversal surface plasmon, which would explain the independence of the peak position on the flake size.

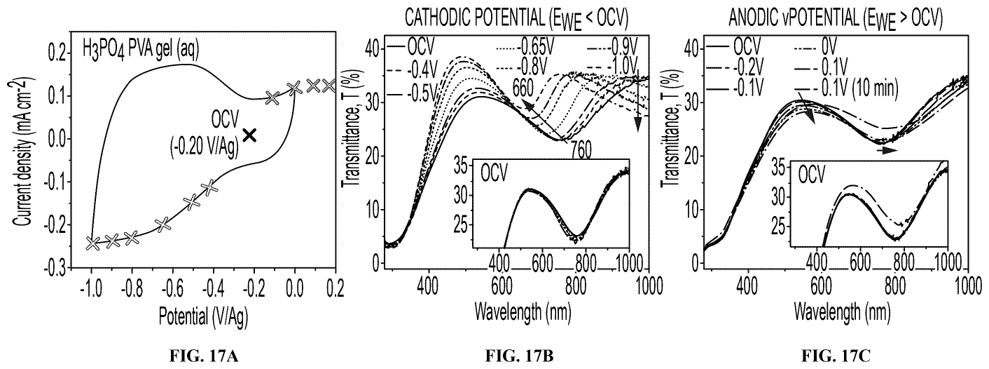

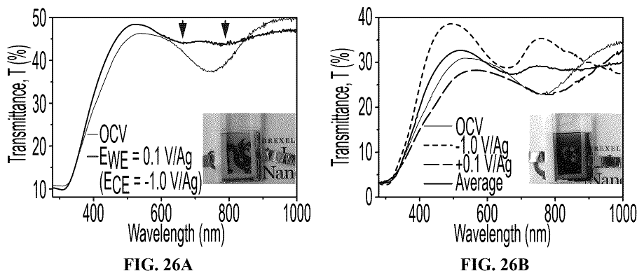

Electrochromic properties of the Ti₃C₂ device were studied by in-situ UV-vis-NIR spectroscopy during electrochemical cycling in 1 M phosphoric acid polyvinyl alcohol gel electrolyte (H₃PO₄/PVA gel). Starting from the open circuit voltage (OCV) at −0.2 V/Ag, cyclic voltammetry (CV) was performed with a voltage window of 1 V (from −1.0 to 0.0 V/Ag at 20 Mv/s) (FIG. 17A). A CV profile of Ti₃C₂ film was obtained, with a broad faradaic contribution from −0.3 to −1.0 V/Ag and a capacitive envelop from −0.3 to 0.0 V/Ag. The UV-vis-NIR transmittance was recorded at different cathodic (E_{WE}<OCV) and anodic potentials (E_{WE}>OCV). When cathodic potentials were consecutively applied (from −0.4 to −1.0 V/Ag, and held for 15 minutes at each step), the absorption peak shifted from the initial value centered at 760 nm (OCV) to 660 nm at E_{WE}=−1.0 V/Ag (FIG. 17B). In this configuration, using 1 M H₃PO₄/PVA gel electrolyte, the absorption peak position shifted by ˜100 nm in wavelength, in addition, this shift was associated with increased (˜12%) transmittance at 770 nm (ΔT₇₇₀ₙₘ) (FIG. 17B). Inversely, when an anodic potential was applied, a lower magnitude shift in the opposite direction was observed. The absorption peak shifted to higher wavelengths (760 nm at OCV to 780 nm at 0.1 V/Ag; Δλ=20 nm) with a small decrease in transmittance (FIG. 17C). Interestingly, in the cathodic regime, the increase in transmittance in the visible range was accompanied by the decrease in transmittance in the infrared range, intensified by applying a more negative potential of −1.0 V/Ag (dark blue curve in FIG. 17B). In contrast, the variation of transmittance was minimal upon applying anodic potentials. The variation in transmittance and the peak shift corresponded to a reversible color change of the Ti₃C₂ film from green (0.0 V/Ag) to blue (−1.0 V/Ag). In addition, a symmetric device (WE+CE) was fabricated (without the hole on the CE previously mentioned) to demonstrate that the device can operate and combine the spectra observed for single electrode in both cathodic potential and anodic potential (See FIGS. 26A, B and complementary information).

To study the reversibility of the optical changes, the potential was released after each potential step to probe the film optical response. Interestingly, the absorption peak position returned to the initial value (˜760 nm), exhibiting a reversible process (inset in FIGS. 17B-17C). However, when an anodic potential outside the voltage window (0.1 V/Ag) was applied, an irreversible increase of transmittance was observed (inset FIG. 17C), indicative of the irreversible oxidation of Ti₃C₂.

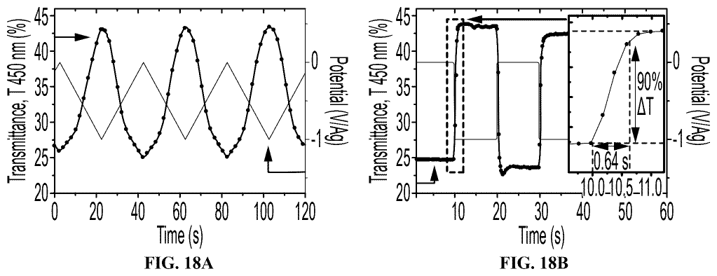

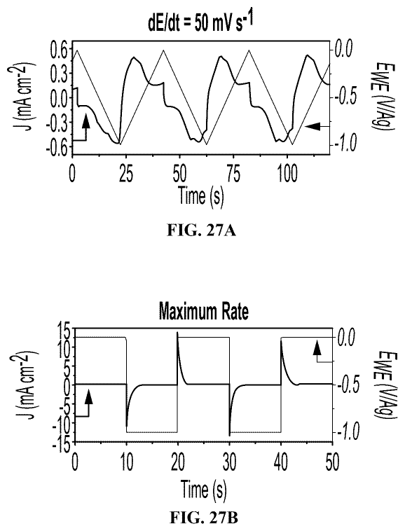

A parameter of an electrochromic device is the switching rate, which is the time needed to switch from one color to the other, or from minimal to maximal transmittance at a specific wavelength of interest. In FIG. 18, the smooth and immediate switching rate of the Ti₃C₂ electrochromic device (device configuration in FIGS. 39A-39B) at different potentials from 0.0 to −1.0 V/Ag was displayed using 1 M H₃PO₄ aqueous electrolyte (instead of H₃PO₄/PVA gel electrolyte, to avoid any possible diffusion limitation of the gel). The switching rate was investigated at 450 nm, the region in the spectrum where Ti₃C₂ had the broadest shift in transmittance (up to 20% T) (see FIG. 17B). It is worth noting that the switching could be performed at any wavelength, and often may be application dependent. When a smooth change of potential is applied (through CV from 0.0 to −1.0 V/Ag at 50 Mv/s), control over the transmittance shift based on the potential is demonstrated (FIG. 3A). However, when the potential was abruptly changed from 0.0 to −1.0 V/Ag (by chronoamperometry), a ˜20% change in transmittance was observed in 0.6 s (FIG. 18B). Metal oxides, such as tungsten oxide, have a switching rate of a few seconds to one minute. Some polymer-based electrochromic devices have been shown to switch in ˜10 ms, however they need to be combined with metal grids and complex nanostructures to obtain such a fast rate. In our study, fast switching rates can be obtained without the need of an external current collector because of the metallic conductivity of Ti₃C₂. However, when high currents occur (intense current spikes, 10 to 15 Ma cm⁻², FIG. 27B), resulting from the immediate switch of potential, the Ti₃C₂ thin film degrades after a few cycles and the rate-lifetime performance will need optimization in future studies.

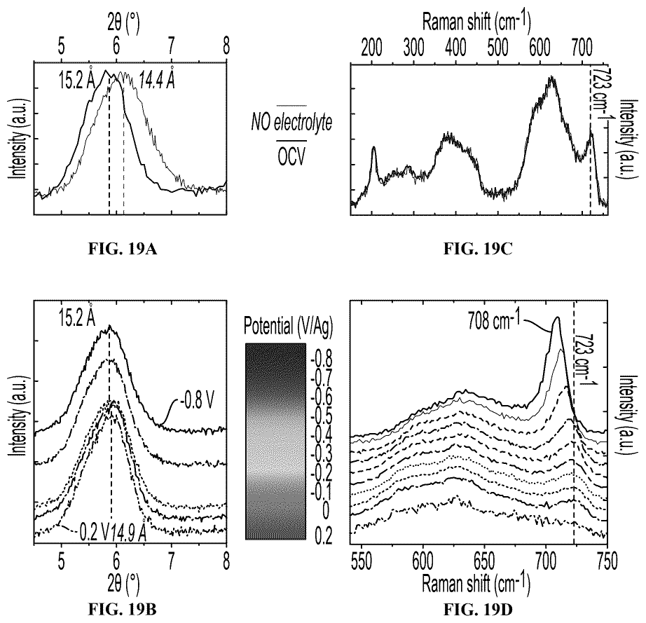

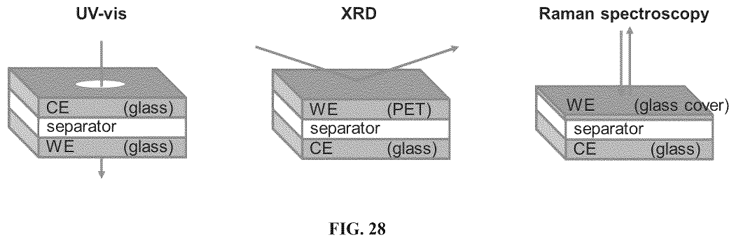

To understand the mechanism of these changes, in-situ electrochemical Raman spectroscopy and in-situ XRD were used, allowing for observation of the chemical and structural changes of the device during cycling in H₃PO₄/PVA gel electrolyte (FIGS. 19A-19D and FIG. 28). XRD was analyzed in the 20 region between 4-8°, corresponding to the (002) peak of Ti₃C₂, to probe the effect of the lattice expansion or contraction due to intercalation/deintercalation of the electrolyte ions and water molecules at different applied potentials. Comparing the XRD patterns of the device without and with electrolyte, a shift of the (002) peak was observed, corresponding to an increase of the c-lattice parameter from 28.8 to 30.4 Å (2θ from 6.07 to) 5.85°, indicating intercalation of the electrolyte (FIG. 19A). The higher initial c value in the Ti₃C₂ film is due to water remaining intercalated from the dip-coating process. When potentials were applied, a shift of the (002) peak was only observed for anodic potentials (−0.1 to 0.2 V/Ag), where the expansion is diminished (Δc=−0.6 Å) (FIG. 19B). However, the expansion upon intercalation for cathodic potentials (−0.1 to −0.8 V/Ag) is not significant compared to the cycling of Ti₃C₂ with other electrolytes, and suggests the origin of the optical peak shift is not because of the intercalation/deintercalation of H ions alone.

Therefore, we turned our attention to the relationship between the pseudocapacitive nature of Ti₃C₂ and the electrochromic properties observed. The pseudocapacitive mechanism relies on the reduction and oxidation of Ti—O/Ti—OH terminations, and the variation of the oxidation state of Ti in Ti₃C₂. Demonstrated by others, the change of surface terminations of Ti₃C₂ from −O to —OH when a cathodic potential is applied can be followed using in-situ Raman spectroscopy. The scattering peak at 723 cm⁻¹ is assigned to the out-of-plane vibration of a C—Ti bond surrounded by an O-termination, such as in Ti₃C₂O₂, whereas the peak at 708 cm⁻¹ corresponds to that of C—Ti in a Ti₃C₂O(OH) environment. While applying a cathodic potential, the environment of the Ti transition metal atoms progressively changes from −O to —OH, inducing a down shift of the peak. This effect on the Raman shift of 723 cm⁻¹ vibration mode was observed for acidic electrolyte (H₂SO₄) but not for neutral electrolyte (MgSO₄).

Similarly, in-situ electrochemical Raman spectroscopy was performed in a three-electrode configuration (FIG. 28). FIG. 19C shows a Raman spectrum for Ti₃C₂ (deconvoluted in FIG. 24C and Table 3). The addition of the H₃PO₄/PVA gel electrolyte had no effect on the Raman spectra, suggesting that the pre-intercalation observed in XRD does not modify the surface chemistry of Ti₃C₂. On the other hand, FIG. 19D shows a proportional shift of the peak from 723 cm⁻¹ to 708 cm⁻¹ while applying a cathodic potential from 0 to −0.8 V/Ag, respectively. Combined with the absence of significant variation of the c-lattice parameter under similar conditions, these observations indicate that the shift of the UV-vis-NIR peak in in-situ electrochemistry is due to the pseudocapacitive properties of the Ti₃C₂.

Recently, others demonstrated a shift of ˜0.3 eV for the surface plasmon at 1.7 eV of Ti₃C₂ flakes upon annealing up to 900° C. This shift was attributed to the modification of the surface terminations of Ti₃C₂ (in that case desorption of fluorine (F) groups) which involved the increase of the metal-like free electron density. Following the Planck-Einstein equation, the surface plasmon that they describe could correspond to the vis-NIR absorption peak observed for Ti₃C₂. In addition, an energy shift of +0.3 eV corresponds to a wavelength shift of −110 nm, similar to the results shown in this study with H₃PO₄/PVA gel electrolyte (FIG. 17B). Therefore, controlling the surface terminations allows one to tune surface plasmon resonance and the resulting electrochromic behavior.

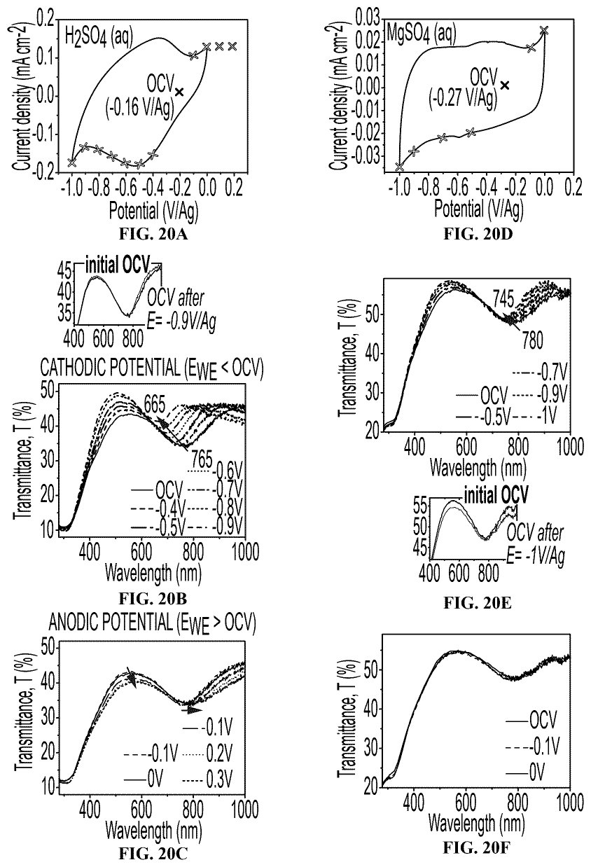

To corroborate the hypothesis, different aqueous electrolytes were tested to probe the effect of the anion (H₃PO₄ vs. H₂SO₄) and the effect of the cation (H₂SO₄ vs. MgSO₄). In the case of H₂SO₄ electrolyte, the CV shows a large increase of the faradaic current for cathodic potentials (FIG. 20A), similar to the behavior of H₃PO₄ (FIG. 17A), relating to the pseudocapacitive mechanism. In accordance with the optical changes occurring during electrochemical cycling in H₃PO₄ electrolyte, H₂SO₄ electrolyte devices showed absorption peak shifts of 100 nm and ΔT₇₇₀ₙₘ˜12% for cathodic potentials (from 34% at −0.16 V to 46% at −1.0 V/Ag, FIG. 20B) and small changes for anodic potentials (FIG. 20C). On the other side, when changing the electrolyte to MgSO₄, the CV was rectangular (FIG. 20D), indicative of an electrical double layer capacitance. Probing the optical changes, devices fabricated with MgSO₄ electrolyte show a blue shift with a lower magnitude (Δλ=35 nm, ΔT₇₇₀ₙₘ˜3%) (FIGS. 20E-20F).

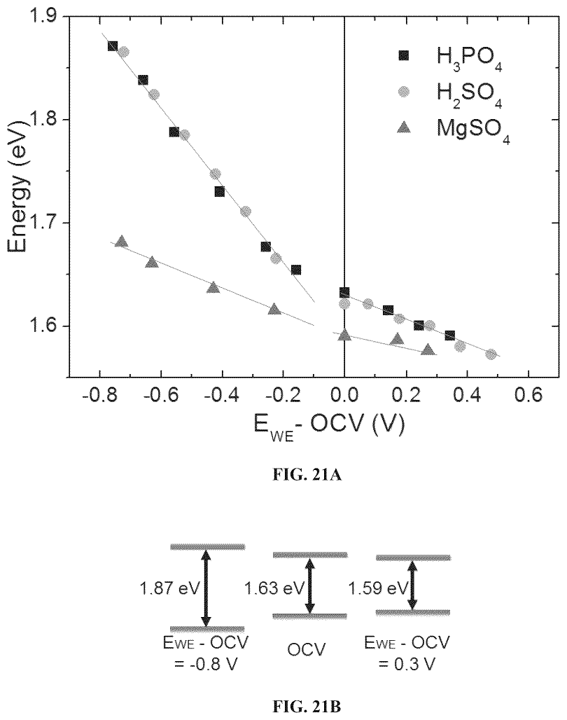

To emphasize the different optoelectrochemical behavior between acidic (1 M H₂SO₄ and H₃PO₄) and neutral (1 M MgSO₄) electrolytes, the energy (in eV) of the absorption peak as a function of the applied potential was plotted in FIG. 21A. Two clear trends are observed when E_{WE}<OCV (cathodic potentials) and E_{WE}>OCV (anodic potentials) for all the three tested electrolytes, where the energy associated with the absorption peak follows a linear trend with the applied potential (total energy change for acidic electrolytes schematized in FIG. 6B). For E_{WE}>OCV, the slope of energy change is similar for all the three electrolytes, emphasizing the negligible effect of the anion intercalation on MXene optical properties in this potential range. Focusing on E_{WE}<OCV, where the most important optical changes occur, here again both acidic electrolytes (H₃PO₄ and H₂SO₄) showed similar effect (Table 4). Considering the difference in energy between OCV and the most negative cathodic potential applied (E_{WE}−OCV=−0.8 V), the Ti₃C₂ films in acidic electrolytes had a total shift of ˜0.25 eV, however with the MgSO₄ electrolyte the shift was only about ˜0.08 eV. These results indicate that the nature of the cation plays an important role in the electrochromic properties of Ti₃C₂. In case of acidic electrolytes, the observed shifts are 3 times higher than for neutral electrolyte, corroborating that protons and the redox mechanism play a significant role in electrochromic performance of MXene devices.

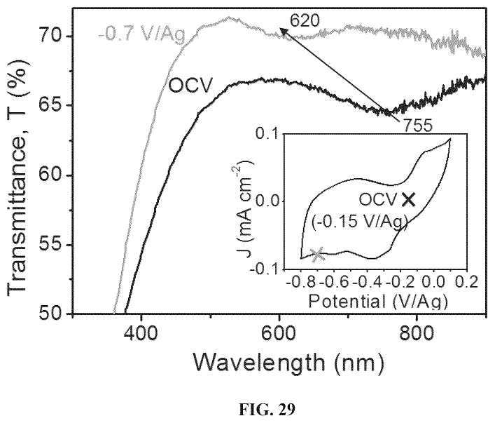

It has been demonstrated that Ti₃C₂ MXene can be used as an active material in an electrochromic device. Because the MXene structure and composition has a direct effect on their optical properties (compare, e.g. Ti₃C₂ and Ti₂C) devices with a variety of electrochromic properties should be possible. As a proof of concept, Ti₃CN MXene was also studied and has demonstrated an even larger shift of the absorption peak than Ti₃C₂ (FIG. 29). This work opens a new avenue for the use of MXene family of materials, with more than 30 members already available, to be further developed as optic, photonic, and electrochromic materials.

### Summary

Ti₃C₂ thin films were fabricated by an optimized dip-coating method, obtaining a maximum FoMₑ of 17. (It should be understood, however, that films can be fabricated by other methods, e.g., spraying, inking, and the like, as dip coating is not the exclusive method.) The electrochromic behavior of the thin films has been studied in a three-electrode configuration by in-situ UV-vis-NIR spectroscopy, observing a shift of the absorption peak and change of transmittance, which is proportional to the cathodic potentials applied. These optical changes are dependent of the electrolytes, where the largest change was observed with acidic electrolytes (ΔT₇₇₀ₙₘ˜12%, Δλ˜100 nm) compared to neutral electrolyte (ΔT₇₇₀ₙₘ˜3%, Δλ35 nm). Using in-situ XRD and in-situ Raman spectroscopy, the mechanism of the electrochromic behavior has been attributed to the pseudocapacitive change of the MXene surface functionalities (Ti—O to Ti—OH) upon reduction. It is believed that the surface plasmon related to the absorption peak in the visible region is affected by tuning the metal-like free electron density of the MXene, which increases when a cathodic potential is applied, and this phenomenon is further amplified by the pseudocapacitive mechanism. Electrochromic change of the films can be influenced by controlling the surface functionalities of Ti₃C₂. Due to changes in optical properties with MXene composition, MXene electrochromic devices with different colors can be produced.

### Illustrative Experimental Section

Preparation of Ti₃C₂

Chemical reagents were used as received without further purification. Ti₃AlC₂ MAX phase powder was obtained from Y-carbon Ltd., Ukraine and sieved (particle size<40 micrometer). Ti₃C₂ MXene was synthesized by selective etching of the aluminum from the MAX, following the minimally intensive layer delamination (MILD) protocol. Briefly, 1 g of Ti₃AlC₂ powder was slowly added to an etchant solution containing 1 g of lithium fluoride salt (LiF, Alfa Aesar, 98+%) dissolved in 20 mL of 9 M hydrochloric acid (HCl, Fisher, technical grade, 35-38%) under stirring. The reaction was stirred for 24 h at 35° C. The resulting acidic solution was washed with deionized water, by consecutive centrifugation (5 minutes at 3500 rpm) and decantation of the clear supernatant, until a pH of 6 or more was reached. When pH≥6, delamination occurred, a stable dark supernatant of Ti₃C₂ was obtained and was collected by centrifuging for 30 minutes at 3500 rpm.

Smaller MXene flakes (˜0.5 μm) were prepared by sonication of the obtained colloidal solution in an ice-bath for 30 minutes under inert gas bubbling to avoid oxidation. The resulting colloidal dispersion was then centrifuged at 3500 rpm for 20 minutes, and the supernatant was collected.

The concentration of Ti₃C₂ solution was measured by filtering a known volume of colloidal dispersion through a polypropylene filter (3501 Coated PP, Celgard LLC, Charlotte, NC), followed by overnight drying under vacuum and weighing.

Thin films Preparation by Dip-Coating

Glass substrates of 2.5×7.5 cm² size (Fischer Scientific) were cleaned in bath sonication with a soap solution (Hellmanex III, Fisher Scientific) followed by consecutive sonication in deionized water and ethanol for 5 minutes each and then dried with compressed air. Then, a plasma treatment (Tergeo Plus, Pie Scientific) at 50 W with a mixture of O2 and Ar (3 and 5 sccm) for 5 minutes was applied to the substrates for further cleaning and to improve their hydrophilicity. Finally, as-prepared substrates were coated with MXene thin film by dip-coating technique. An automated dip-coater (PTL-MM01 Dip Coater, MTI Corporation) was used to control the dipping/withdrawing speed and distance. The substrates were immersed in the colloidal solution for 3 minutes, pulled out at a constant speed of 2 mm/s, and dried in air at room temperature. In case of multiple dipping (up to five), the substrate was left to dry between each dip for 5 minutes. The film on the back side of the substrate was erased using ethanol. The parameters studied during optimization of the technique were: MXene concentration (1 to 10 mg/mL), number of dips (1 to 5) and MXene flake size. The obtained thin films were kept in desiccator overnight before characterization.

### Material Characterization

The particle size of MXene in colloidal solution was measured by dynamic light scattering (DLS, Zetasizer Nano ZS, Malvern Panalytical). The optical spectra of the MXene thin films was measured in the range of 280 to 1000 nm by UV-vis-NIR spectroscopy (Evolution 201 UV-vis-NIR spectrophotometer, Thermo-Fischer scientific). The sheet resistance was measured with a four-point probe (ResTest v1, Jandel Engineering Ltd., Bedfordshire, UK) with a probe distance of 1 mm, measuring at 5 different spots for each sample and taking the averaged result. The top view of the MXene coatings were imaged using a scanning electron microscope (SEM) (Zeiss Supra 50VP, Germany). Roughness and thickness of the films were analyzed by optical profilometer (Zygo Corporation, Middlefield, USA). Raman spectroscopy was done using an inverted reflection mode with a Renishaw microscope (2008, Glouceshire, UK), equipped with 50× objective and a LEICA CTR6000 setup with 633 nm laser, 1800 lines mm⁻¹, grating at 10% of maximum intensity. Spectra were collected with an accumulation time of 120 s and 3 accumulations. XRD was conducted on a Rigaku Smartlab operating at 40 kV and 40 mA. Each scan was collected from 4-8° (2θ) with a step size of 0.02° at 5 s step⁻¹, on MXene films or loose MAX powder.

### Fabrication of MXene Electrochromic Device

To study the electrochromic properties of the MXene thin films, symmetric three-electrode cells were used. The working electrode (WE) and counter electrode (CE) were MXene thin films on glass substrate with copper tape on one side to make the electrical contact. A silver wire was used as pseudo-reference electrode (RE) and a Teflon mask was used as mask to create an electrolyte reservoir between the electrodes with an area ˜3.7 cm². For single-electrode in-situ optoelectrochemical study (UV-vis-NIR spectroscopy), a 0.5 cm diameter hole was made on the Ti₃C₂ CE (see FIG. 1), to ensure the UV-vis-NIR characterization of the WE only. For in-situ XRD measurements, a PET foil was used as WE substrate instead of glass to improve the collected signal. For in-situ Raman spectroscopy measurements, MXene was deposited on a glass cover slide and used as a WE.

The electrolytes used were phosphoric acid in polyvinyl alcohol gel (H₃PO₄/PVA gel), sulfuric acid (H₂SO₄, Fisher Scientific, 98%) and magnesium sulphate (MgSO₄, Fisher Scientific), all with a concentration of 1 M. To obtain the H₃PO₄/PVA gel, 1 g of PVA (Alfa Aesar, 98%) was dissolved in 10 mL deionized H₂O by stirring at 80° C. for 3 h. Then 1 g (0.6 mL) of concentrated H₃PO₄ (Alfa Aesar) was added to the obtained PVA gel and stirred for 30 minutes at room temperature to obtain H₃PO₄/PVA gel.

### In-situ Electrochromic measurements

UV-vis-NIR, XRD and Raman in-Situ Electrochemistry

For in-situ electrochemical measurements with UV-vis-NIR spectroscopy, XRD and Raman spectroscopy, the systems were pre-cycled 5 times by cyclic voltammetry (CV) at 20 mV/s to determine the potential window of the device. Then, chronoamperometry (CA) were acquired for different potentials applied for a period of 15 minutes each, during the time needed to measure the spectra of the corresponding technique (UV-vis-NIR spectroscopy, XRD, Raman spectroscopy). In the case of UV-vis-NIR spectroscopy, the uncoated glass slide was used for the blank. The change of transmittance was measured at 770 nm (ΔT₇₇₀ₙₘ), comparing the spectra at OCV and at the applied potential. Three different electrolytes were compared: H₃PO₄/PVA gel, H₂SO₄ and MgSO₄. To calculate the switching rate, the time needed to switch transmittance at 450 nm (T₄₅₀ₙₘ) was measured when chronoamperometry from 0.0 to −1.0 V/Ag was applied, with an aqueous H₃PO₄ electrolyte. The time measured corresponds to 90% of the total change of transmittance. To evaluate the dynamic response of the device in case of a continuous potential perturbation, T₄₅₀ₙₘ was also followed while cycling the working electrode through a CV between 0.0 and −1.0 V/Ag at 50 mV/s. In the case of Raman spectroscopy and XRD analysis, the only electrolyte used was H₃PO₄/PVA gel. The conditions followed for in-situ Raman spectroscopy and XRD were the same than used for thin film characterization.

It is well known that the size of MXene flakes plays an important role in several properties of MXene-based devices. The lateral dimension of Ti₃C₂ flakes were measured in solution by Dynamic light scattering (DLS), obtaining an average size of 1.4 +0.1 μm for minimally intensive layer delamination (MILD) synthesis and 0.5 +0.2 μm after sonication (FIG. 22A). This average flake size was further proved by SEM (FIG. 22B and FIG. 22C). It is also important to note the low polydispersity for MXene flakes obtained by MILD method.

FIG. 22D shows optoelectronic properties of MXene films, plotting the dependence of the transmittance at 550 nm (T₅₅₀ₙₘ) to the sheet resistance (Rₛ) for a panel of Ti₃C₂ MXene films of different thicknesses. Two regimes were observed, i.e., bulk and percolative regions, as observed for thin films based on other nanomaterials.² For thick Ti₃C₂ films (bulk region, T₅₅₀ₙₘ<85%), Rₛ shows linear dependency to T₅₅₀ₙₘ (from 10 Ω sq⁻¹ at 45% to 120 Ω sq⁻¹ at 85%). Below this threshold thickness (percolative region, T₅₅₀ₙₘ>85%), the number of flakes per area is low enough to form a less continuous thin film. However, the flake covering is enough to ensure electronic conduction. Because of the percolation, in this region, R_{S} increases much faster with decreasing of film thickness (increasing of T₅₅₀ₙₘ).

The effect of the flake size on the transmittance and sheet resistance of the dip-coated films were characterized for large flakes (˜1.4±0.1 μm, MILD) or smaller flakes (0.5±0.2 μm, sonicated). In the percolative region, similar optoelectronic properties were observed for both flake sizes. For thicker films, in the bulk region (T₅₅₀ₙₘ<85%), the difference between MILD and sonicated MXene was larger showing lower R_{S} at similar T₅₅₀ₙₘ for large flake size, indicating a better film quality. This can be further proved by calculating the corresponding electrical figure of merit (FoMₑ) according to the equation (1). In this case, the FoMₑ values obtained were 14 for large flakes vs. 9 for small flakes, indicating that better optoelectronics can be achieved by using large MXene flakes. To explain these results, the electrical conductivity was measured for free-standing films, obtained by vacuum-assisted filtration process of the same solutions used in the dip-coating process, and stored in vacuum overnight. The average electronic conductivity value was 7530±200 S cm⁻¹ for films obtained from larger flakes and 5680±150 S cm⁻¹ for that from smaller flakes, proving better intrinsic electronic conduction for films made of larger flakes. This better intrinsic electronic conductivity of large flakes explains better optoelectronic characteristics on the bulk region.

As shown in FIGS. 23A-23B, the thickness of the obtained thin film can be increased when higher MXene concentrations are used and/or by repeating the dipping process. However, the effect on the optoelectronic properties is not the same in both cases, which can be observed by the corresponding FoMₑ value (FIG. 22C inset). Comparing the effect of these two parameters, the optoelectronic properties are similar for the thinnest samples (T₅₅₀ₙₘ>85%) but for thicker films (T₅₅₀ₙₘ<85%), the films obtained by several dips show higher Rₛ for the same T₅₅₀ₙₘ. This could be explained by the potential decrease of the substrate hydrophilicity after the first dip or some peel-off of the layers during the next dip cycles, making it more difficult to obtain a homogeneous coating along its surface. On the other hand, when only one dip using high concentration solution, the amount of MXene in solution is enough to provide a continuous homogeneous layer over the plasma treated hydrophilic substrate area, giving better optoelectronic properties. Therefore, to get homogeneous thin films with optimized optoelectronic properties, a high concentrated colloidal dispersion of large flake MXenes is used, dipping the substrate one time.

FIG. 24A illustrates that the average thickness of the dip-coated film is 28±4 nm. The surface roughness is 2.5 nm, indicating the uniformity of the preparation method and homogeneity of the films. The XRD pattern in FIG. 24B, and further FIG. 25, illustrates the MXene thin film. These patterns illustrate that, the flakes are preferentially oriented along the (002) direction parallel to the surface substrate, leading to constructive interference in this direction. The broadness of the (002) peak in addition to the existence of the (004)-(0012) peaks illustrate that the flakes are stacked in a coherent manner with regularity. Within these flakes, the existence of the higher numbered (00l) peaks indicate that there is relatively large size with a low degree of crumpling/defective motifs on the basal planes. For MXenes, as the crystal size decreases, there is increased destructive interference due to grain boundary effects leads to broadening of the (002) peak and the disappearance of the higher orders (00l) peaks. Vibration modes deconvoluted in the Raman spectrum presented in FIG. 24C are explained below.

TABLE 3
Assignment of Raman active vibration modes of Ti₃C₂.

| Raman | | | Raman | | |
|---|---|---|---|---|---|
| shift | | | shift | | |
| position | | Predicted | position | | Predicted |
| (cm⁻¹) | Mode | formula | (cm⁻¹) | Mode | formula |
| 204 | A_{1g} (Ti, C, O) | Ti₃C₂O₂ | 585 | A_{1g} (Ti, O) | Ti₃C₂O₂ |
| 251 | E_{g} (F) | Ti₃C₂F₂ | 628 | E_{g} (C) | Ti₃C₂OH |
| 289 | E_{g} (O, H) | Ti₃C₂(OH)₂ | 676 | A_{1g} (C) | Ti₃C₂OH |
| 384 | E_{g} (O) | Ti₃C₂O₂ | 723 | A_{1g} (C) | Ti₃C₂O₂ |
| 438 | E_{g} (H) | Ti₃C₂(OH)₂ | | | |

The UV-vis-NIR study was also conducted for the full symmetric device (both films are complete, the path of the laser goes through both thin films), obtaining the UV-vis-NIR spectrum of both WE and CE at the same time (FIG. 26A). In this case, when anodic potential was applied (E_{WE}=0.1 V/Ag), two peaks appeared instead of one. Here, we show that the reason of these two peaks is the combination of the optoelectrochemical responses of the WE and CE, which is demonstrated by the study of single electrode at different potentials (FIG. 26B). When the spectra of the anodic potential (WE in full device) and the one of the cathodic potential (CE in full device) are combined, the averaged UV-vis-NIR spectrum achieves the same shape compared to the one seen for the full device (black line).

TABLE 4
Fitting data on linear regression for energy change vs. potential applied.

| | Cathodic potential (E_{WE} < OCV) | | | Anodic potential (E_{WE} > OCV) | | |
|---|---|---|---|---|---|---|
| Electrolyte | slope | intersection | R² | slope | intersection | R² |
| H₃PO₄ | −0.37 | 1.58 | 0.991 | −0.12 | 1.63 | 0.995 |
| H₂SO₄ | −0.39 | 1.58 | 0.999 | −0.12 | 1.63 | 0.970 |
| MgSO₄ | −0.12 | 1.59 | 0.986 | −0.10 | 1.60 | 0.965 |

### Preparation of Ti₃CN

Similar to Ti3C2 synthesis, Ti3CN was obtained by etching of 0.5 g Ti3AlCN MAX. The etchant solution was composed of 1 g of LiF dissolved in 10 mL of 9 M HCl by stirring during 10 minutes. Then, the mixture was heated to 40 oC and stirred for 18 h. After etching, the mixture was washed by centrifugation at 3500 rpm (10 minutes per cycle), decantation and addition of deionized water until the supernatant reached a pH≥6.

Similar to Ti₃C₂ synthesis, Ti₃CN was obtained by etching of 0.5 g Ti₃AlCN MAX synthesized as reported elsewhere.⁵¹ The etchant solution was composed of 1 g of LiF dissolved in 10 mL of 9 M HCl by stirring during 10 minutes. Then, the mixture was heated to 40° C. and stirred for 18 h. After etching, the mixture was washed by centrifugation at 3500 rpm (10 minutes per cycle), decantation and addition of deionized water until the supernatant reached a pH≥6 and then by centrifugation at 8000 rpm (10 minutes, 1 cycle). The final black precipitate was dispersed in 20 mL of DI water and bath sonicated (40 kHz) for 30 minutes at room temperature. Finally, the suspension was centrifuged at 3500 rpm for 1 h and the stable dark supernatant (Ti₃CN) was collected.

### Additional Results and Discussion

The unique combination of metallic conductivity and hydrophilicity classify MXenes as versatile class of materials for emerging optical and optoelectronic applications. Following sections are focused on optical, optoelectronic and optoelectrochemical properties of four different Ti-based MXene compositions—Ti₃C₂, Ti₃CN, Ti₂C and Ti_{1.6}Nb_{0.4}C semi-transparent thin films on glass substrates.

### Optical Properties of MXene Thin Films

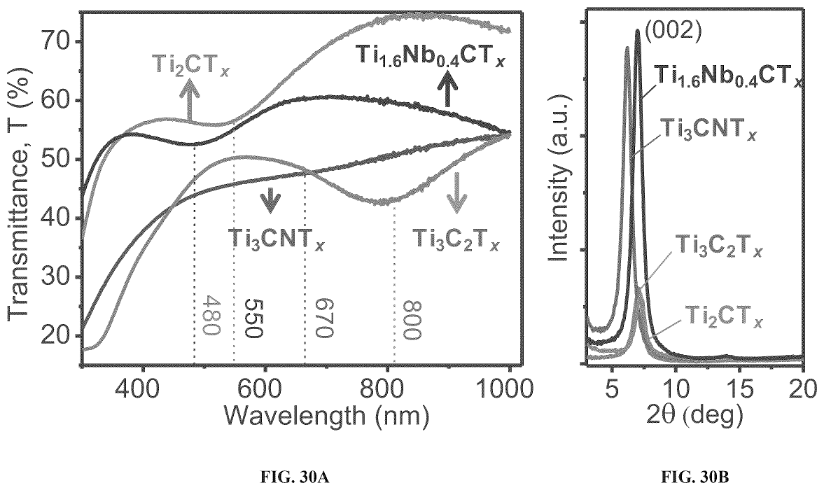

The optical properties of MXene thin films were studied by UV-vis spectroscopy (Evolution 201 UV-vis-NIR spectrophotometer, Thermo-Fischer scientific). To quantify the optical properties of MXene thin films, UV-vis-NIR spectra were recorded in the range of 300-1000 nm (FIG. 30A). MXene thin films have broad absorption bands at different wavelengths in the visible range, specific to MXene composition. However, based on synthesis and processing conditions, the given MXene composition may have slight variations in the optical absorption properties. The absorption band for Ti₃C₂ is observed at ˜800 nm; Ti₃CN at 670 nm while Ti₂C and Ti_{1.6}Nb_{0.4}C have absorption bands at ˜550 and 480 nm, respectively. It turns out that absorption characteristics of Ti-based MXenes can cover the entire visible spectrum of wavelengths. The optical absorption properties of MXenes are attributed to the surface plasmon resonance, in particular-transverse plasmons resonance in the visible region of electromagnetic spectrum. Apparently, the absorption characteristics are governed by the transition metal and carbon (nitrogen) composition and stoichiometry. All Ti-based MXene thin films (thickness, 40 nm) showed good crystalline quality as evident from the strong (002) reflection peak as shown in FIG. 12B. The (002) reflection peak at 6.5-7.2° in MXenes corresponds to d-spacing of 13.4-12.2 Å which is sufficient for the protons to access the surface sites to undergo redox reactions results in faster kinetics.

### Optoelectronic Properties of MXene Thin Films

The electrical conductivity and sheet resistance (at an applied current of 0.5 mA) of MXene thin films were measured by taking the average of sheet resistance measured at five different locations of the film on four corners and centre using a four-point probe (ResTest v1, Jandel Engineering Ltd., Bedfordshire, UK) with a probe distance of 1 mm.

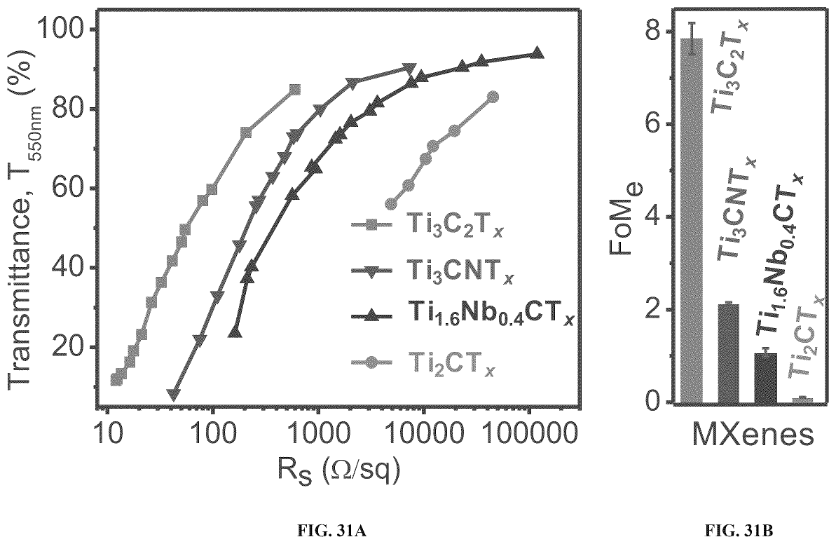

The electrical figure of merit (FoMₑ) for the MXene thin films can be dependent on several parameters such as MXene composition, synthesis and processing conditions. Since we used spray coating technique in common to all MXene thin films, the FoMₑ (processing parameter is ruled out) is mostly governed by the intrinsic electrical conductivity and optical properties. MXene thin films followed common trend of percolative electrical transport (decrease in sheet resistance with decrease in transparency) at low thickness (10-50 nm) and then bulk-like electrical transport (sheet resistance is nearly constant with decrease in transparency) as shown in FIG. 31A. As shown in FIG. 31B, it was observed that Ti₃C₂ has much higher FOMₑ value of 7.8 compared to Ti₃CN (FOMₑ, 2.1) Ti₂C (FOMₑ, 0.1) and Ti_{1.6}Nb_{0.4}C (FOMₑ, 1). The FOMₑ values for 32 compositions is higher than 21 compositions, which is due to greater oxidation stability of the former over the latter. Ti₃C₂ thin films showed superior optoelectronic quality over the rest of the Ti-based MXenes, due to well-developed synthesis conditions and optimal surface chemistry for Ti₃C₂.

### Electrochromic Properties of MXene Thin Films

Electrochromic behavior of MXene thin films was investigated using a three-electrode electrochemical cell combined with UV-vis measurements as discussed in the previous sections. Ag wire and Ti₃C₂ (thickness, 100 nm) films were employed as quasi reference electrode (RE) and counter electrode (CE), respectively. Working electrodes are nothing but thin films of different MXene compositions having 40-50% transparency at 550 nm. In order to probe the optical properties of only working electrode, counter electrode film of 7 mm in diameter was scraped off where visible light was allowed to pass through CE and WE without significant optical absorption contribution from CE as shown in FIG. 29.

The electrochromic behavior of MXene thin films was studied by recording in-situ UV-vis-NIR spectra with simultaneous impose of constant potentials (chronoamperometry). To take the advantage of proton induced pseudo capacitive behavior of MXenes, protic gel electrolyte was used.

Electrochromic Behavior of Ti₃C₂

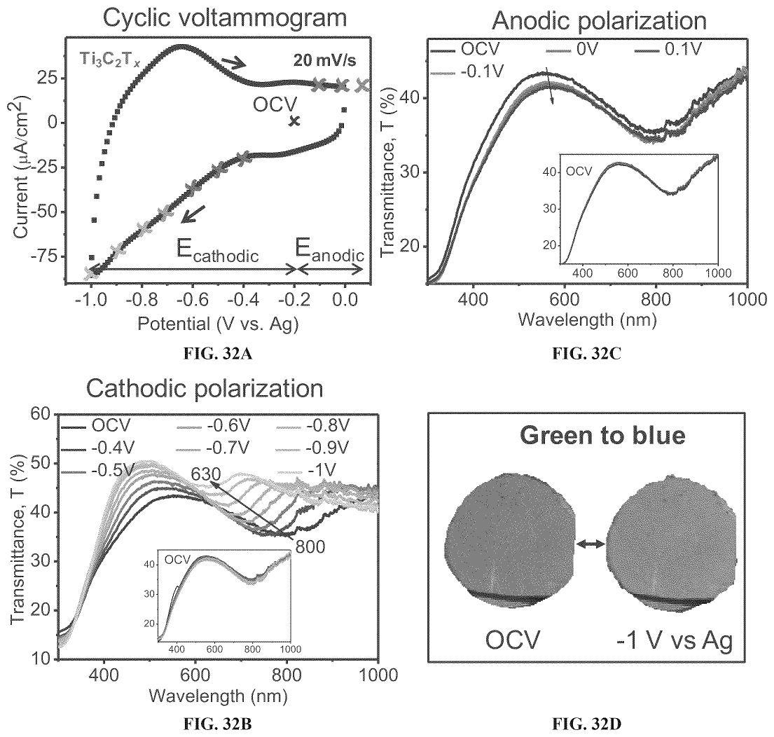

For each cell, UV-vis-NIR spectra were recorded continuously starting from open circuit voltage (OCV) to −1 V vs Ag (cathodic polarization) followed by anodic sweep up to 0.1 V (vs. Ag) in steps of 100 mV. OCV is the condition of the electrochemical cell without application of voltage or current but having interfacial contact of electrolyte with the MXene thin film. Cathodic (E_{cathodic}) and anodic (E_{anodic}) polarization are defined with respect to OCV as marked in FIG. 32A. Ti₃C₂, Ti₃CN, Ti₂C, Ti_{1.6}Nb_{0.4}C thin films showed different CV profiles, attributed to the differences in their redox properties. The (de)protonation of oxygen functionalities on titanium surface is the main mechanism of redox behavior of Ti-based MXene electrodes. Areal charge capacities of MXene thin films were estimated by integrating the discharge portion of the CVs, the typical values are found to be 1.23, 2.08, 1.36 and 1.67 mF/cm² for Ti₃C₂, Ti₃CN, Ti₂C and Ti_{1.6}Nb_{0.4}C thin film devices respectively. The extent of redox activity can influence on the charge storage properties of MXenes, which is governed by the transition metal composition, stoichiometry and surface chemistry.

As shown in FIG. 32B, blue shift in the absorption bands of MXene electrochromic devices under cathodic polarization was observed. During the cathodic polarization, Ti₃C₂ absorption band shifts from 800 nm (at OCV) to 630 nm (at −1V vs. Ag). Upon gradual increase of cathodic potential from OCV, it was observed that absorption band also shifts gradually towards lower values of wavelengths. It was known that titanium surface is reduced by protonation of oxygen functionalities with subsequent reduction of Ti oxidation state. As the CV goes from −1 V (vs. Ag) to OCV, the absorption band shifts back from 635 to 800 nm, meaning that highly reversible nature of Ti-redox state. Such kind of color change from green (at OCV) to blue (at −1 V vs. Ag) is clearly evident from the digital photographs taken during cycling (FIG. 32D). The reversible electrochromic behavior of Ti₃C₂ was also further confirmed by relaxing the system to equilibrium state after imposing the potentials as shown in the inlets of FIGS. 32B and 32C.

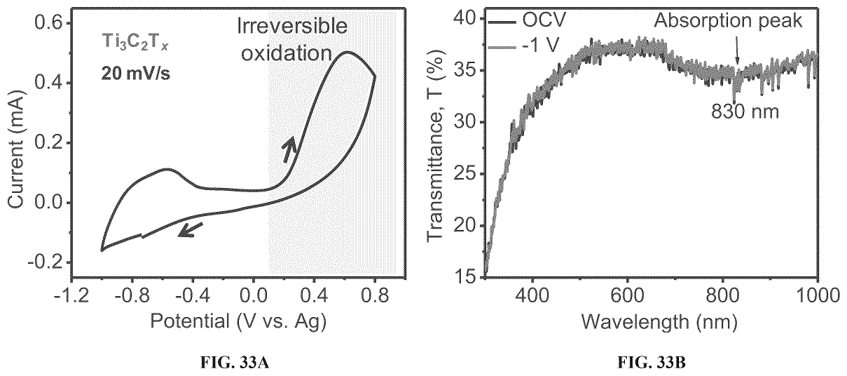

When the MXene thin films were polarized to anodic potentials (E_{anodic}>OCV), we have not observed any change in the absorption properties (FIG. 32C). This is due to capacitive type double layer (de)sorption of ions without change of Ti-redox state. These results again support that Ti-redox state change is responsible for the tunable optical properties of MXene thin films. It is important to note that there was no change in the transmittance of MXene thin films during anodic polarization (only up to stable potential limit). To confirm the reversible color change is due to change of redox state of Ti, we have anodically oxidized Ti₃C₂ thin films by sweeping to 0.8 V (vs. Ag) (FIG. 33A). At this stage, Ti is irreversibly oxidized to +4 state with loss of electrochemical activity. We have observed that the absorption band is centered at 830 nm as presented in FIG. 33B, but there was no optical shift observed up on cathodic polarization.

### Electrochromic Behavior of Ti₃CN

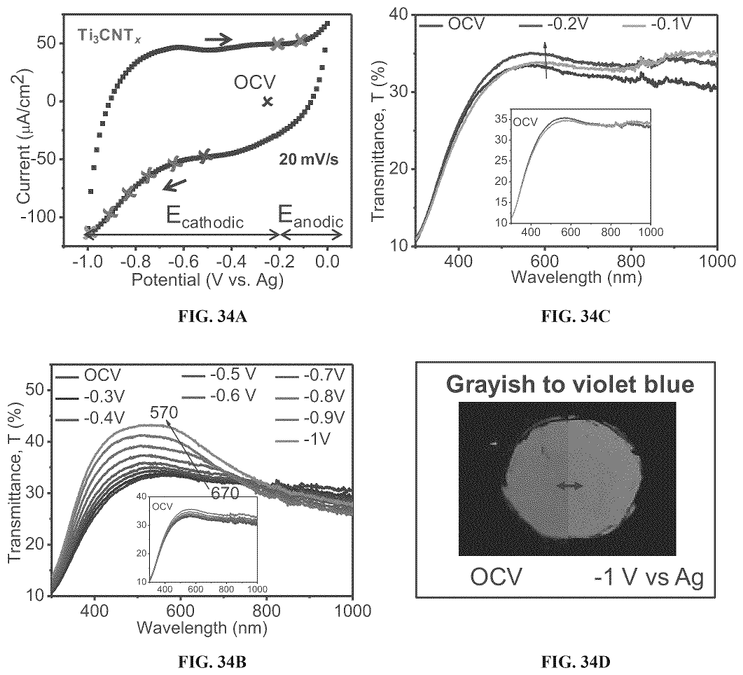

To study the effect of transition metal composition and stoichiometry, three different Ti-based MXenes were employed for electrochromic study. Spectroelectrochemical studies of Ti₃CN were performed, a member of 32 phase analogous to Ti₃C₂. From cyclic voltammetry shown in FIG. 16A, it is clear that no prominent redox peak is observed unlike Ti₃C₂ providing a clue that all MXenes have their unique signatures of redox behavior providing an origin for this study that is different MXenes have different optical absorption properties. A reversible onset of absorption (there is no clear absorption band seen) shifts between 670 nm (OCV) to 570 nm (-1 V vs. Ag) with gradual shift in the onset of peaks or narrowing down of the spectra of Ti₃CN with smalls increments in applied cathodic potentials is shown in FIG. 34B. During anodic polarizations, there is no clear trend observed but clearly there are some slight transmittance changes as shown in FIG. 34C with insets showing the reversibility of optical properties when it allowed to relax after the application of potential (square pulse). A color change from dim grayish to slight violet tint was observed shown in FIG. 34D.

Electrochromic Behavior of Ti₂C and Ti_{1.6}Nb_{0.4}C

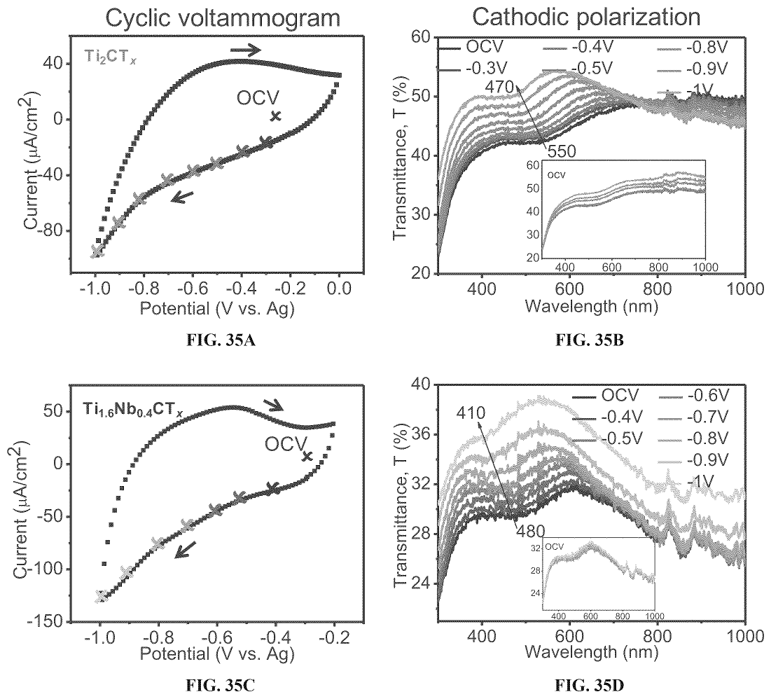

Furthermore, it is interesting to study the electrochromic effect in 21 carbide phases as Ti atoms are only available at the surface unlike 32 and 43 carbide phases having core titanium atoms (besides surface Ti). FIG. 35A and c represent cyclic voltammograms of Ti₂C and Ti_{1.6}Nb_{0.4}C thin film devices. In case of Ti₂C thin films, we have observed a shift from 550 nm (OCV) to 470 nm (−1V vs. Ag), which is again supporting the change of Ti redox state (FIG. 35B). Interestingly, the UV transmittance was increased by 10% during cathodic polarization of Ti₂C thin films. Similarly, for Ti_{1.6}Nb_{0.4}C thin films, we have observed a shift from 480 nm (OCV) to 420 nm (−1 V vs. Ag) and 6% change in transmittance (optical contrast) (FIG. 35C). The color change from wine brownish (OCV) to green (−1V vs Ag wire) was observed during cycling. Whereas for Ti₂C, there is definitely a change in optical properties from spectral shift but the color switching is not distinguishable because of the high electrical resistance offered by the film (related to poor optoelectronic quality of the film). Similar to 32 phase, there is no significant shift observed during anodic polarization when cycled in the stable potential window.

Such kind of blue shift in the absorption properties of Ti-based MXenes is due to increased electronic density of titanium atoms (in the reduced state) under cathodic polarization. The excess electronic density can screen the electric fields and hence cause blue shift in the absorption properties.

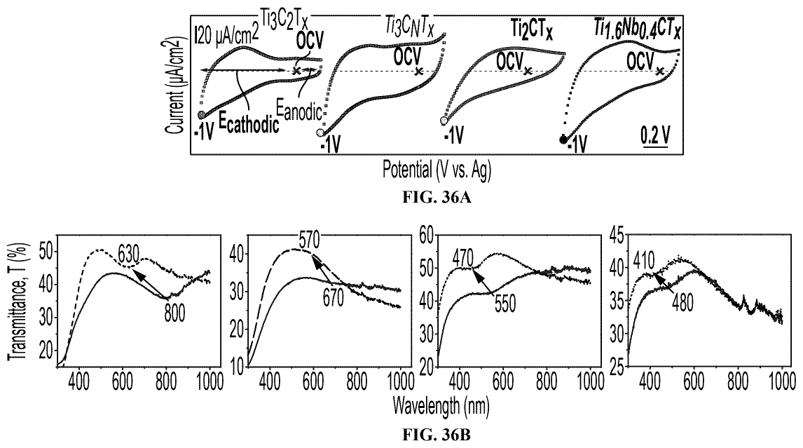

FIGS. 36A and 36B provide a glimpse of spectroelectrochemical studies of Ti₃C₂, Ti₃CN, Ti₂C and Ti_{1.6}Nb_{0.4}C MXenes. It is also evident from the observations that the MXenes studied are cathodic coloring materials and exhibits plasmonic electrochromic effect.

### Switching Speeds of Ti-Based Electrochromic Devices

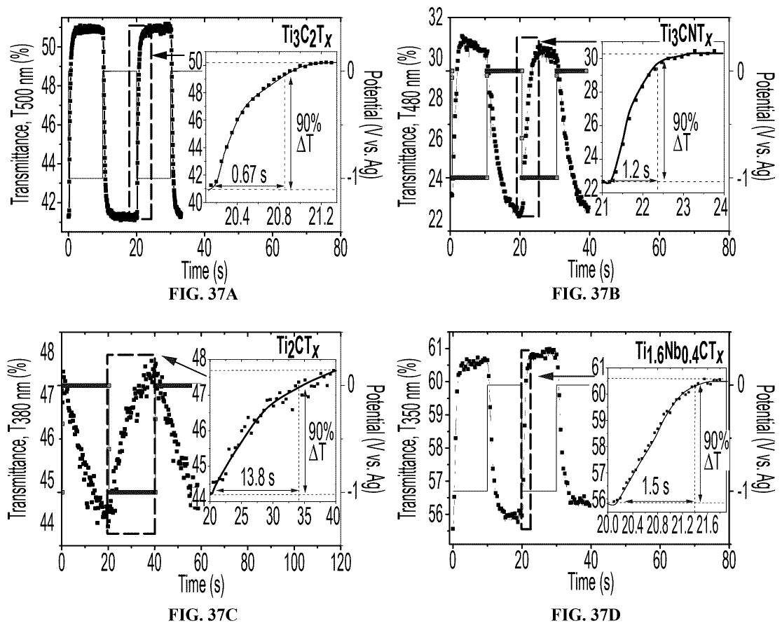

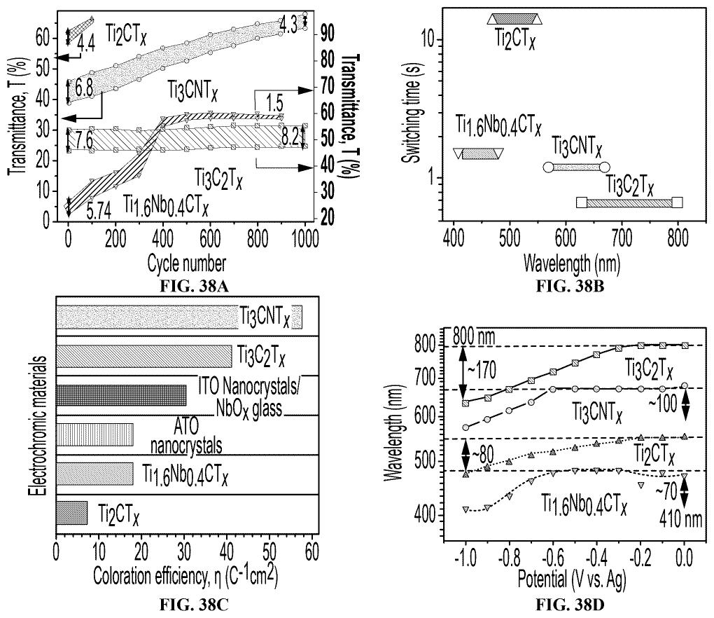

Switching time of the electrochromic devices is estimated by measuring the time required to change the transmittance by 90% of ΔT. For the sake of better ionic conductivity and transport, liquid electrolyte (1M H₃PO₄) was chosen over the gel electrolytes to study switching times. We found that switching times of Ti₃C₂, Ti₃CN, Ti₂C, and Ti_{1.6}Nb_{0.4}C electrochromic devices are around 0.7, 1.2, 14, 1.5 seconds, respectively (FIGS. 37A-37D). The fast response of Ti₃C₂ electrochromic device and rapid absorption changes (17 nm/100 mV) is governed by low sheet resistance value with higher FoMₑ compared to the rest of the MXenes. Since we used MXene thin films as both TCE and electrochromic film, the intrinsic switching times of each MXene film were evaluated without the influence from the external current collectors. As shown in FIG. 38A, the switching times of titanium based electrochromic devices are plotted pointing the undergone shift in wavelength, indicating tunable electrochromic behavior in the visible spectrum.

### Electro-Optical Performance of MXene Electrochromic Devices

In addition to the shift in the optical absorption band, we have also observed transmittance changes (optical contrast) in the MXene thin films under cathodic potential sweeps. The specific wavelengths were chosen (for each type of MXene) where there was a maximum change of transmittance was observed. As is evident from FIGS. 36A and 36B, Ti₃C₂, Ti₃CN, Ti₂C, and Ti_{1.6}Nb_{0.4}C electrochromic devices showed maximum change in the transmittance values at 500, 480, 380 and 350 nm, respectively. In case of Ti₃C₂ electrochromic device, transmittance change up to 9% was observed reversibly by continuous CV sweeps at 50 mV/s (for 50 cycles) as shown in FIG. 38B. Similarly, for Ti₃CN, reversible transmittance changes up to 6% was observed. However, in the case of Ti₂C, and Ti_{1.6}Nb_{0.4}C electrochemical devices, we observed decrease in the % ΔT (400 nm) in the initial cycles followed by the permanent increase in transparency of the film. This is due to oxidation induced degradation of 21 MXene phases, similar the reported in the literature. Since we are working with thin films, the kinetics of degradation are much faster than thicker films.

The optical absorption shifts of MXene thin films under cathodic polarization potentials are summarized in FIGS. 36A and 36B. We have estimated extinction peak shift with respect to potential step (100 mV) used in this study. The estimated shifts are found to be 17 nm/100 mV, 10 nm/100 mV, 8 nm/100 mV and 7 nm/100 mV for Ti₃C₂, Ti₃CN, Ti₂C and Ti_{1.6}Nb_{0.4}C, respectively. As is evident from FIG. 38C, the optical absorption properties of Ti-based MXenes are widely tunable by electrochemically in the entire range of visible spectrum from 800 to 410 nm. The extent of shift is based on active number of Ti redox sites with potential change of electron density electrochemically. Chapman et al., observed a shift of only 1 nm/100 mV for Ag nanoparticle films, indicating that higher redox activity of MXenes over metal nanoparticles.

TABLE 6
Summary of variations and optoelectronic properties of
MXene thin film devices investigated in this study.

| | | | | | | ΔT | |
|---|---|---|---|---|---|---|---|
| | | | | | | With | |
| | | | | | | absorption | Switching |
| MXenes | Etching | T_{550 nm} | Rₛ | | Δλ_{SPR} | peak | time |
| (ref) | method | (%) | (Ω/sq) | FoMₑ | (nm) | shift | (s) |
| Ti₃C₂ | LiF + | 50 | 50 | 17 | 100 | 12% | 0.64 |
| (⁴⁵) | HCl | | | | | | |
| | (MILD) | | | | | | |
| Ti₃C₂ | HF + | 50 | 55 | 7.8 | ~170 | 10% | 0.67 |
| (Present work) | HCl; | | | | | | |
| | LiCl | | | | | | |
| Ti₃CN | LiF + | 50 | 200 | 2.1 | ~100 | 10% | 1.2 |
| (Present work) | HCl | | | | | | |
| | (MILD) | | | | | | |
| Ti₂C | HF + | 54 | 5000 | 0.1 | ~80 | 8% | 13.8 |
| (Present work) | HCl; | | | | | | |
| | LiCl | | | | | | |
| Ti_{1.6}Nb_{0.4}C | LiF + | 50 | 400 | 1 | ~70 | 6% | 1.54 |
| (Present work) | HCl | | | | | | |
| | (MILD) | | | | | | |

Rₛ: sheet resistance; T_{550 nm}: transmittance at 550 nm; Δλ_{SPR}: wavelength change in the surface plasmon resonance; ΔT: change in transmittance associated with absorption band shift; FOM_{e:} electrical figure of merit; : surface functional groups (—OH, ═O, —F); HF: hydrofluoric acid; HCl: hydrochloric acid; LiCl: lithium chloride; LiF: lithium fluoride.

### Exemplary Embodiments

The following embodiments are illustrative only and do not serve to limit the scope of the present disclosure or the appended claims.
Embodiment 1. An electrochromic device, comprising: an electrochromic portion and at least one of (i) a transparent conducting portion and (ii) an ion storage portion, one or more MXene materials being present in at least one of (a) the electrochromic portion and (b) the at least one of (i) the transparent conducting electrode portion and (ii) the ion storage portion; and an electrolyte (an electrolyte can be acidic or alkaline), the electrolyte placing the electrochromic portion into electronic communication with the at least one of (i) the transparent conducting portion and (ii) the ion storage portion.
Embodiment 2. The electrochromic device of Embodiment 1, wherein the electrolyte comprises an organic material or a non-aqueous material. Exemplary organic electrolytes include, e.g., lithium bis (trifluoromethylsulfonyl) imide (LiTFSI) or 1-ethyl-3-methylimidazolium bis (trifluoromethylsulfonyl)imide (EMIMTFSI) dissolved in polycarbonate (PC). Exemplary aqueous electrolytes include but are not limited to sulfuric acid, phosphoric acid, magnesium sulphate dissolved in water, and polyvinyl alcohol (PVA).
Embodiment 3. The electrochromic device of any one of Embodiments 1-2, wherein the device comprises an electrochromic portion and a transparent conducting portion, and wherein both the electrochromic portion and transparent conducting portion comprises the same or different MXene materials.
Embodiment 4. The electrochromic device of any one of Embodiments 1-3, wherein the device comprises an electrochromic portion and an ion storage portion, and wherein both the electrochromic portion and the ion storage portion comprises the same or different MXene materials.
Embodiment 5. The electrochromic device of any one of Embodiments 1-4, wherein the electrochromic device comprises a polymeric material contacting the MXene material, the polymeric material optionally being intercalated within the MXene material. Exemplary, non-limiting polymers include, e.g., poly(3,4-ethylenedioxythiophene) (PEDOT), poly(3,4 ethylenedioxythiophene) polystyrene sulfonate (PEDOT:PSS), polyurethane, polyvinyl alcohol, polyaniline, and polypyrrole.
Embodiment 6. The electrochromic device of Embodiment 5, wherein the polymeric material comprises a conducting polymer.
Embodiment 7. The electrochromic device of any one of Embodiments 5-6, wherein the polymer comprises an electrochromic polymer.
Embodiment 8. The electrochromic device of any one of Embodiments 5-7, wherein the polymer comprises PEDOT.
Embodiment 9. The electrochromic device of anyone of Embodiments 1-8, wherein the electrolyte comprises a solid material.
Embodiment 10. The electrochromic device of any one of Embodiments 1-9, wherein the electrochromic portion is disposed between the transparent conductor portion and the ion storage portion.
Embodiment 11. The electrochromic device of Embodiment 1, wherein at least two of the electrochromic portion and the at least one of (i) a transparent conducting electrode portion and (ii) an ion storage portion comprise one or more MXene materials.
Embodiment 12. The electrochromic device of any one of Embodiments 1-11, further comprising a transparent substrate configured to support at least one of the electrochromic portion and the at least one of (i) a transparent conducting electrode portion and (ii) an ion storage portion.
Embodiment 13. The electrochromic device of Embodiment 12, wherein the transparent substrate comprises a glass.
Embodiment 14. The electrochromic device of Embodiment 1, further comprising: (a) a substrate, (b) a first transparent conducting layer on the substrate, (c) a stack disposed on the first transparent conducting layer, the stack comprising: (i) an electrochromic portion; (ii) a counter electrode layer comprising a counter electrode material that serves as a reservoir of ions; where the stack optionally comprises an ion conducting and electrically insulating region disposed between the electrochromic portion and the counter electrode layer; and (d) a second transparent conducting oxide layer on top of the stack, the layers preferably being arranged in the order: substrate, transparent conductive layer, counter electrode layer, ion conducting layer, electrochromic material layer and an optional further transparent conductive layer, wherein at least one of the transparent conductive layer electrode, the ion-storage layer, or the electrochromic portion comprises at least one MXene material.
Embodiment 15. The electrochromic device of Embodiment 14, wherein two or more of the transparent conductive layer electrode, the ion-storage layer, or the electrochromic portion comprises at least one MXene material, which at least one MXene material can be the same or different for each layer.
Embodiment 16. The electrochromic device of any one of Embodiments 14-15, wherein the layer comprising at least one MXene layer serves as two or more of: the transparent conductive layer, the ion-storage layer, and the electrochromic portion.
Embodiment 17. An electrochromic device, comprising: a first MXene portion and a second MXene portion, the first MXene portion and the second MXene portion being in physical isolation from one another, a conductive material disposed on at least one of the first MXene portion and the second MXene portion, the conductive material optionally having a lower conductivity than the MXene portion on which the conductive material is disposed, the conductive material optionally being disposed within the MXene portion on which the conductive material is disposed, and the conductive material optionally comprising a conductive polymer.
Embodiment 18. The electrochromic device of Embodiment 17, further comprising an electrolyte placing the first MXene portion into electronic communication with the second MXene portion, the electrolyte optionally comprising an organic electrolyte or a non-aqueous electrolyte.
Embodiment 19. The electrochromic device of any one of Embodiments 17-18, wherein at least one of the first MXene portion and the second MXene portion is disposed on a transparent substrate.
Embodiment 20. The electrochromic device of any one of Embodiments 17-19, wherein the first MXene portion and the second MXene portion comprise the same MXene material.
Embodiment 21. The electrochromic device of any one of Embodiments 17-20, wherein the conductive material is disposed on the first MXene portion and on the second MXene portion.
Embodiment 22. The electrochromic device of any one of Embodiments 17-21, wherein the first MXene portion has disposed thereon a conductive material, wherein the second MXene portion has disposed thereon a conductive material, and wherein the conductive material disposed on the first MXene portion is different from the conductive material disposed on the second MXene portion.
Embodiment 23. The electrochromic device of any one of Embodiments 17-22, wherein at least one of the first MXene portion and the second MXene portion comprises a plurality of layers of MXene material.
Embodiment 24. The electrochromic device of any one of Embodiments 1-23, wherein the electrochromic device is characterized as having a switching rate of from about 1 ms to about 120 seconds.
Embodiment 25. The electrochromic device of any one of Embodiments 1-24, wherein the electrochromic device is characterized as having a coloration efficiency of from about 2 to about 250 cm² C⁻¹.
Embodiment 26. A method, comprising: operating a device according to any one of Embodiments 1-16 so as to induce a color change in the electrochromic portion. One can also operate a device according to any one of Embodiments 1-25 so as to effect a color change of the device.
Embodiment |27. A method, comprising: operating a device according to any one of Embodiments 1-16 so as to effect at least one of ion accumulation into or ion release from the ion storage portion. One can also operate a device according to any one of Embodiments 17-23 so as to effect at least one of ion accumulation or ion release.
Embodiment 28. A device, the device comprising an electrochromic device according to any one of Embodiments 1-26.
Embodiment 29. The device of Embodiment 28, wherein the device is characterized as a window, infrared-reflecting window, an energy storage device, photovoltaic devices, a solar cell, touch screen, liquid-crystal display, or a light-emitting diode. The foregoing list is exemplary only, and is not exhaustive or limiting.
Embodiment 30. A method, comprising: disposing an amount of a MXene material on a substrate so as to form a MXene panel, the substrate optionally being transparent; placing the MXene panel into electronic communication with an electrode.
Embodiment 31. The method of Embodiment 30, further comprising disposing a conductive material on the MXene material.
Embodiment 32. The method of any one of Embodiments 30-31, further comprising polymerizing the conductive material.
Embodiment 33. The method of any one of Embodiments 30-32, wherein placing the MXene panel into electronic communication with an electrode comprising disposing an electrolyte so as to place the MXene panel into electronic communication with the electrode.

A device can be quantified in terms of its switching rate, which is the time needed to switch from one color to the other, or from minimal to maximal transmittance at a specific wavelength of interest. A device according to the present disclosure can have a switching rate of, e.g., from about 10 ms to about 30 s.

A device can also be quantified in terms of its “color change,” which can be described by change of absorption wavelength and transmittance at a specific wavelength. By using a combination of different MXene electrochromic layers, one can attain a wavelength change from 400-800 nm.

Coloration efficiency (η, cm² C⁻¹) is used to define performance among different electrochromic materials and devices. Coloration efficiency at a given wavelength is given as 1n[T_{b}/T_{c}]/Q, where Q is the electronic charge injected per unit area and T_{b}/T_{c} is the transmission in bleached and colored states, respectively. This equation provides information on the change in optical density achieved by charge. Materials with higher η will be able to switch faster and more repeatedly, since less charge is required to produce a given color change. A device can utilize visible color change, however, infrared color change can also be used, e.g., for electrochromic devices that block (reflect) heat.

One can also characterize devices in terms of their “retention,” which refers to the ability of the device to retain color efficiency or charge capacity. Retention of the device is quantified by measuring the change in transmittance/color (coloration efficiency) or charge capacity of the device over a few to several thousands of electrochemical cycles.

### References

The following references are incorporated herein by reference in their entireties for any and all purposes.

X. Chen, H. Lin, J. Deng, Y. Zhang, X. Sun, P. Chen, X. Fang, Z. Zhang, G. Guan, H. Peng, Electrochromic Fiber-Shaped Supercapacitors, Adv. Mater. 26 (2014) 8126-8132.

W. Weng, P. Chen, S. He, X. Sun, H. Peng, Smart Electronic Textiles, Angew. Chem. Int. Ed. 55 (2016) 6140-6169.

H. Li, J. Li, C. Hou, D. Ho, Q. Zhang, Y. Li, H. Wang, Solution-Processed Porous Tungsten Molybdenum Oxide Electrodes for Energy Storage Smart Windows, Adv. Mater. Technol. 2 (2017) 1700047.

S. Lin, X. Bai, H. Wang, H. Wang, J. Song, K. Huang, C. Wang, N. Wang, B. Li, M. Lei, H. Wu, Roll-to-Roll Production of Transparent Silver-Nanofiber-Network Electrodes for Flexible Electrochromic Smart Windows, Adv. Mater. 29 (2017) 1703238.

Z. Liu, H. I. Wang, A. Narita, Q. Chen, Z. Mics, D. Turchinovich, M. Kläui, M. Bonn, K. Müllen, Photoswitchable Micro-Supercapacitor Based on a Diarylethene-Graphene Composite Film, J. Am. Chem. Soc. 139 (2017) 9443-9446.

T. Y. Yun, X. Li, S. H. Kim, H. C. Moon, Dual-Function Electrochromic Supercapacitors Displaying Real-Time Capacity in Color, ACS Appl. Mater. Inter. 10 (2018) 43993-43999.

P. Yang, P. Sun, W. Mai, Electrochromic energy storage devices, Mater. Today 19 (2016) 394-402.

L. Zhang, M. Liao, L. Bao, X. Sun, H. Peng, The Functionalization of Miniature Energy—Storage Devices, Small Methods 1 (2017) 1700211.

S. Qin, Q. Zhang, X. Yang, M. Liu, Q. Sun, Z. L. Wang, Hybrid Piezo/Triboelectric—Driven Self—Charging Electrochromic Supercapacitor Power Package, Adv. Energy Mater. 8 (2018) 1800069.

T. G. Yun, D. Kim, Y. H. Kim, M. Park, S. Hyun, S. M. Han, Photoresponsive Smart Coloration Electrochromic Supercapacitor, Adv. Mater. 29 (2017) 1606728.

P. Zhang, F. Zhu, F. Wang, J. Wang, R. Dong, X. Zhuang, O. G. Schmidt, X. Feng, Stimulus—Responsive Micro—Supercapacitors with Ultrahigh Energy Density and Reversible Electrochromic Window, Adv. Mater. 29 (2017) 1604491.

K. Laszczyk, D. Futaba, K. Kobashi, K. Hata, T. Yamada, A. Sekiguchi, The limitation of electrode shape on the operational speed of a carbon nanotube based micro-supercapacitor, Sustain. Energ. Fuels 1 (2017) 1282-1286.

Y. Shao, J. Li, Y. Li, H. Wang, Q. Zhang, R. B. Kaner, Flexible quasi-solid-state planar micro-supercapacitor based on cellular graphene films, Mater. Horiz. 4 (2017) 1145-1150.

P. Huang, C. Lethien, S. Pinaud, K. Brousse, R. Laloo, V. Turq, M. Respaud, A. Demortiere, B. Daffos, P. L. Taberna, On-chip and freestanding elastic carbon films for micro-supercapacitors, Science 351 (2016) 691-695.

N. A. Kyeremateng, T. Brousse, D. Pech, Microsupercapacitors as miniaturized energy-storage components for on-chip electronics, Nat. Nanotechnol. 12 (2017) 7.

C. J. Zhang, V. Nicolosi, Graphene and MXene-based transparent conductive electrodes and supercapacitors, Energy Storage Mater. 16 (2018) 102-125.

K. Hantanasirisakul, M. Q. Zhao, P. Urbankowski, J. Halim, B. Anasori, S. Kota, C. E. Ren, M. W. Barsoum, Y. Gogotsi, Fabrication of Ti3C2 MXene transparent thin films with tunable optoelectronic properties, Adv. Electron. Mater. 2 (2016) 1600050.

P. Salles, E. Quain, N. Kurra, A. Sarycheva, Y. Gogotsi, Automated Scalpel Patterning of Solution Processed Thin Films for Fabrication of Transparent MXene Microsupercapacitors, Small 14 (2018) 1802864.

C. Zhang, B. Anasori, A. SeralAscaso, S. H. Park, N. McEvoy, A. Shmeliov, G. S. Duesberg, J. N. Coleman, Y. Gogotsi, V. Nicolosi, Transparent, Flexible, and Conductive 2D Titanium Carbide (MXene) Films with High Volumetric Capacitance, Adv. Mater. 29 (2017) 1702678.

B. Anasori, M. R. Lukatskaya, Y. Gogotsi, 2D metal carbides and nitrides (MXenes) for energy storage, Nat. Rev. Mater. 2 (2017) 16098.

S. Wang, X. Zhao, X. Yan, Z. Xiao, C. Liu, Y. Zhang, X. Yang, Regulating Fast Anionic Redox for High-Voltage Aqueous Hydrogen-Ion-based Energy Storage, Angew. Chem. 131 (2019) 211-216.

Y. Xia, T. S. Mathis, M. Zhao, B. Anasori, A. Dang, Z. Zhou, H. Cho, Y. Gogotsi, S. Yang, Thickness-independent capacitance of vertically aligned liquid-crystalline MXenes, Nature 557 (2018) 409.

A. A. Argun, P. H. Aubert, B. C. Thompson, I. Schwendeman, C. L. Gaupp, J. Hwang, N. J. Pinto, D. B. Tanner, A. G. MacDiarmid, J. R. Reynolds, Multicolored electrochromism in polymers: structures and devices, Chem. Mater. 16 (2004) 4401-4412.

J. Li, H. Li, J. Li, G. Wu, Y. Shao, Y. Li, Q. Zhang, H. Wang, A single-walled carbon nanotubes/poly(3,4-ethylenedioxythiophene)-poly(styrenesulfonate)/copper hexacyanoferrate hybrid film for high-volumetric performance flexible supercapacitors, J. Power Sources 386 (2018) 96-105.

J. Li, N. Kurra, M. Seredych, X. Meng, H. Wang, Y. Gogotsi, Bipolar carbide-carbon high voltage aqueous lithium-ion capacitors, Nano Energy 56 (2019) 151-159.

M. Alhabeb, K. Maleski, B. Anasori, P. Lelyukh, L. Clark, S. Sin, Y. Gogotsi, Guidelines for Synthesis and Processing of Two-Dimensional Titanium Carbide (Ti3C2Tₓ MXene), Chem. Mater. 29 (2017) 7633-7644.

X. Wang, T. S. Mathis, K. Li, Z. Lin, L. Vlcek, T. Torita, N. C. Osti, C. Hatter, P. Urbankowski, A. Sarycheva, M. Tyagi, E. Mamontov, P. Simon, Y. Gogotsi, Influences from solvents on charge storage in titanium carbide MXenes, Nat. Energy 4 (2019) 241-248.

P. Subramanian, N. Clark, B. WintherJensen, D. MacFarlane, L. Spiccia, Vapour-phase polymerization of pyrrole and 3, 4-ethylenedioxythiophene using iron (III) 2, 4, 6-trimethylbenzenesulfonate, Aust. J. Chem. 62 (2009) 133-139.

B. Winther-Jensen, K. West, Vapor-phase polymerization of 3, 4-ethylenedioxythiophene: a route to highly conducting polymer surface layers, Macromolecules 37 (2004) 4538-4543.

G. Cai, P. Darmawan, M. Cui, J. Wang, J. Chen, S. Magdassi, P. S. Lee, Highly Stable Transparent Conductive Silver Grid/PEDOT: PSS Electrodes for Integrated Bifunctional Flexible Electrochromic Supercapacitors, Adv. Energy Mater. 6 (2016) 1501882.

R. Liu, J. Duay, T. Lane, S. Bok Lee, Synthesis and characterization of RuO₂/poly(3,4-ethylenedioxythiophene) composite nanotubes for supercapacitors, Phys. Chem. Chem. Phys. 12 (2010) 4309-4316.

M. F. ElKady, V. Strong, S. Dubin, R. B. Kaner, Laser Scribing of High-Performance and Flexible Graphene-Based Electrochemical Capacitors, Science 335 (2012) 1326-1330.

C. Kim, D. Y. Kang, J. H. Moon, Full lithographic fabrication of boron-doped 3D porous carbon patterns for high volumetric energy density microsupercapacitors, Nano Energy 53 (2018) 182-188.

Z. Wu, K. Parvez, A. Winter, H. Vieker, X. Liu, S. Han, A. Turchanin, X. Feng, K. Müllen, Layer-by-Layer Assembled Heteroatom-Doped Graphene Films with Ultrahigh Volumetric Capacitance and Rate Capability for Micro-Supercapacitors, Adv. Mater. 26 (2014) 4552-4558.

Z. Wu, Y. Tan, S. Zheng, S. Wang, K. Parvez, J. Qin, X. Shi, C. Sun, X. Bao, X. Feng, K. Müllen, Bottom-Up Fabrication of Sulfur-Doped Graphene Films Derived from Sulfur-Annulated Nanographene for Ultrahigh Volumetric Capacitance Micro-Supercapacitors, J. Am. Chem. Soc. 139 (2017) 4506-4512.

J. Qin, S. Wang, F. Zhou, P. Das, S. Zheng, C. Sun, X. Bao, Z. Wu, 2D mesoporous MnO₂ nanosheets for high-energy asymmetric micro-supercapacitors in water-in-salt gel electrolyte, Energy Storage Mater. (2018) Doi: 10.1016/j.ensm.2018.1012.1022.

N. Kurra, M. K. Hota, H. N. Alshareef, Conducting polymer micro-supercapacitors for flexible energy storage and AC line-filtering, Nano Energy 13 (2015) 500-508.

P. Salles, D. Pinto, K. Hantanasirisakul, K. Maleski, C. E. Shuck, Y. Gogotsi, Electrochromic Effect in Titanium Carbide MXene Thin Films Produced by Dip-Coating, Adv. Funct. Mater. (2019) doi: 10.1002/adfm.201809223.

S. Garreau, G. Louarn, J. Buisson, G. Froyer, S. Lefrant, In situ spectroelectrochemical Raman studies of poly (3, 4-ethylenedioxythiophene) (PEDOT), Macromolecules 32 (1999) 6807-6812.

D. Dong, W. Wang, A. Rougier, G. Dong, M. Da Rocha, L. Presmanes, K. Zrikem, G. Song, X. Diao, A. Barnabé, Life-cycling and uncovering cation-trapping evidence of a monolithic inorganic electrochromic device: glass/ITO/WO₃/LiTaO₃/NiO/ITO, Nanoscale 10 (2018) 16521-16530.

M. Fabretto, K. Zuber, C. Hall, P. Murphy, H. J. Griesser, The role of water in the synthesis and performance of vapour phase polymerised PEDOT electrochromic devices, J. Mater. Chem. 19 (2009) 7871-7878.

C. Chang, G. Liou, S. Hsiao, Highly stable anodic green electrochromic aromatic polyamides: synthesis and electrochromic properties, J. Mater. Chem. 17 (2007) 1007-1015.

B. Gélinas, D. Das, D. Rochefort, Air-Stable, Self-Bleaching Electrochromic Device Based on Viologen-and Ferrocene-Containing Triflimide Redox Ionic Liquids, ACS Appl. Mater. Inter. 9 (2017) 28726-28736.

D. S. Hecht, L. Hu, G. Irvin, Adv. Mater. 2011, 23, 1482.

R. Baetens, B. P. Jelle, A. Gustavsen, Sol. Energy Mater. Sol. Cells 2010, 94, 87.

G. Cai, J. Wang, P. S. Lee, Acc. Chem. Res. 2016, 49, 1469.

C. G. Granqvist, Thin Solid Films 2014, 564, 1.

C. G. Granqvist, M. A. Arvizu, I. Bayrak Pehlivan, H. Y. Qu, R. T. Wen, G. A. Niklasson, Electrochim. Acta 2017, 259, 1170.

U. Betz, M. Kharrazi Olsson, J. Marthy, M. F. Escolá, F. Atamny, Surf. Coatings Technol. 2006, 200, 5751.

S. De, J. N. Coleman, ACS Nano 2010, 4, 2713.

K. Ellmer, Nat. Photonics 2012, 6, 809.

L. Yu, C. Shearer, J. Shapter, Chem. Rev. 2016, 116, 13413.

Y. H. Liu, J. L. Xu, S. Shen, X. L. Cai, L. Sen Chen, S. D. Wang, J. Mater. Chem. A 2017, 5, 9032.

Y. Xu, J. Liu, Small 2016, 12, 1400.

S. Kiruthika, C. Sow, G. U. Kulkarni, Small 2017, 13, 1701906.

H. Zheng, J. Z. Ou, M. S. Strano, R. B. Kaner, A. Mitchell, K. Kalantar-Zadeh, Adv. Funct. Mater. 2011, 21, 2175.

F. Shahzad, M. Alhabeb, C. B. Hatter, B. Anasori, S. Man Hong, C. M. Koo, Y. Gogotsi, Science 2016, 353, 1137.

M. Naguib, M. Kurtoglu, V. Presser, J. Lu, J. Niu, M. Heon, L. Hultman, Y. Gogotsi, M. W. Barsoum, Adv. Mater. 2011, 23, 4248.

K. Hantanasirisakul, Y. Gogotsi, Adv. Mater. 2018, 1804779.

J. Halim, K. M. Cook, M. Naguib, P. Eklund, Y. Gogotsi, J. Rosen, M. W. Barsoum, Appl. Surf. Sci. 2016, 362, 406.

I. Persson, L.-Å. Näslund, J. Halim, M. W. Barsoum, V. Darakchieva, J. Palisaitis, J. Rosen, P. Persson, 2D Mater. 2018, 5, 15002.

K. Maleski, C. E. Ren, M. Zhao, B. Anasori, Y. Gogotsi, ACS Appl. Mater. Interfaces 2018, 10, 24491.

A. Lipatov, M. Alhabeb, M. R. Lukatskaya, A. Boson, Y. Gogotsi, A. Sinitskii, Adv. Electron. Mater. 2016, 2, 1600255.

C. J. Zhang, S. Pinilla, N. McEvoy, C. P. Cullen, B. Anasori, E. Long, S.-H. Park, A. Seral-Ascaso, A. Shmeliov, D. Krishnan, C. Morant, X. Liu, G. S. Duesberg, Y. Gogotsi, V. Nicolosi, Chem. Mater. 2017, 29, 4848.

M. Mariano, O. Mashtalir, F. Q. Antonio, W.-H. Ryu, B. Deng, F. Xia, Y. Gogotsi, A. D. Taylor, Nanoscale 2016, 8, 16371.

A. D. Dillon, M. J. Ghidi, A. L. Krick, J. Griggs, S. J. May, Y. Gogotsi, M. W. Barsoum, A. T. Fafarman, Adv. Funct. Mater. 2016, 26, 4162.

G. Ying, A. D. Dillon, A. T. Fafarman, M. W. Barsoum, Mater. Res. Lett. 2017, 5, 391.

G. Ying, S. Kota, A. D. Dillon, A. T. Fafarman, M. W. Barsoum, FlatChem 2018, 8, 25.

Y. Yang, S. Umrao, S. Lai, S. Lee, J. Phys. Chem. Lett. 2017, 8, 859.

J. Halim, M. R. Lukatskaya, K. M. Cook, J. Lu, C. R. Smith, L. Å. Näslund, S. J. May, L. Hultman, Y. Gogotsi, P. Eklund, M. W. Barsoum, Chem. Mater. 2014, 26, 2374.

M. R. Lukatskaya, S.-M. Bak, X. Yu, X.-Q. Yang, M. W. Barsoum, Y. Gogotsi, Adv. Energy Mater. 2015, 5, 1500589.

C. Zhan, M. Naguib, M. Lukatskaya, P. R. C. Kent, Y. Gogotsi, D. Jiang, Phys. Chem. Lett. 2018, 9, 1223.

Y. Gogotsi, R. M. Penner, ACS Nano 2018, 12, 2081.

M. R. Lukatskaya, S. Kota, Z. Lin, M. Q. Zhao, N. Shpigel, M. D. Levi, J. Halim, P. L. Taberna, M. W. Barsoum, P. Simon, Y. Gogotsi, Nat. Energy 2017, 2, 17105.

B. Akuzum, K. Maleski, B. Anasori, P. Lelyukh, N. J. Alvarez, E. C. Kumbur, Y. Gogotsi, ACS Nano 2018, 12, 2685.

C. Couly, M. Alhabeb, K. L. Van Aken, N. Kurra, L. Gomes, A. M. Navarro-Suárez, B. Anasori, H. N. Alshareef, Y. Gogotsi, Adv. Electron. Mater. 2018, 4, 1700339.

H. An, T. Habib, S. Shah, H. Gao, M. Radovic, M. J. Green, J. L. Lutkenhaus, Sci. Adv. 2018, 4, eaaq0118.

K. Chaudhuri, M. Alhabeb, Z. Wang, V. M. Shalaev, Y. Gogotsi, A. Boltasseva, ACS Photonics 2018, 5, 1115.

J. K. El-Demellawi, S. Lopatin, J. Yin, O. F. Mohammed, H. N. Alshareef, ACS Nano 2018, 12, 8485.

M. Naguib, O. Mashtalir, M. R. Lukatskaya, B. Dyatkin, C. Zhang, V. Presser, Y. Gogotsi, M. W. Barsoum, Chem. Commun. 2014, 50, 7420.

T. Xu, E. C. Walter, A. Agrawal, C. Bohn, J. Velmurugan, W. Zhu, H. J. Lezec, A. A. Talin, Nat. Commun. 2016, 7, 10479.

M. R. Lukatskaya, O. Mashtalir, C. E. Ren, Y. D. Agnese, M. W. Barsoum, Y. Gogotsi, Science 2013, 341, 1502.

O. Mashtalir, M. Naguib, V. N. Mochalin, Y. Dall'Agnese, M. Heon, M. W. Barsoum, Y. Gogotsi, Nat. Commun. 2013, 4, 1.

M. Ghidiu, J. Halim, S. Kota, D. Bish, Y. Gogotsi, M. W. Barsoum, Chem. Mater. 2016, 28, 3507.

M. Hu, Z. Li, T. Hu, S. Zhu, C. Zhang, X. Wang, ACS Nano 2016, 10, 11344.

J. Ye, H. Tan, S. Wu, K. Ni, F. Pan, J. Liu, Z. Tao, Y. Qu, H. Ji, P. Simon, Y. Zhu, Adv. Mater. 2018, 30, 1801384.

K. Maleski, C. E. Ren, M. Zhao, B. Anasori and Y. Gogotsi, ACS Appl. Mater. Interfaces, 2018, 10, 24491-24498.

P. J. King, T. M. Higgins, S. De, N. Nicoloso and J. N. Coleman, ACS Nano, 2012, 6, 1732-1741.

Y. Y. Peng, B. Akuzum, N. Kurra, M. Q. Zhao, M. Alhabeb, B. Anasori, E. C. Kumbur, H. N. Alshareef, M. Der Ger and Y. Gogotsi, Energy Environ. Sci., 2016, 9, 2847-2854.

T. Hu, J. Wang, H. Zhang, Z. Li, M. Hu and X. Wang, Phys. Chem. Chem. Phys., 2015, 17, 9997-10003.

Li, Levitt, Kurra, Juan, Noriega, Xiao, Wang, Wang, Alshareef, Gogotsi, “MXene-conducting Polymer Electrochromic Microsupercapacitors,” Energy Storage Materials, Volume 20, July 2019, Pages 455-461.

“Tunable Electrochromic Behavior in Titanium-Based MXenes,” G. Valurouthu, Master's Thesis, European Joint Master Course.

What is claimed:

1. An electrochromic device, comprising:
an electrochromic portion and at least one of (i) a transparent conducting portion and (ii) an ion storage portion,
one or more MXene materials being present in at least one of (a) the electrochromic portion and (b) the at least one of (i) the transparent conducting electrode portion and (ii) the ion storage portion; and
an electrolyte,
the electrolyte placing the electrochromic portion into electronic communication with the at least one of (i) the transparent conducting portion and (ii) the ion storage portion.
